(19) United States
(12) Patent Application Publication
(10) Pub. No.: US 2026/0114119 A1
(43) Pub. Date: Apr. 23, 2026

(54) LIGHT-EMITTING DEVICE AND ELECTRONIC APPARATUS

(71) Applicant: SAMSUNG DISPLAY CO., LTD., Yongin-si (KR)

(72) Inventors: Seokgyu Yoon, Yongin-si (KR); Mieun Jun, Yongin-si (KR); Hyeongu Cho, Yongin-si (KR); Jaejin Lyu, Yongin-si (KR)

(21) Appl. No.: 19/413,700

(22) Filed: Dec. 9, 2025

Related U.S. Application Data
(63) Continuation of application No. 17/162,538, filed on Jan. 29, 2021.

(30) Foreign Application Priority Data
Jan. 30, 2020 (KR) 10-2020-0011347
Jan. 28, 2021 (KR) 10-2021-0011975

(51) Int. Cl. H10K 50/12; H10K 50/11; H10K 59/12; H10K 85/30; H10K 85/60; H10K 101/10

(52) U.S. Cl. CPC H10K 50/121; H10K 50/11; H10K 85/346; H10K 85/623; H10K 85/654; H10K 85/6572; H10K 85/658; H10K 59/12; H10K 2101/10

(57) ABSTRACT

A light-emitting device includes an emission layer that includes a host, a first dopant, and a second dopant, and an electronic apparatus includes the same. In the emission layer, a) the first dopant is a phosphorescent dopant, b) a Stokes shift of the second dopant is less than or equal to 15 nm, and c) a spectral overlap integral of an emission spectrum of the first dopant and an absorption spectrum of the second dopant may be greater than or equal to 1.5×10¹⁵ M⁻¹ cm⁻¹ nm⁴, and accordingly, the emission efficiency (for example, external quantum efficiency) and lifespan of the light-emitting device may be improved.

### CROSS-REFERENCE TO RELATED APPLICATION

This application is a continuation of U.S. patent application Ser. No. 17/162,538, filed on Jan. 29, 2021, which claims priority to and the benefit of Korean Patent Applications No. 10-2020-0011347, filed on Jan. 30, 2020, and 10-2021-0011975, filed on Jan. 28, 2021 in the Korean Intellectual Property Office, the entire content of each of which is hereby incorporated by reference.

### BACKGROUND

### 1. Field

One or more aspects of embodiments of the present disclosure relate to a light-emitting device and an electronic apparatus including the same.

### 2. Description of Related Art

Light-emitting devices (for example, organic light-emitting devices) may include a first electrode located on a substrate, and a hole transport region, an emission layer, an electron transport region, and a second electrode sequentially stacked on the first electrode. Holes provided from the first electrode may move toward the emission layer through the hole transport region, and electrons provided from the second electrode may move toward the emission layer through the electron transport region. Carriers (such as the holes and the electrons), may recombine in the emission layer to produce excitons. These excitons may transition from an excited state to the ground state to thereby generate light.

### SUMMARY

One or more aspects of embodiments of the present disclosure are directed toward a light-emitting device with low driving voltage, excellent external quantum efficiency, and/or improved lifespan characteristics; and an electronic apparatus including the same.

Additional aspects will be set forth in part in the description that follows and, in part, will be apparent from the description, or may be learned by practice of the presented embodiments of the disclosure.

One or more embodiments of the present disclosure provide a light-emitting device including:
a first electrode,
a second electrode facing the first electrode, and
an interlayer arranged between the first electrode and the second electrode and including an emission layer,
wherein the emission layer includes a host, a first dopant, and a second dopant,
the host, the first dopant, and the second dopant are different from one another,
the first dopant is a phosphorescent dopant,
a Stokes shift (e.g., Stoke's shift) of the second dopant is less than or equal to 15 nm,
a spectral overlap integral of an emission spectrum of the first dopant and an absorption spectrum of the second dopant is greater than or equal to 1.5×10¹⁵ M⁻¹ cm⁻¹ nm⁴, and
the spectral overlap integral is evaluated by Equation 1:

$$J ( λ ) = {\int }_{0}^{∞} ε ( λ ) {λ}^{4} {F}_{D} ( λ ) d λ . \qquad Equation 1$$

In Equation 1,
J(λ) is the spectral overlap integral of the emission spectrum of the first dopant and the absorption spectrum of the second dopant in units of M⁻¹ cm⁻¹ nm⁴.
ε(A) is a molar extinction coefficient of the second dopant calculated from the absorption spectrum of the second dopant in units of M⁻¹ cm⁻¹,
λ is the wavelength of the emission spectrum and the absorption spectrum in units of nm,
F_{D}(A) is the normalized emission spectrum of the first dopant, wherein the emission spectrum of the first dopant is an emission spectrum evaluated at room temperature in a 5 μM (5 μmol/L) toluene solution of the first dopant, and
the absorption spectrum of the second dopant is an absorption spectrum evaluated at room temperature in a 5 μM (5 μmol/L) toluene solution of the second dopant.

One or more embodiments of the present disclosure provide an electronic apparatus including the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram schematically illustrating a structure of a light-emitting device according to an embodiment;

FIG. 2 is a diagram schematically illustrating a structure of an electronic apparatus according to an embodiment; and

FIG. 3 is a diagram schematically illustrating a structure of an electronic apparatus according to another embodiment.

FIG. 4 is combined plot of the emission spectra of Example Compounds D1-1, D1-2 and D1-3 (“D1-1”, “D1-2” and “D1-3”) and an absorption spectrum of Example Compound D2-1 (“D2-1(Abs)”).

### DETAILED DESCRIPTION

Reference will now be made in more detail to embodiments, examples of which are illustrated in the accompanying drawings, wherein like reference numerals refer to like elements throughout, and duplicative descriptions thereof may not be provided. In this regard, the present embodiments may have different forms and should not be construed as being limited to the descriptions set forth herein. Accordingly, the embodiments are merely described below, by referring to the drawings, to explain aspects of the present description. As used herein, the term “and/or” includes any and all combinations of one or more of the associated listed items. Throughout the disclosure, the expression “at least one of a, b or c” may indicate only a, only b, only c, both a and b, both a and c, both b and c, all of a, b, and c, or variations thereof.

As used herein, expressions such as “at least one of,” “one of,” and “selected from,” when preceding a list of elements, modify the entire list of elements and do not modify the individual elements of the list. Further, the use of “may” when describing embodiments of the present disclosure refers to “one or more embodiments of the present disclosure”.

The disclosure may take the form of diverse and/or modified embodiments, and selected embodiments are illustrated in the drawings and described in the detailed description. Various effects and characteristics of the disclosure, and a method of accomplishing the same will be apparent when referring to the embodiments as described with reference to the drawings. However, the disclosure may be embodied in many different forms and should not be construed as being limited to the embodiments set forth herein.

One or more embodiments of the disclosure will be described below in more detail with reference to the accompanying drawings. Components that are substantially the same or are in correspondence with each other may have the same reference numeral regardless of the drawing number, and redundant explanations may be omitted.

An expression used in the singular encompasses the expression of the plural, unless it has a clearly different meaning in the context.

It will be further understood that the terms “includes,” “including,” “comprises,” and/or “comprising,” as used herein specify the presence of stated features or elements, but do not preclude the presence or addition of one or more other features or elements.

It will be understood that when a layer, region, or component is referred to as being “on” or “onto” another layer, region, or component, it may be directly or indirectly formed on the other layer, region, or component. For example, intervening layers, regions, or components may be present. When an element is referred to as being “directly on,” “directly connected to,” or “directly coupled to” another element, there are no intervening elements present.

The sizes of elements in the drawings may be exaggerated or reduced for convenience of explanation, and the disclosure is not limited thereto.

The expression “(an interlayer) includes a compound represented by Formula 1” as used herein may include a case in which “(an interlayer) includes identical compounds (e.g., a single compound) represented by Formula 1” and a case in which “(an interlayer) includes two or more different compounds represented by Formula 1.”

A light-emitting device may include: a first electrode; a second electrode facing the first electrode; and an interlayer arranged between the first electrode and the second electrode and including an emission layer, wherein the emission layer may include a host, a first dopant, and a second dopant.

The host, the first dopant, and the second dopant, which are included in the emission layer, may be different from each other.

The host may include a compound different from the first dopant and the second dopant. The host and examples thereof may be the same as described below.

The first dopant may be a phosphorescent dopant. For example, the first dopant may be to emit phosphorescence according to a phosphorescence emission mechanism.

In an embodiment, the first dopant may be a transition metal-containing organometallic compound. For example, the transition metal may be a first-row transition metal of the Periodic Table of Elements, a second-row transition metal of the Periodic Table of Elements, or a third-row transition metal of the Periodic Table of Elements. In an embodiment, the transition metal may be a metal having an atomic weight of 40 or more. In an embodiment, the transition metal may be iridium (Ir), platinum (Pt), osmium (Os), titanium (Ti), zirconium (Zr), hafnium (Hf), europium (Eu), terbium (Tb), thulium (Tm), or rhodium (Rh).

A Stokes shift of the second dopant may be less than or equal to 15 nm.

In an embodiment, the Stokes shift of the second dopant may be greater than or equal to 5 nm and less than or equal to 15 nm.

In some embodiments, a spectral overlap integral of an emission spectrum of the first dopant and an absorption spectrum of the second dopant may be greater than or equal to 1.5×10¹⁵ M⁻¹ cm⁻¹ nm⁴. The spectral overlap integral may be evaluated by Equation 1:

$$J ( λ ) = {\int }_{0}^{∞} ε ( λ ) {λ}^{4} {F}_{D} ( λ ) d λ . \qquad Equation 1$$

In Equation 1,
J(λ) is the spectral overlap integral of the emission spectrum of the first dopant and the absorption spectrum of the second dopant in units of M⁻¹ cm⁻¹ nm⁴.
ε(A) is a molar extinction coefficient of the second dopant calculated from the absorption spectrum of the second dopant in units of M⁻¹ cm⁻¹,
λ is the wavelength of the emission spectrum and the absorption spectrum in units of nm, and
F_{D}(λ) is the normalized emission spectrum of the first dopant, wherein the emission spectrum of the first dopant is an emission spectrum evaluated at room temperature in a 5 μM (5 μmol/L) toluene solution of the first dopant, and
the absorption spectrum of the second dopant is an absorption spectrum evaluated at room temperature in a 5 μM (5 μmol/L) toluene solution of the second dopant.

In an embodiment, the spectral overlap integral may be greater than or equal to 1.5×10¹⁵ M⁻¹ cm⁻¹ nm⁴ and less than or equal to 2.0×10¹⁵ M⁻¹ cm⁻¹ nm⁴.

A Forster radius of the second dopant with respect to the first dopant may be greater than or equal to 4.5 nm, for example, greater than or equal to 5 nm and less than or equal to 10 nm. When the Forster radius of the second dopant with respect to the first dopant satisfies the above-described range, exciton transfer efficiency from the first dopant to the second dopant may be improved, and thus emission efficiency and/or lifespan of the light-emitting device may be improved.

An emission peak wavelength in the emission spectrum of the first dopant may be greater than or equal to 430 nm and less than or equal to 470 nm. The emission peak wavelength in the emission spectrum of the first dopant may be observed from the emission spectrum of the first dopant as evaluated in the same manner described above.

The emission peak wavelength in the emission spectrum of the first dopant may be greater than an absorption peak wavelength in the absorption spectrum of the second dopant. The emission peak wavelength in the emission spectrum of the first dopant and the absorption peak wavelength in the absorption spectrum of the second dopant may be respectively observed from the emission spectrum of the first dopant and the absorption spectrum of the second dopant, which are evaluated in the same manner described above. In an embodiment, an absolute value of a difference between the emission peak wavelength in the emission spectrum of the first dopant and the absorption peak wavelength in the absorption spectrum of the second dopant may be greater than or equal to 5 nm and less than or equal to 50 nm.

A lowest excitation triplet energy level (T₁) of the first dopant may be greater than or equal to a lowest excitation singlet energy level (S₁) of the second dopant. The lowest excitation triplet energy level of the first dopant may be calculated by comparing a room-temperature emission spectrum with a low-temperature emission spectrum of the first dopant in a solution (for example, in a toluene solution), and the lowest excitation singlet energy level of the second dopant may be calculated from a room-temperature emission spectrum of the second dopant. In an embodiment, an absolute value of a difference between the lowest excitation triplet energy level of the first dopant and the lowest excitation singlet energy level of the second dopant may be greater than or equal to 0.0 eV and less than or equal to 1.0 eV, for example, greater than or equal to 0.0 eV and less than or equal to 0.3 eV. When the lowest excitation triplet energy level of the first dopant and the lowest excitation singlet energy level of the second dopant satisfy the above-described relationship, excitons may be easily transferred from the first dopant to the second dopant, and thus emission efficiency and/or lifespan of the light-emitting device may be improved.

In an embodiment, excitons may transition from a lowest excitation triplet energy level (T₁) of the first dopant to a lowest excitation singlet energy level (S₁) of the second dopant, and excitons at the lowest excitation singlet energy level (S₁) of the second dopant may transition to the ground state, and light may be thus emitted from the emission layer. In this case, among the total emission components emitted from the emission layer, the proportion of emission components emitted from the second dopant may be greater than or equal to 80%, for example, greater than or equal to 90% and less than or equal to 100% (e.g., the second dopant may be to emit greater than or equal to 80%, for example, greater than or equal to 90% and less than or equal to 100%, of the total emission components to be emitted from the emission layer). In some embodiments, among the total emission components emitted from the emission layer, the proportion of emission components emitted from the first dopant may be less than 20%, for example, greater than or equal to 0% and less than 20% (e.g., the first dopant may be to emit less than 20%, for example, greater than or equal to 0% and less than 20%, of the total emission components to be emitted from the emission layer).

An emission peak wavelength in an emission spectrum of the second dopant may be greater than or equal to 420 nm and less than or equal to 470 nm. The emission peak wavelength in the emission spectrum of the second dopant may be observed using the same method used to observe the emission peak wavelength in the emission spectrum of the first dopant.

In an embodiment, the emission layer may be to emit blue light having an emission peak wavelength of greater than or equal to 420 nm and less than or equal to 470 nm. In an embodiment, the emission layer may be to emit blue light having a CIEₓ color coordinate of greater than or equal to 0.115 and less than or equal to 0.135 (for example, greater than or equal to 0.120 and less than or equal to 0.130) and a CIE_{y} color coordinate of greater than or equal to 0.120 and less than or equal to 0.140 (for example, greater than or equal to 0.125 and less than or equal to 0.135). 80% or more, for example, 90% or more and 100% or less, of the total emission components of the blue light may be light emitted from the second dopant.

A sum of an amount of the first dopant and an amount of the second dopant may be less than an amount of the host. The amount may be expressed as a weight or percent (proportional) weight. In an embodiment, the sum of an amount of the first dopant and an amount of the second dopant may be 0.1 parts by weight to 30 parts by weight, 1 parts by weight to 20 parts by weight, or 5 parts by weight to 15 parts by weight, based on 100 parts by weight of the emission layer.

A weight ratio of the first dopant to the second dopant in the emission layer may be in a range of 1:9 to 9:1, 2:8 to 8:2, 3:7 to 7:3, or 4:6 to 6:4.

When the amounts of the first dopant and the second dopant and the weight ratio of the first dopant to the second dopant in the emission layer each satisfy the above-described ranges, quenching may be substantially prevented or reduced, and thus a light-emitting device having excellent emission efficiency and/or excellent lifespan may be provided.

In an embodiment, the emission layer may include (e.g., consist of) the host, the first dopant, and the second dopant, as described above.

As described above, because the emission layer of the light-emitting device includes the host, the first dopant, and the second dopant and satisfies the following conditions below, e.g.:
a) the first dopant is a phosphorescent dopant,
b) the Stokes shift of the second dopant is less than or equal to 15 nm, and
c) the spectral overlap integral of the emission spectrum of the first dopant and the absorption spectrum of the second dopant is greater than or equal to 1.5×10¹⁵ M⁻¹ cm⁻¹ nm⁴,
the Forster resonance energy transfer (FRET) efficiency from the first dopant to the second dopant may be improved, a Forster radius of the second dopant with respect to the first dopant may increase, and thus the emission efficiency (for example, external quantum efficiency) and/or lifespan of the light-emitting device may be improved.

In the light-emitting device,
the first electrode may be an anode,
the second electrode may be a cathode,
the interlayer may further include a hole transport region located between the first electrode and the emission layer, and an electron transport region located between the emission layer and the second electrode,
the hole transport region may include a hole injection layer, a hole transport layer, an emission auxiliary layer, an electron blocking layer, or any combination thereof, and
the electron transport region may include a buffer layer, a hole blocking layer, an electron control layer, an electron transport layer, an electron injection layer, or any combination thereof.

In an embodiment, the light-emitting device may further include a capping layer located outside the first electrode and/or outside the second electrode.

In an embodiment, the light-emitting device may further include at least one of a first capping layer located outside the first electrode or a second capping layer located outside the second electrode. The first capping layer and/or the second capping layer may be the same as described in the present specification.

According to another aspect, an electronic apparatus including the light-emitting device is provided. The electronic apparatus may further include a thin-film transistor. In one or more embodiments, the electronic apparatus may further include a thin-film transistor including a source electrode and a drain electrode, and the first electrode of the light-emitting device may be electrically connected to the source electrode or the drain electrode. In an embodiment, the electronic apparatus may further include a color filter, a color conversion layer, a touch screen layer, a polarizing layer, or any combination thereof. The electronic apparatus may be the same as described in the present specification.

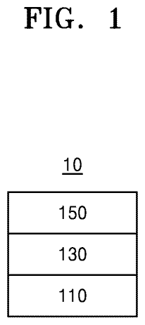

### Description of FIG. 1

FIG. 1 is a schematic cross-sectional view of a light-emitting device 10 according to an embodiment. The light-emitting device 10 includes a first electrode 110, an interlayer 130, and a second electrode 150.

Hereinafter, a structure of the light-emitting device 10 according to an embodiment and a method of manufacturing the light-emitting device 10 will be described in connection with FIG. 1.

### First Electrode 110

In FIG. 1, a substrate may be additionally located under the first electrode 110 and/or above the second electrode 150. The substrate may be a glass substrate and/or a plastic substrate. The substrate may be a flexible substrate. In one or more embodiments, the substrate may include a plastic with excellent heat resistance and/or durability (such as polyimide, polyethylene terephthalate (PET), polycarbonate, polyethylene naphthalate, polyarylate (PAR), polyetherimide, or any combination thereof).

The first electrode 110 may be formed by, for example, depositing or sputtering a material for forming the first electrode 110 on the substrate. When the first electrode 110 is an anode, a high work function material that can easily inject holes may be used as a material for forming the first electrode 110.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In one or more embodiments, when the first electrode 110 is a semi-transmissive electrode or a reflective electrode, magnesium (Mg), silver (Ag), aluminum (Al), aluminum-lithium (Al—Li), calcium (Ca), magnesium-indium (Mg—In), magnesium-silver (Mg—Ag), or any combination thereof may be used as a material for forming the first electrode 110.

The first electrode 110 may have a single-layered structure including (e.g., consisting of) a single layer, or a multi-layered structure including a plurality of layers. In an embodiment, the first electrode 110 may have a three-layered structure of ITO/Ag/ITO.

### Interlayer 130

The interlayer 130 is located on the first electrode 110. The interlayer 130 may include an emission layer.

The interlayer 130 may further include a hole transport region located between the first electrode 110 and the emission layer, and/or an electron transport region located between the emission layer and the second electrode 150.

The interlayer 130 may further include, in addition to one or more suitable organic materials, inorganic materials (such as quantum dots).

In one or more embodiments, the interlayer 130 may include: i) two or more emitting units sequentially stacked between the first electrode 110 and the second electrode 150, and ii) a charge generation layer located between the two emitting units. When the interlayer 130 includes the emitting unit and the charge generation layer as described above, the light-emitting device 10 may be a tandem light-emitting device.

### Hole Transport Region in Interlayer 130

The hole transport region may have: i) a single-layered structure including (e.g., consisting of) a single layer including (e.g., consisting of) a single material, ii) a single-layered structure including (e.g., consisting of) a single layer including a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer, a hole injection layer/hole transport layer/emission auxiliary layer, a hole injection layer/emission auxiliary layer, a hole transport layer/emission auxiliary layer, or a hole injection layer/hole transport layer/electron blocking layer, wherein the constituting layers of each structure are stacked sequentially from the first electrode 110.

The hole transport region may include a compound represented by Formula 201, a compound represented by Formula 202, or any combination thereof:

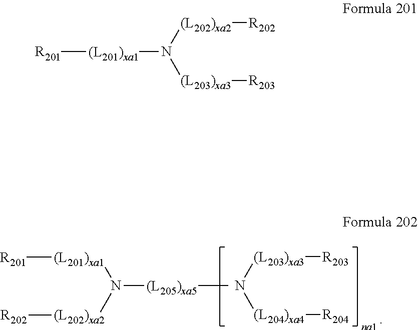

In Formulae 201 and 202,
L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
L₂₀₅ may be *—O—*, *—S—*, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,
xa1 to xa4 may each independently be an integer from 0 to 5,
xa5 may be an integer from 1 to 10,
R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, for example to form a C₈-C₆ polycyclic group unsubstituted or substituted with at least one R₁₀ₐ (for example, a carbazole group) (for example, see Compound HT16 and/or the like),
R₂₀₃ and R₂₀₄ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and
na1 may be an integer from 1 to 4.

In an embodiment, Formulae 201 and 202 may each include at least one of the groups represented by Formulae CY201 to CY217:

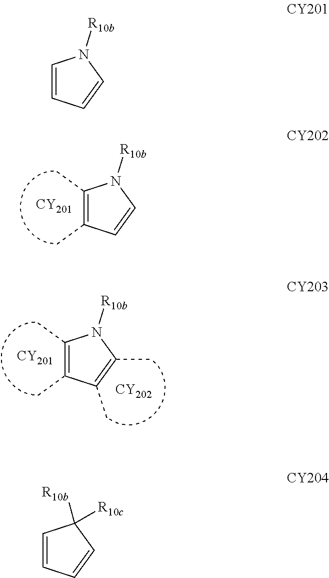

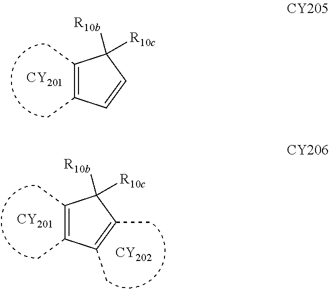

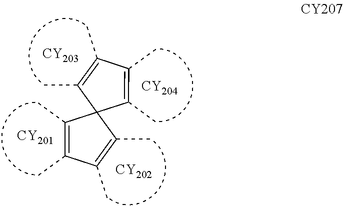

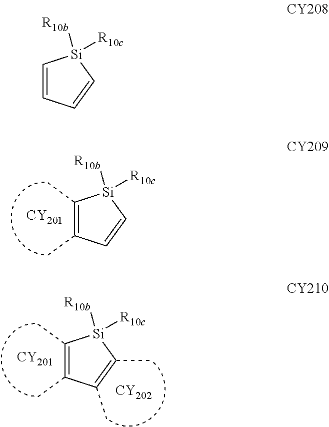

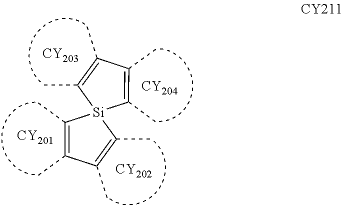

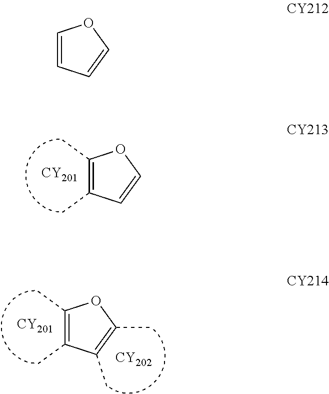

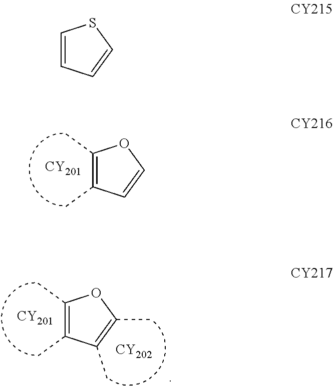

Regarding Formulae CY201 to CY217, R_{10b} and R_{10c} may each independently be the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with at least one R₁₀ₐ described herein.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, Formulae 201 and 202 may each include at least one of the groups represented by Formulae CY201 to CY203.

In an embodiment, Formula 201 may include at least one of the groups represented by Formulae CY201 to CY203 or at least one of the groups represented by Formulae CY204 to CY217.

In one or more embodiments, in Formula 201, xa1 is 1, R₂₀₁ is a group represented by one of Formulae CY201 to CY203, xa2 is 0, and R₂₀₂ is a group represented by one of Formulae CY204 to CY207.

In one or more embodiments, each of Formulae 201 and 202 may not include (e.g., may not be) the groups represented by Formulae CY201 to CY203.

In one or more embodiments, each of Formulae 201 and 202 may not include groups represented by Formulae CY201 to CY203 and may include at least one of the groups represented by Formulae CY204 to CY217.

In an embodiment, each of Formulae 201 and 202 may not include groups represented by Formulae CY201 to CY217.

In an embodiment, the hole transport region may include one of Compounds HT1 to HT46, m-MTDATA, TDATA, 2-TNATA, NPB (NPD), β-NPB, TPD, spiro-TPD, spiro-NPB, methylated-NPB, TAPC, HMTPD, 4,4′,4″-tris(N-carbazolyl)triphenylamine (TCTA), polyaniline/dodecylbenzene sulfonic acid (PANI/DBSA), poly(3,4-ethylene dioxythiophene)/poly(4-styrene sulfonate) (PEDOT/PSS), polyaniline/camphor sulfonic acid (PANI/CSA), polyaniline/poly(4-styrene sulfonate) (PANI/PSS), or any combination thereof:

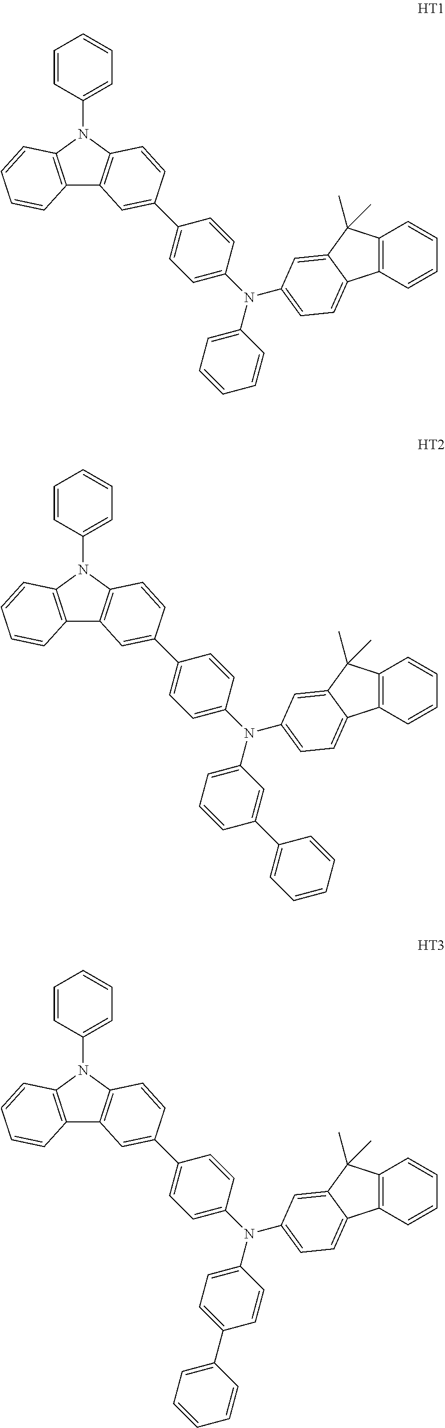 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

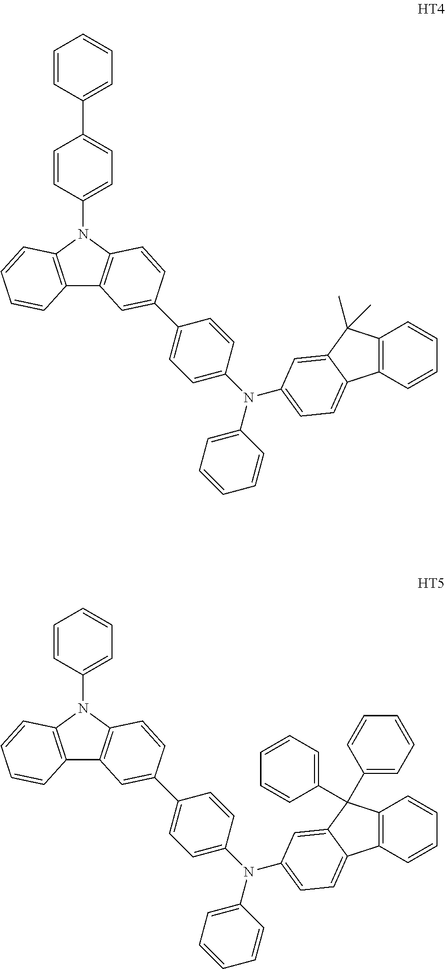 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1]

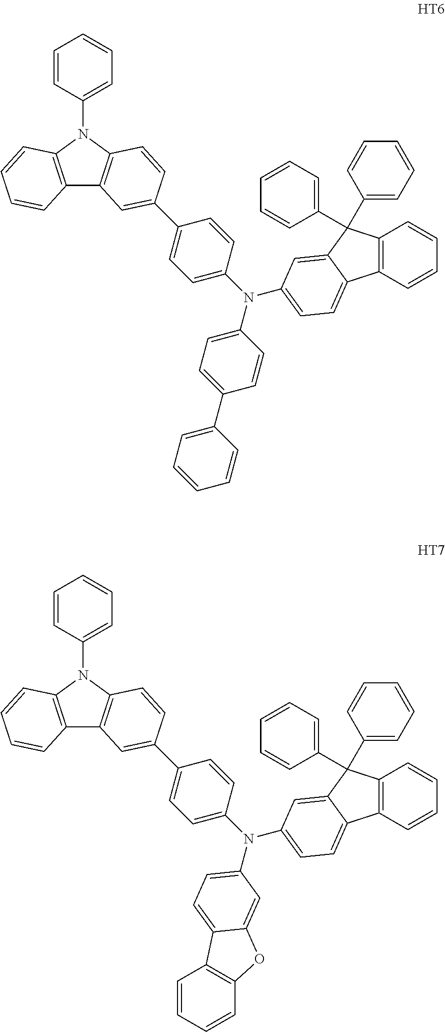 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1]

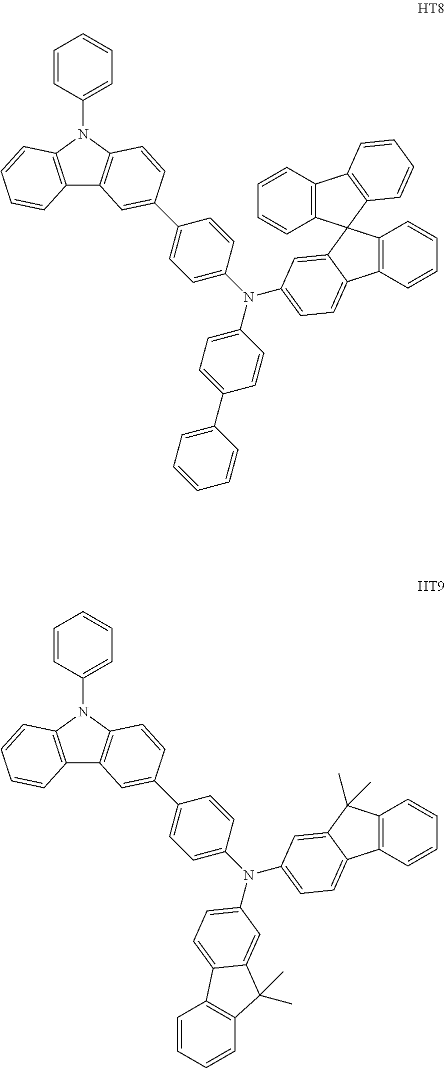 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

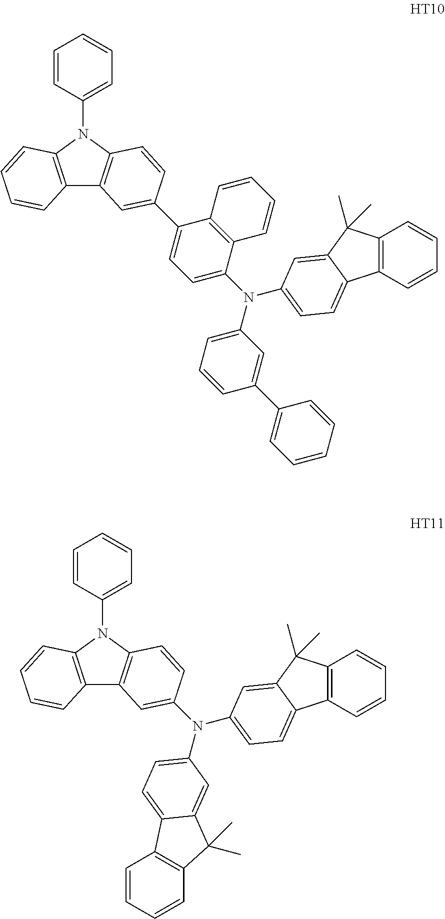 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

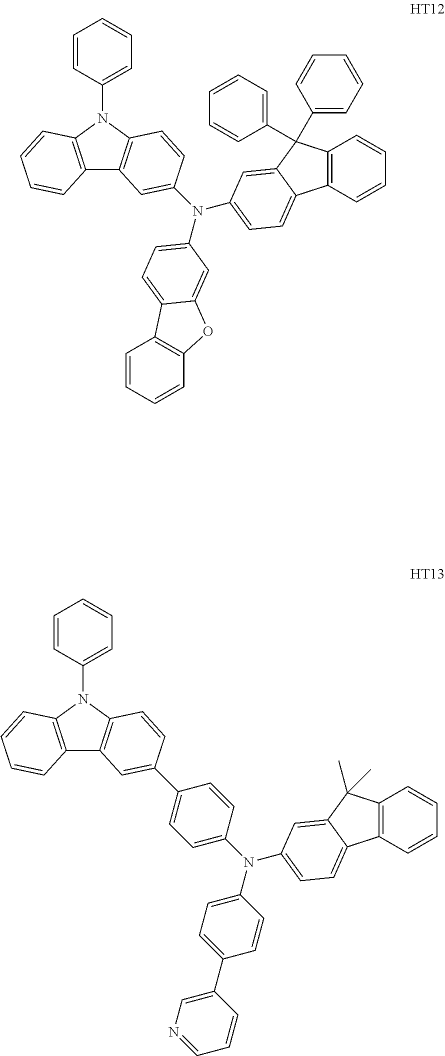 [SMILES: c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1 ; CC1(C)c2ccccc2-c2ccc(N(c3ccc(-c4cccnc4)cc3)c3ccc(-c4ccc5c(c4)c4ccccc4n5-c4ccccc4)cc3)cc21]

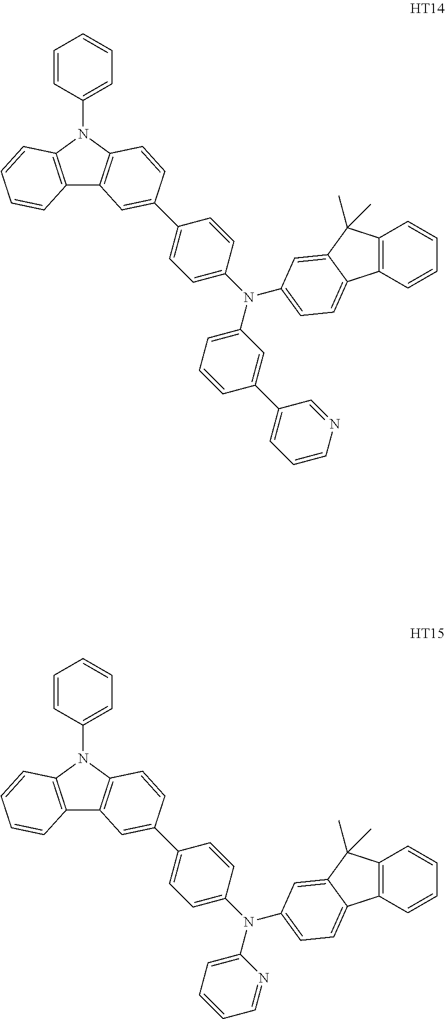 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

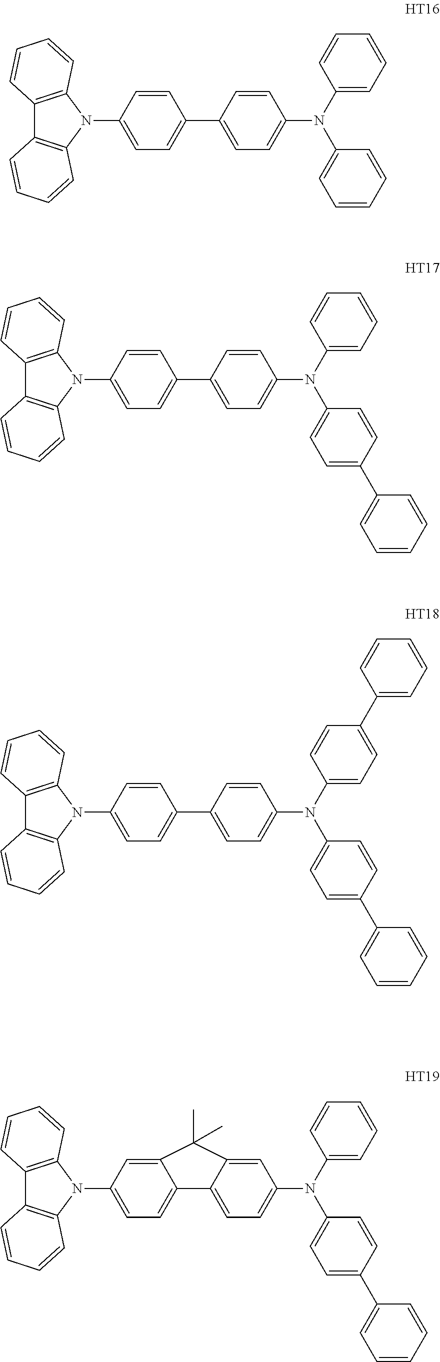 [SMILES: c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21]

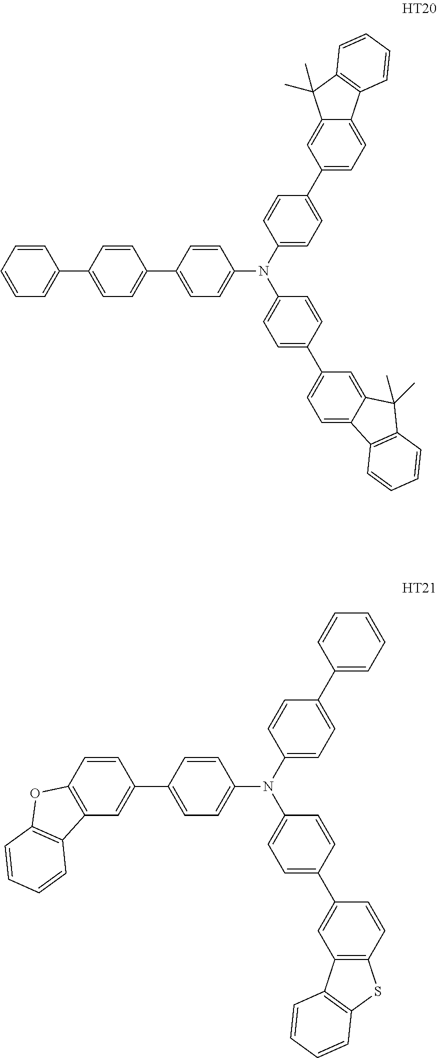 [SMILES: CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1]

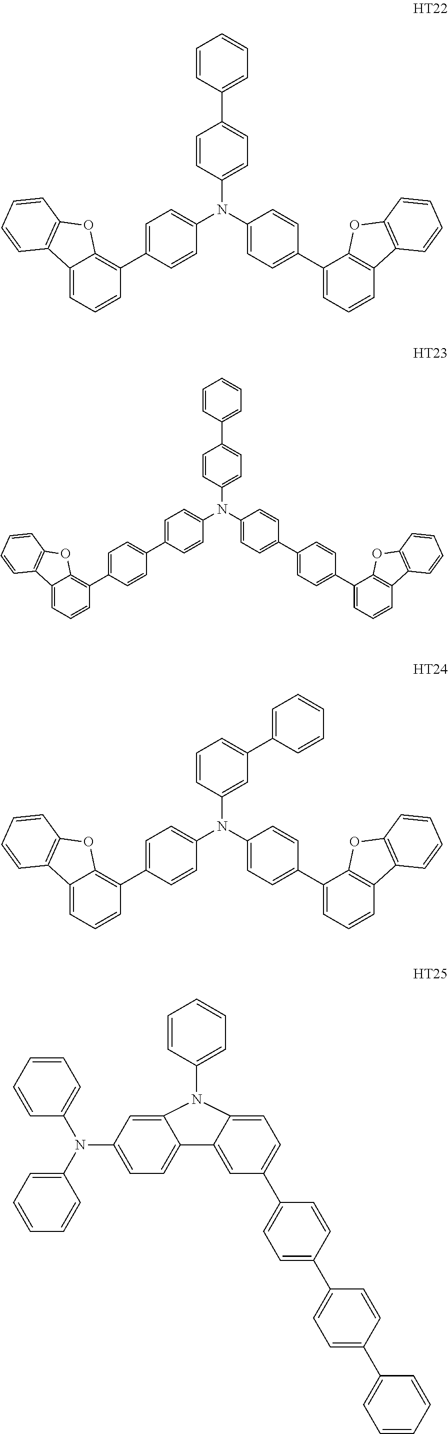 [SMILES: c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1 ; c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1]

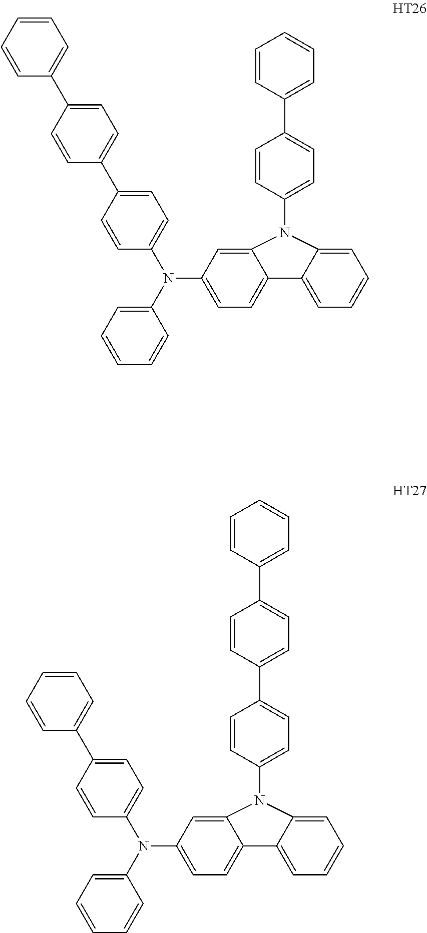 [SMILES: c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

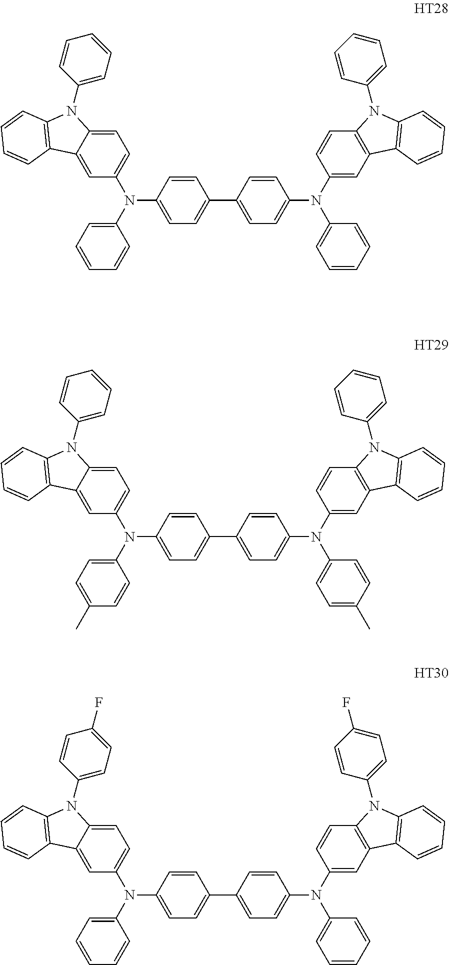 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; Cc1ccc(N(c2ccc(-c3ccc(N(c4ccc(C)cc4)c4ccc5c(c4)c4ccccc4n5-c4ccccc4)cc3)cc2)c2ccc3c(c2)c2ccccc2n3-c2ccccc2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

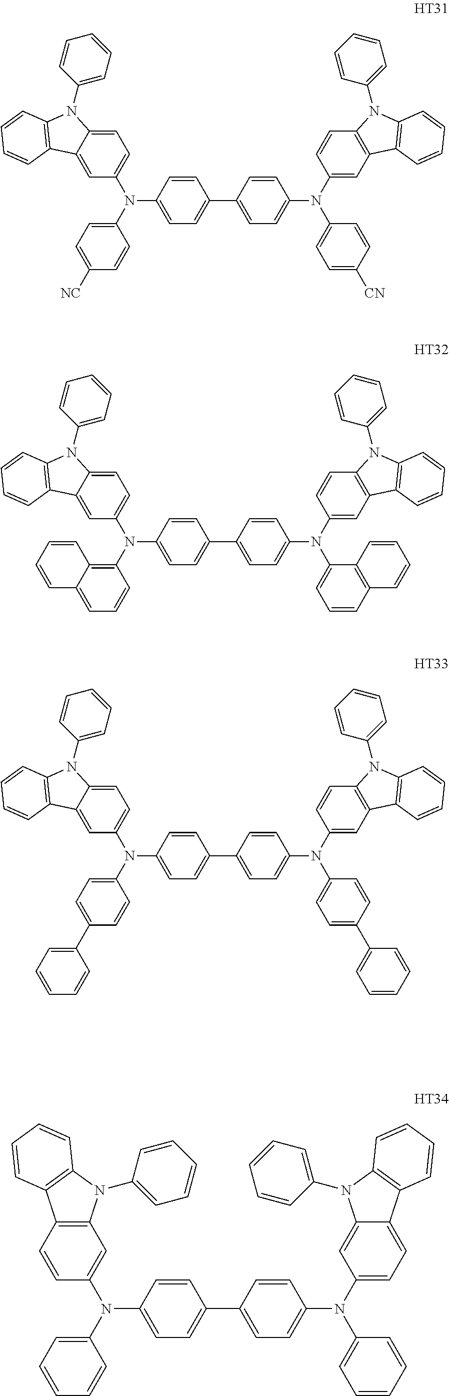 [SMILES: N#Cc1ccc(N(c2ccc(-c3ccc(N(c4ccc(C#N)cc4)c4ccc5c(c4)c4ccccc4n5-c4ccccc4)cc3)cc2)c2ccc3c(c2)c2ccccc2n3-c2ccccc2)cc1 ; c1ccc(-n2c3ccccc3c3cc(N(c4ccc(-c5ccc(N(c6ccc7c(c6)c6ccccc6n7-c6ccccc6)c6cccc7ccccc67)cc5)cc4)c4cccc5ccccc45)ccc32)cc1 ; c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1]

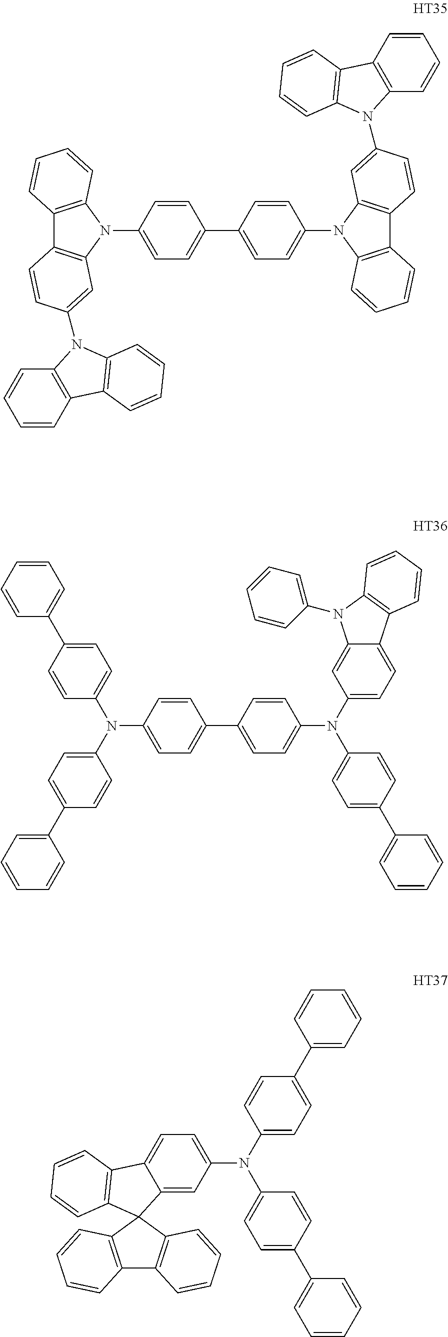 [SMILES: c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1]

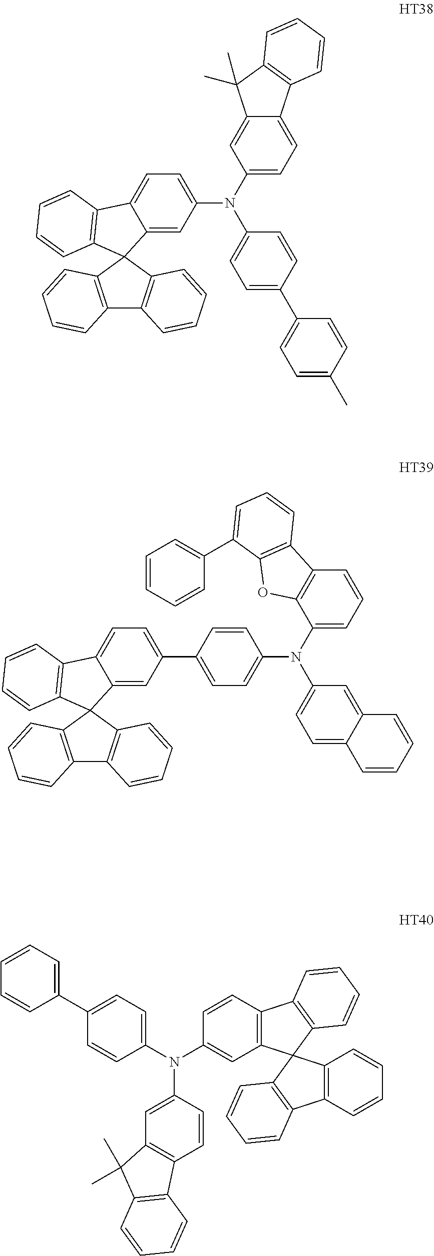 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21]

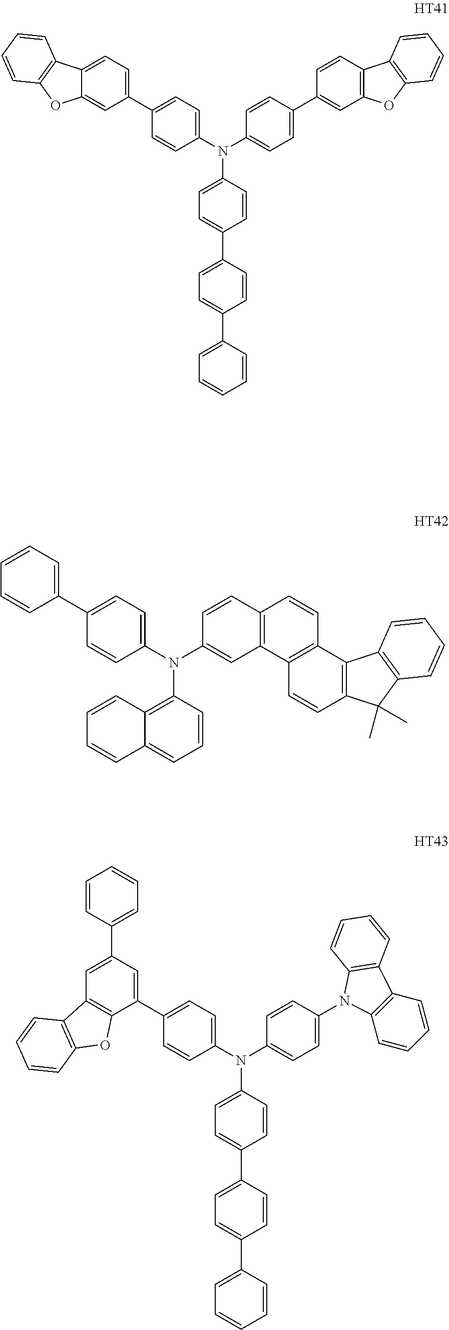 [SMILES: c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1 ; CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-c5cc(-c6ccccc6)cc6c5oc5ccccc56)cc4)c4ccc(-n5c6ccccc6c6ccccc65)cc4)cc3)cc2)cc1]

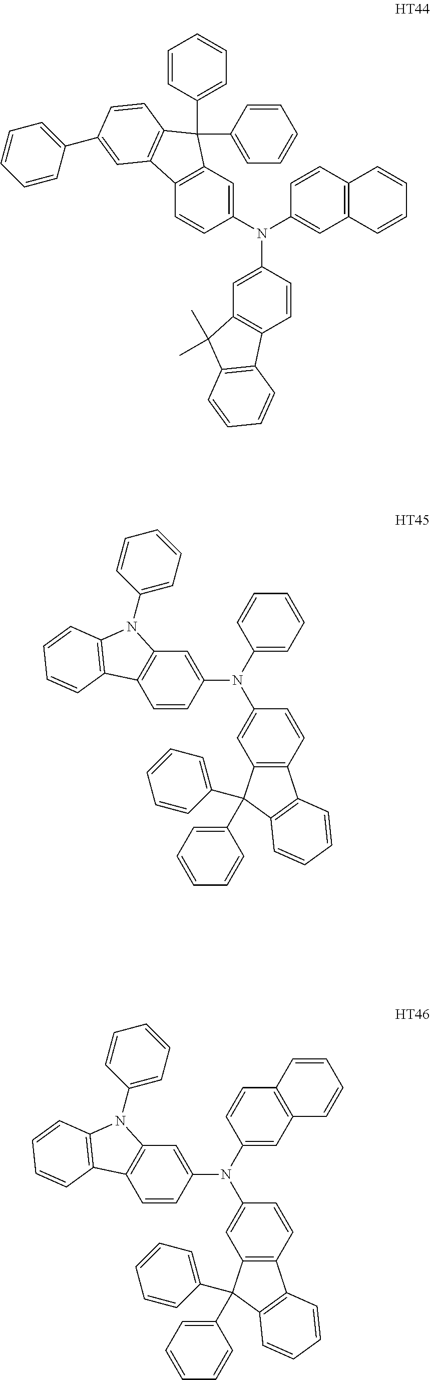 [SMILES: CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; c1ccc(-n2c3ccccc3c3ccc(N(c4ccc5c(c4)C(c4ccccc4)(c4ccccc4)c4ccccc4-5)c4ccc5ccccc5c4)cc32)cc1]

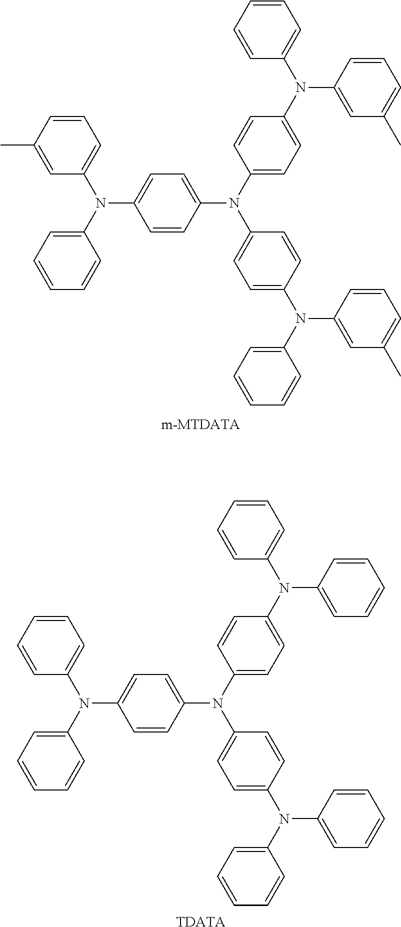

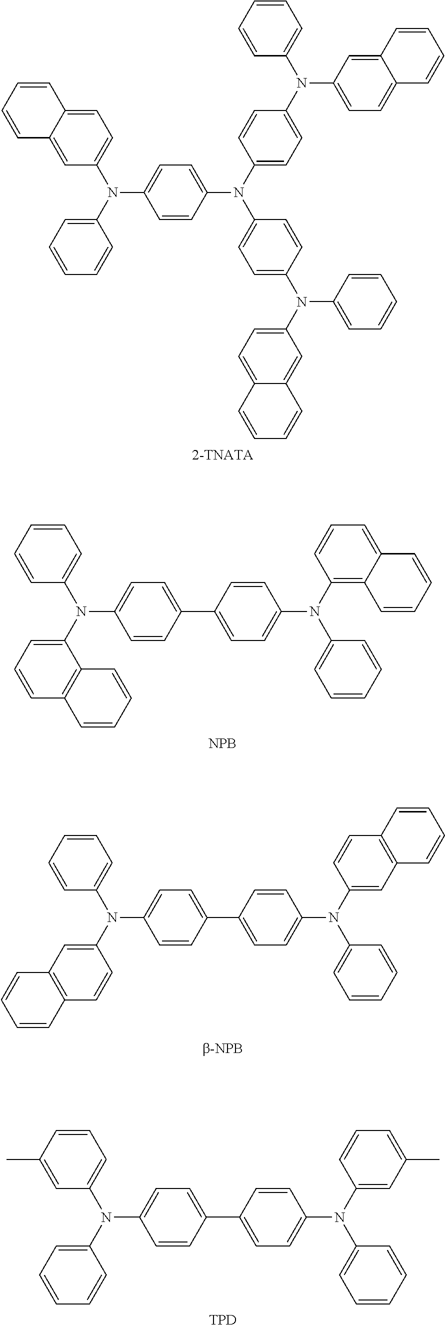

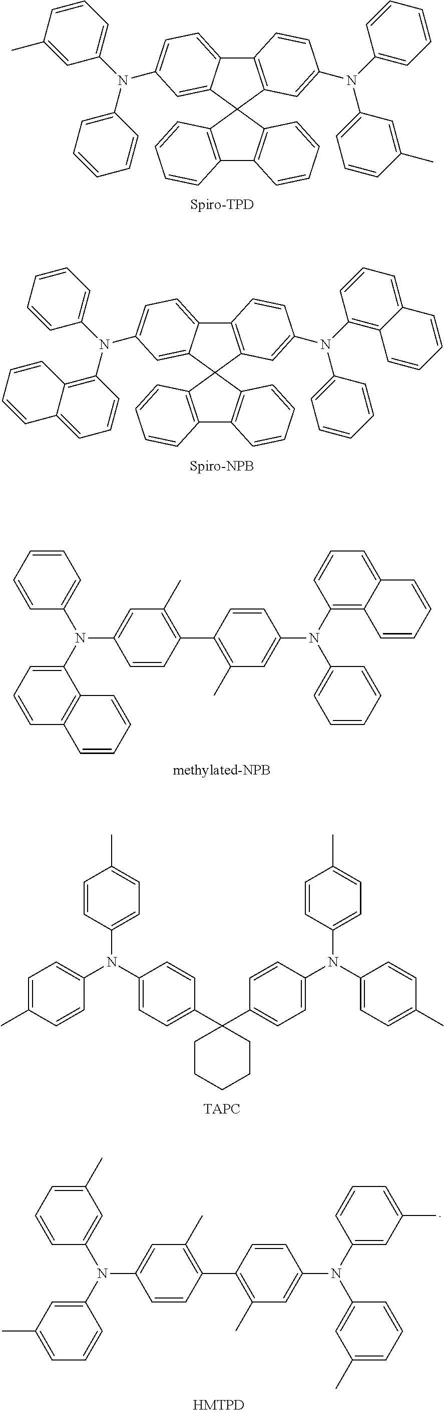

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase the light-emission efficiency of a device by compensating for an optical resonance distance of the wavelength of light emitted by an emission layer, and the electron blocking layer may prevent or reduce leakage of electrons from an emission layer to a hole transport region. The emission auxiliary layer and the electron blocking layer may each independently include the same materials described above.

p-Dopant

The hole transport region may further include, in addition to these materials, a charge-generating material for the improvement of conductive properties. The charge-generating material may be substantially uniformly or non-uniformly dispersed in the hole transport region (for example, in the form of a single layer including (e.g., consisting of) a charge-generating material).

The charge-generating material may be, for example, a p-dopant.

In an embodiment, a lowest unoccupied molecular orbital (LUMO) energy level of the p-dopant may be −3.5 eV or less.

In an embodiment, the p-dopant may include a quinone derivative, a cyano group-containing compound, a compound containing an element EL1 and an element EL2, or any combination thereof.

Non-limiting examples of the quinone derivative include TCNQ and/or F4-TCNQ.

Non-limiting examples of the cyano group-containing compound include HAT-CN and/or a compound represented by Formula 221:

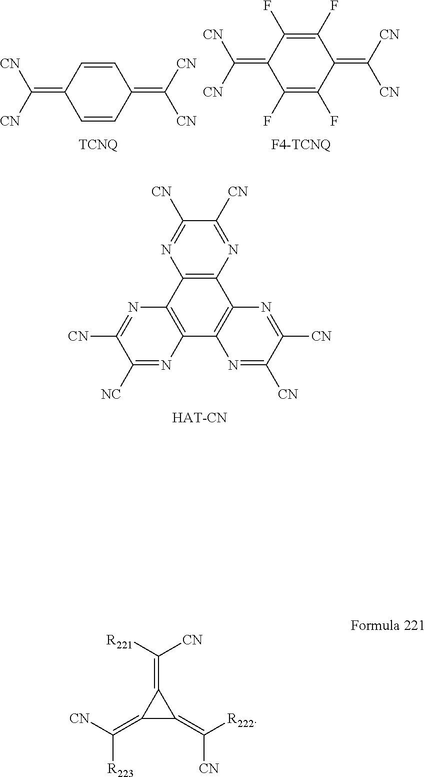

In Formula 221,
R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
at least one of R₂₂₁ to R₂₂₃ may each independently be a C₃-C₆₀ carbocyclic group or a C₁-C₆₀ heterocyclic group, each substituted with: a cyano group; —F; —Cl; —Br; —I; a C₁-C₂₀ alkyl group substituted with a cyano group, —F, —Cl, —Br, —I, or any combination thereof; or any combination thereof.

Regarding the compound containing the element EL1 and the element EL2, the element EL1 may be a metal, a metalloid, or a combination thereof, and the element EL2 may be a non-metal, a metalloid, or a combination thereof.

Non-limiting examples of the metal include: an alkali metal (for example, lithium (Li), sodium (Na), potassium (K), rubidium (Rb), cesium (Cs), and/or the like); an alkaline earth metal (for example, beryllium (Be), magnesium (Mg), calcium (Ca), strontium (Sr), barium (Ba), and/or the like); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), and/or the like); a post-transition metal (for example, zinc (Zn), indium (In), tin (Sn), and/or the like); and/or a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), and/or the like).

Non-limiting examples of the metalloid include silicon (Si), antimony (Sb), and/or tellurium (Te).

Non-limiting examples of the non-metal include oxygen (O) and/or a halogen (for example, F, Cl, Br, I, etc.).

In an embodiment, non-limiting examples of the compound containing the element EL1 and the element EL2 include a metal oxide, a metal halide (for example, a metal fluoride, a metal chloride, a metal bromide, or a metal iodide), a metalloid halide (for example, a metalloid fluoride, a metalloid chloride, a metalloid bromide, or a metalloid iodide), and/or a metal telluride.

Non-limiting examples of the metal oxide include a tungsten oxide (for example, WO, W₂O₃, WO₂, WO₃, and/or W₂O₅), a vanadium oxide (for example, VO, V₂O₃, VO₂, and/or V₂O₅), a molybdenum oxide (MoO, Mo₂O₃, MoO₂, MoO₃, and/or Mo₂O₅), and/or a rhenium oxide (for example, ReO₃).

Non-limiting examples of the metal halide include an alkali metal halide, an alkaline earth metal halide, a transition metal halide, a post-transition metal halide, and/or a lanthanide metal halide.

Non-limiting examples of the alkali metal halide include LiF, NaF, KF, RbF, CsF, LiCl, NaCl, KCl, RbCl, CsCl, LiBr, NaBr, KBr, RbBr, CsBr, LiI, NaI, KI, RbI, and/or CsI.

Non-limiting examples of the alkaline earth metal halide include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, and/or BaI₂.

Non-limiting examples of the transition metal halide include a titanium halide (for example, TiF₄, TiCl₄, TiBr₄, and/or TiI₄), a zirconium halide (for example, ZrF₄, ZrCl₄, ZrBr₄, and/or ZrI₄), a hafnium halide (for example, HfF₄, HfCl₄, HfBr₄, and/or HfI₄), a vanadium halide (for example, VF₃, VCl₃, VBr₃, and/or VI₃), a niobium halide (for example, NbF₃, NbCl₃, NbBr₃, and/or NbI₃), a tantalum halide (for example, TaF₃, TaCl₃, TaBr₃, and/or TaI₃), a chromium halide (for example, CrF₃, CrCl₃, CrBr₃, and/or CrI₃), a molybdenum halide (for example, MoF₃, MoCl₃, MoBr₃, and/or MoI₃), a tungsten halide (for example, WF₃, WCl₃, WBr₃, and/or WI₃), a manganese halide (for example, MnF₂, MnCl₂, MnBr₂, and/or MnI₂), a technetium halide (for example, TcF₂, TcCl₂, TcBr₂, and/or TcI₂), a rhenium halide (for example, ReF₂, ReCl₂, ReBr₂, and/or ReI₂), an iron halide (for example, FeF₂, FeCl₂, FeBr₂, and/or FeI₂), a ruthenium halide (for example, RuF₂, RuCl₂, RuBr₂, and/or RuI₂), an osmium halide (for example, OsF₂, OsCl₂, OsBr₂, and/or OsI₂), a cobalt halide (for example, CoF₂, CoCl₂, CoBr₂, and/or CoI₂), a rhodium halide (for example, RhF₂, RhCl₂, RhBr₂, and/or RhI₂), an iridium halide (for example, IrF₂, IrCl₂, IrBr₂, and/or IrI₂), a nickel halide (for example, NiF₂, NiCl₂, NiBr₂, and/or NiI₂), a palladium halide (for example, PdF₂, PdCl₂, PdBr₂, and/or PdI₂), a platinum halide (for example, PtF₂, PtCl₂, PtBr₂, and/or PtI₂), a copper halide (for example, CuF, CuCl, CuBr, and/or CuI), a silver halide (for example, AgF, AgCl, AgBr, and/or AgI), and/or a gold halide (for example, AUF, AuCl, AuBr, and/or AuI).

Non-limiting examples of the post-transition metal halide include a zinc halide (for example, ZnF₂, ZnCl₂, ZnBr₂, and/or ZnI₂), an indium halide (for example, InI₃), and/or a tin halide (for example, SnI₂).

Non-limiting examples of the lanthanide metal halide include YbF, YbF₂, YbF₃, SmF₃, YbCl, YbCl₂, YbCl₃, SmCl₃, YbBr, YbBr₂, YbBr₃, SmBr₃, YbI, YbI₂, YbI₃, and/or SmI₃.

Non-limiting examples of the metalloid halide may include an antimony halide (for example, SbCl₅).

Non-limiting examples of the metal telluride include an alkali metal telluride (for example, Li₂Te, Na₂Te, K₂Te, Rb₂Te, and/or Cs₂Te), an alkaline earth metal telluride (for example, BeTe, MgTe, CaTe, SrTe, and/or BaTe), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, and/or Au₂Te), a post-transition metal telluride (for example, ZnTe), and/or a lanthanide metal telluride (for example, LaTe, CeTe, PrTe, NdTe, PmTe, EuTe, GdTe, TbTe, DyTe, HoTe, ErTe, TmTe, YbTe, and/or LuTe).

### Emission Layer in Interlayer 130

When the light-emitting device 10 is a full-color light-emitting device, the emission layer may be patterned into a red emission layer, a green emission layer, and/or a blue emission layer, according to a sub-pixel. In one or more embodiments, the emission layer may have a stacked structure of two or more layers selected from a red emission layer, a green emission layer, and a blue emission layer, in which the two or more layers may contact each other or may be separated from each other to emit white light. In one or more embodiments, the emission layer may include two or more materials of a red light-emitting material, a green light-emitting material, and a blue light-emitting material, in which the two or more materials may be mixed with each other in a single (e.g., the same) layer to emit white light.

The emission layer may include a host, a first dopant, and a second dopant. The emission layer, the host, the first dopant, and the second dopant may each independently be the same as described above.

Examples of the host, the first dopant, and the second dopant, which may be included in the emission layer, may each independently be the same as described below.

A thickness of the emission layer may be in a range of about 100 Å to about 1,000 Å, for example, about 200 Å to about 600 Å. When the thickness of the emission layer is within this range, excellent luminescence characteristics may be obtained without a substantial increase in driving voltage.

### Host

In an embodiment, the host may be a hole transport compound.

In an embodiment, the host may be an electron transport compound.

In an embodiment, the host may include a first host and a second host, the first host and the second host may be different from each other, and i) the first host may be a hole transport compound, and the second host may be an electron transport compound, ii) both the first host and the second host may be (e.g., simultaneously) hole transport compounds, or iii) both the first host and the second host may be (e.g., simultaneously) electron transport compounds. The first host and the second host may form an exciplex.

In an embodiment, the host may form an exciplex with the first dopant.

The hole transport compound in the present specification may be a compound that does not include an electron transport moiety.

The electron transport compound in the present specification may be a compound that includes at least one electron transport moiety.

The term “electron transport moiety” used herein may include a cyano group, a phosphine oxide group, a sulfoxide group, a sulfonate group, a IT electron-deficient nitrogen-containing C₁-C₆₀ cyclic group, or any combination thereof.

In an embodiment, the host, the first host, and the second host may each independently include a compound represented by Formula 1 or a compound represented by Formula 2:

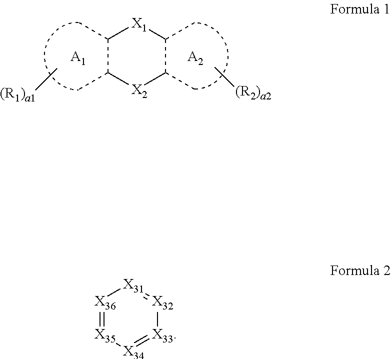

In Formulae 1 and 2,
X₁ may be O, S, N(R₃), or C(R₃)(R₄),
X₂ may be a single bond, O, S, N(R₅), or C(R₅)(R₆),
ring A₁ and ring A₂ may each independently be a C₃-C₆₀ carbocyclic group or a C₁-C₆₀ heterocyclic group,
R₁ to R₆ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —B(Q₁)(Q₂), —N(Q₁)(Q₂), —P(Q₁)(Q₂), —C(═O)(Q₁), —S(═O)(Q₁), —S(═O)₂(Q₁), —P(═O)(Q₁)(Q₂), or —P(═S)(Q₁)(Q₂),
a1 and a2 may each independently be 1, 2, 3, 4, 5, or 6,
X₃₁ may be N or C(R₃₁); X₃₂ may be N or C(R₃₂); X₃₃ may be N or C(R₃₃); X₃₄ may be N or C(R₃₄); X₃₅ may be N or C(R₃₅); X₃₆ may be N or C(R₃₆), and at least one of X₃₁ to X₃₆ may be N;
R₃₁ to R₃₆ may each independently be hydrogen, deuterium, a C₁-C₆₀ alkyl group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ, and
R₁₀ₐ and Q₁ to Q₃ may each independently be the same as described in the present specification.

In an embodiment, the first host may include a compound represented by Formula 1, and the second host may include a compound represented by Formula 2.

In one or more embodiments, the host, the first host, and the second host may each independently include a compound represented by Formula 301:

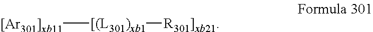

In Formula 301,
Ar₃₀₁ and L₃₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
xb11 may be 1, 2, or 3,
xb1 may be an integer from 0 to 5,
R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),
xb21 may be an integer from 1 to 5, and
Q₃₀₁ to Q₃₀₃ may each independently be the same as described in connection with Q₁.

In an embodiment, when xb11 in Formula 301 is 2 or more, the two or more of Ar₃₀₁(s) may be linked to each other via a single bond.

In an embodiment, in Formula 301, Ar₃₀₁ and L₃₀₁ may each independently be a benzene group, a naphthalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, a dibenzofuran group, a dibenzothiophene group, a pyridine group, a pyrimidine group, a triazine group, a phenanthroline group, a diazole group, or a triazole group.

In an embodiment, at least one of the R₃₀₁ (s) in Formula 301 may be —N(Q₃₀₁)(Q₃₀₂).

In an embodiment, the host, the first host, and the second host may each independently include a compound represented by Formula 301-1, a compound represented by Formula 301-2, or any combination thereof.

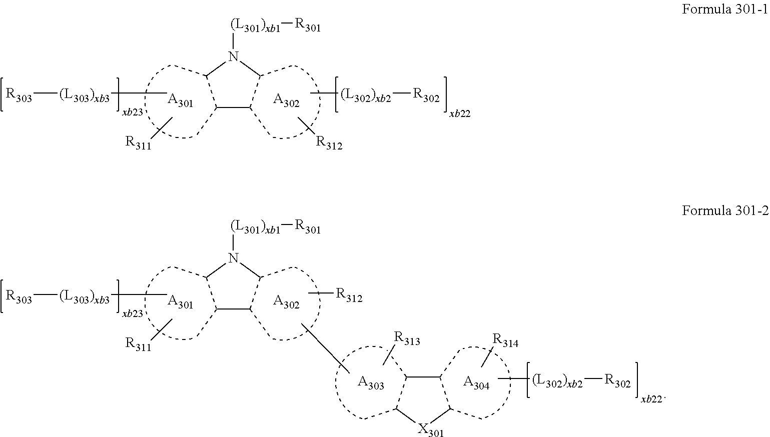

In Formulae 301-1 and 301-2,
ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,
X₃₀₁ may be O, S, N-[(L₃₀₄)_{xb4}-R₃₀₄], C(R₃₀₄)(R₃₀₅), or Si(R₃₀₄)(R₃₀₅),
xb22 and xb23 may each independently be 0, 1, or 2,
L₃₀₁, xb1, and R₃₀₁ may each independently be the same as described in the present specification,
L₃₀₂ to L₃₀₄ may each independently be the same as described in connection with L₃₀₁,
xb2 to xb4 may each independently be the same as described in connection with xb1, and
R₃₀₂ to R₃₀₅ and R₃₁₁ to R₃₁₄ may each independently be the same as described in connection with R₃₀₁.

In an embodiment, ring A₃₀₁ to ring A₃₀₄ may each independently be a benzene group, a naphthalene group, a phenanthrene group, a fluoranthene group, a triphenylene group, a pyrene group, a chrysene group, a pyridine group, a pyrimidine group, an indene group, a fluorene group, a spiro-bifluorene group, a benzofluorene group, a dibenzofluorene group, an indole group, a carbazole group, a benzocarbazole group, a dibenzocarbazole group, a furan group, a benzofuran group, a dibenzofuran group, a naphthofuran group, a benzonaphthofuran group, a dinaphthofuran group, a thiophene group, a benzothiophene group, a dibenzothiophene group, a naphthothiophene group, a benzonaphthothiophene group, or dinaphthothiophene group, each unsubstituted or substituted with at least one R₁₀ₐ.

In an embodiment, the host may include an alkaline earth metal complex, a post-transition metal complex, or any combination thereof. In an embodiment, the host may include a Be complex (for example, Compound H55) or a Mg complex. In some embodiments, the host may include a Zn complex, or any combination of the above.

In an embodiment, the host may include one of Compounds H1 to H130, 9,10-di(2-naphthyl) anthracene (ADN), 2-methyl-9,10-bis(naphthalen-2-yl) anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri (carbazol-9-yl)benzene (TCP), 3,3′-di(9H-carbazol-9-yl)-1,1′-biphenyl (mCBP), or any combination thereof:

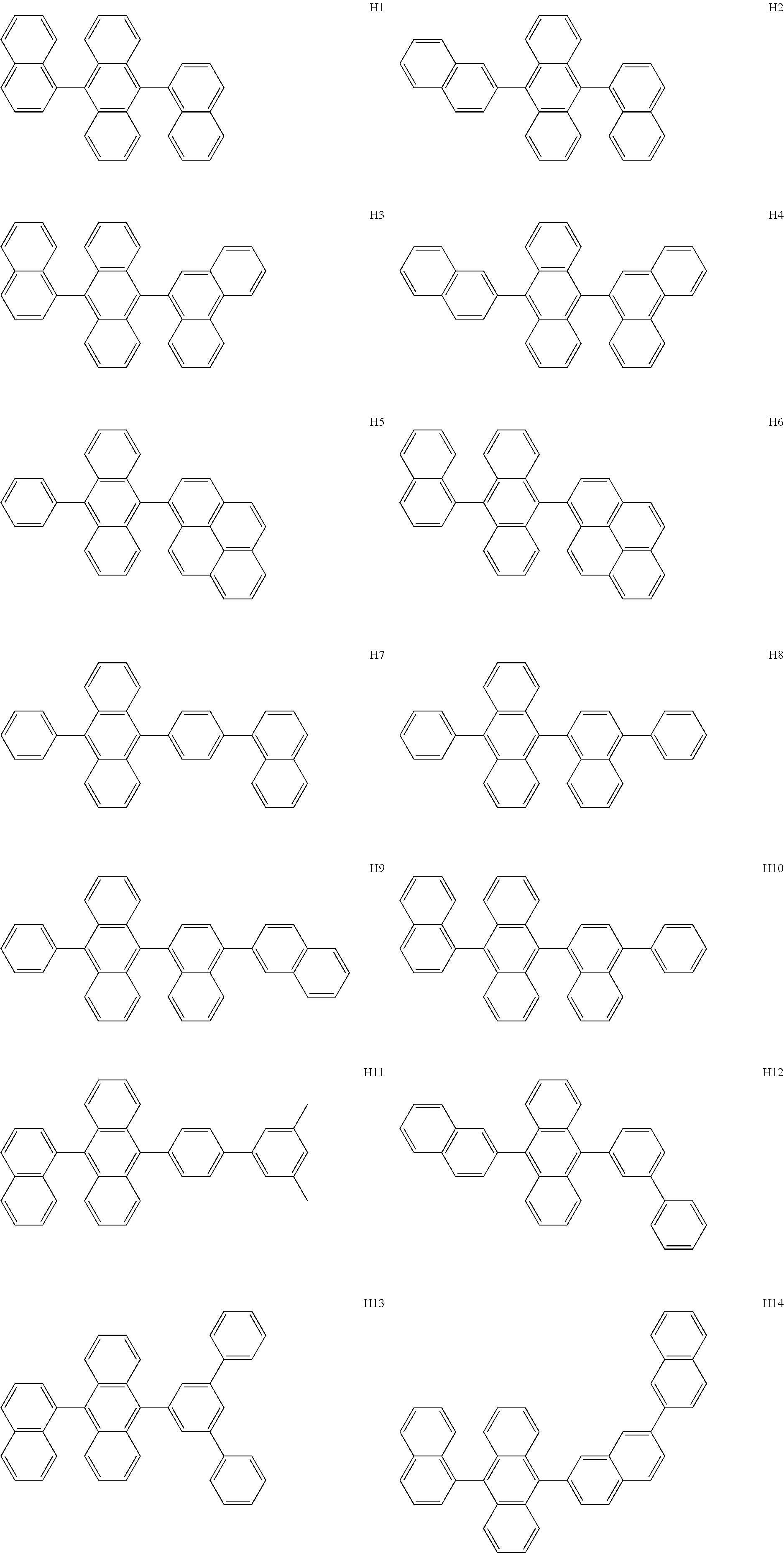

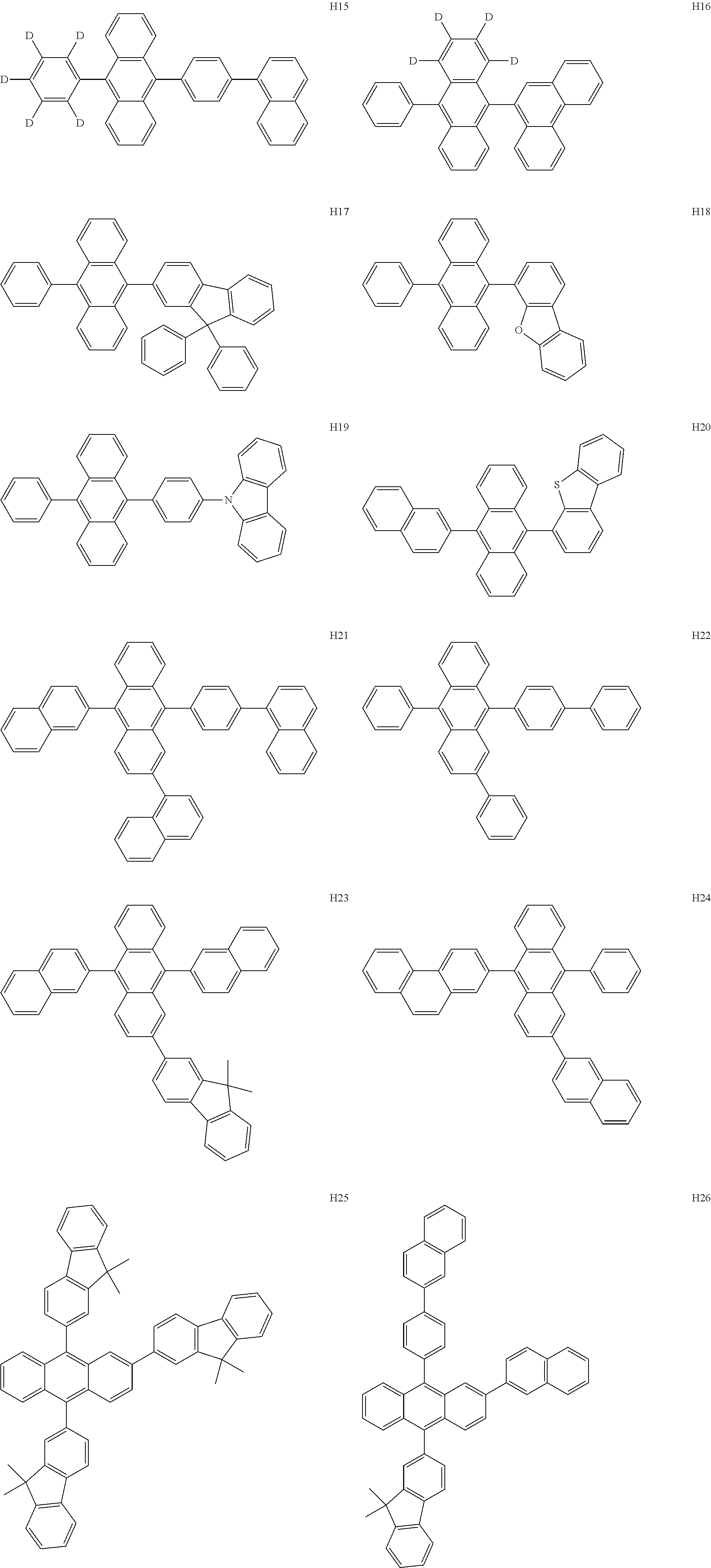

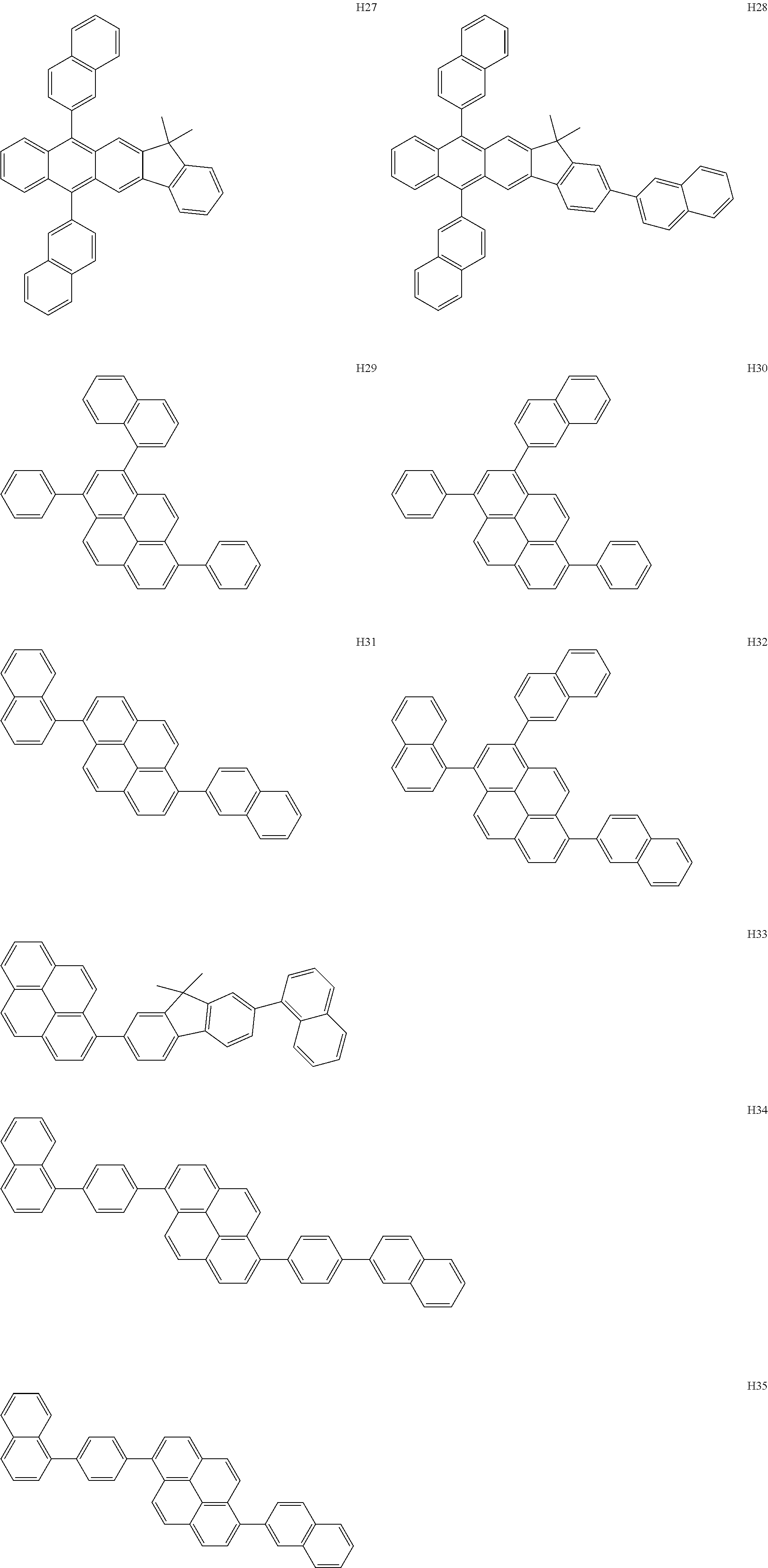

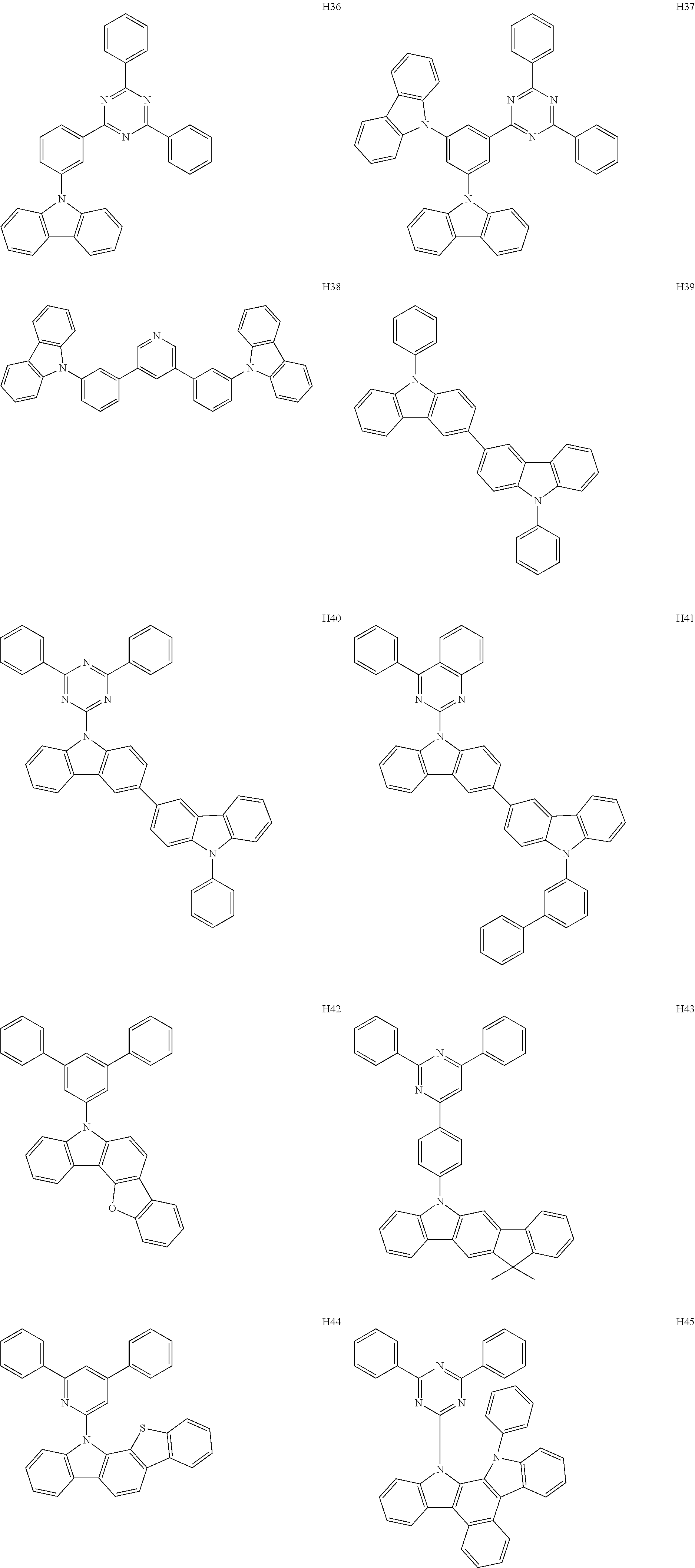

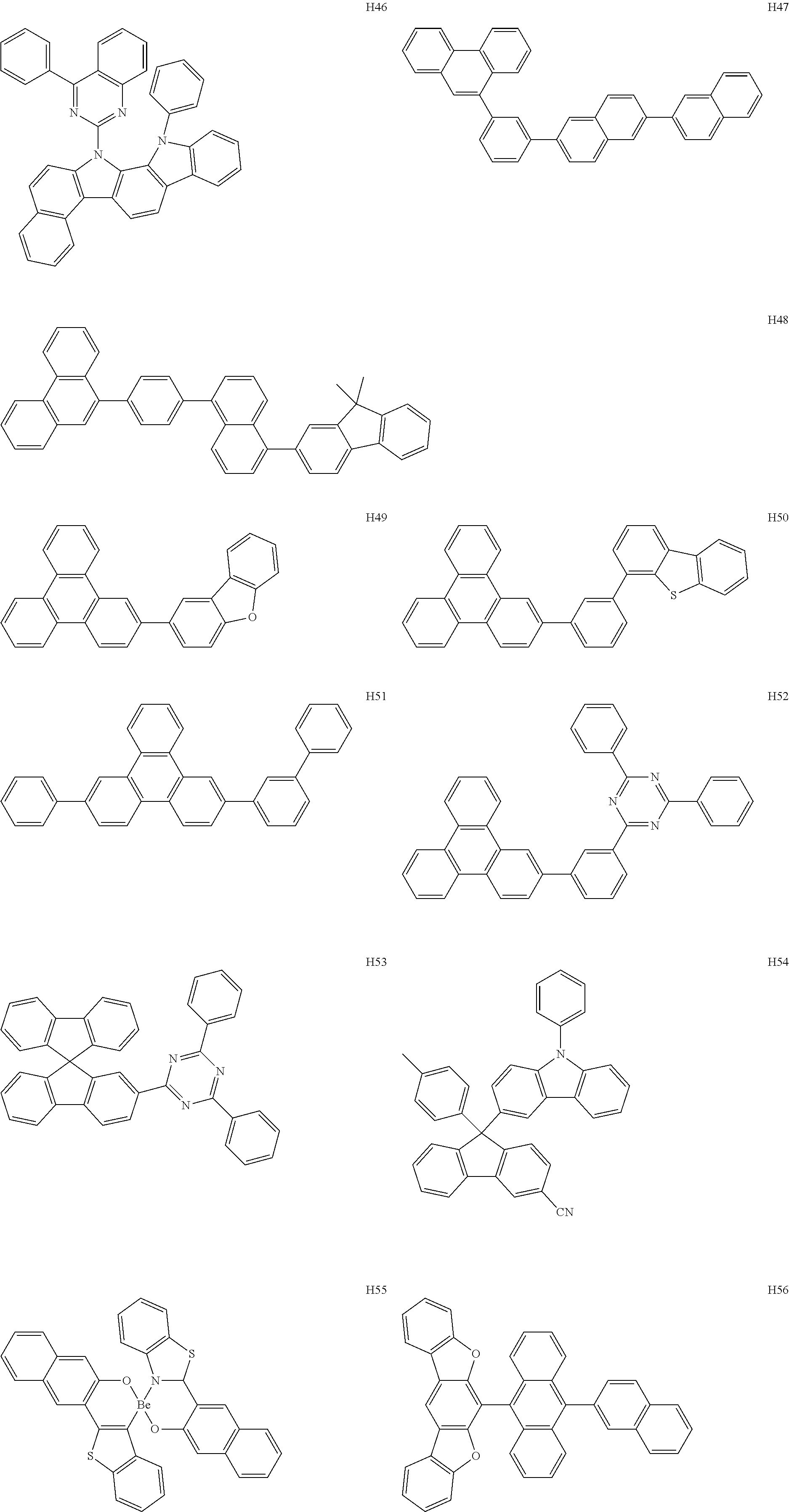

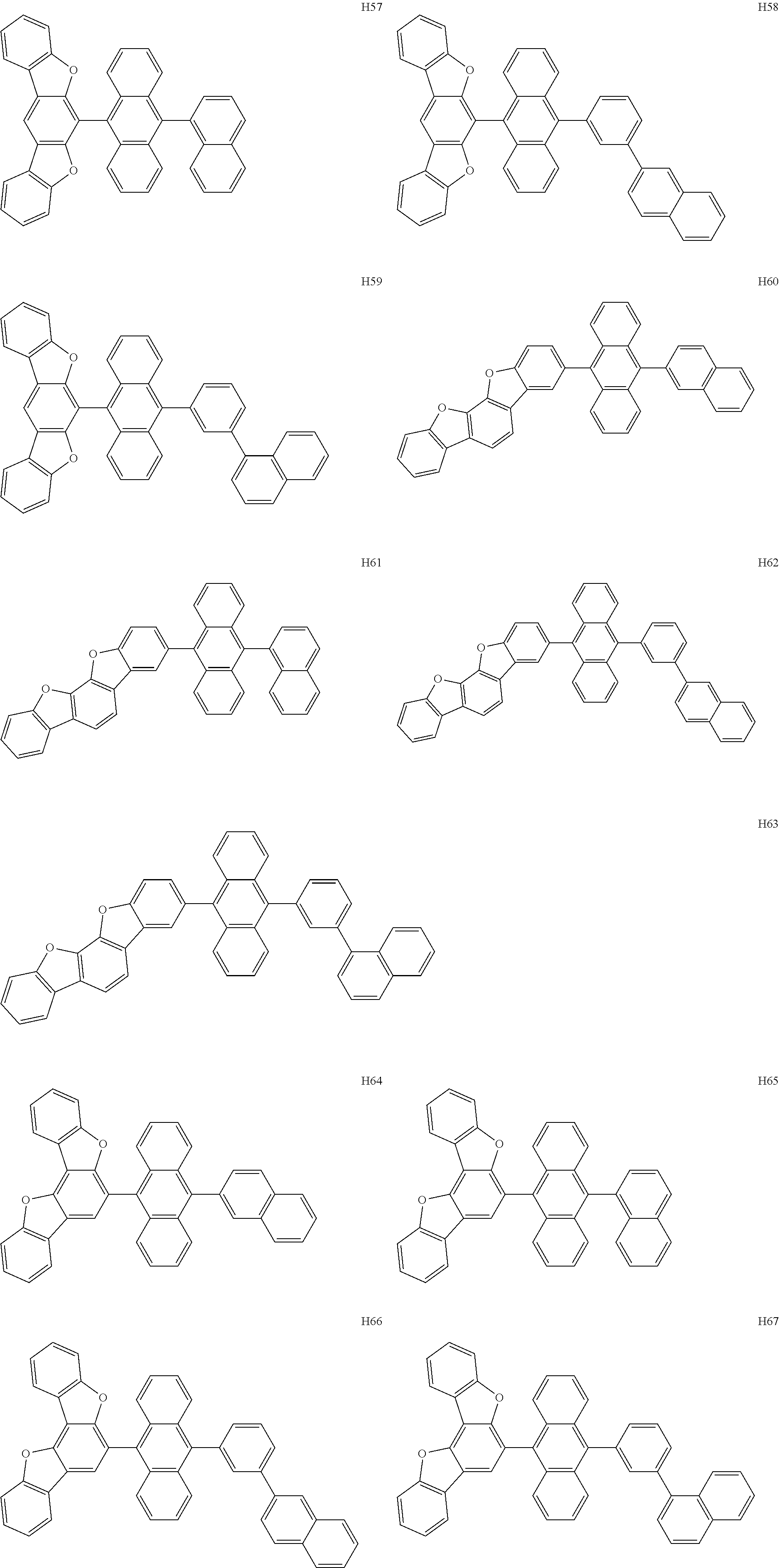

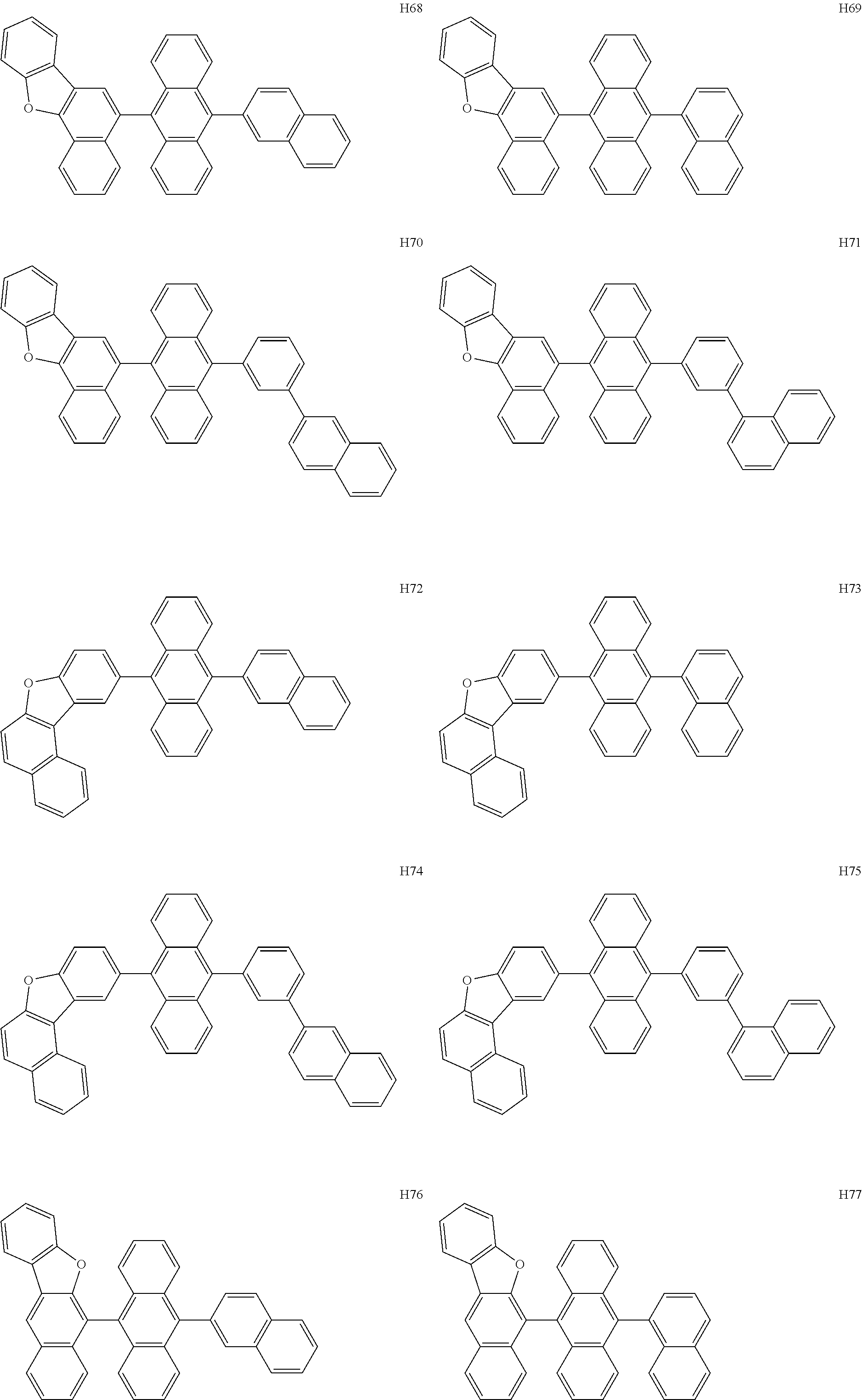

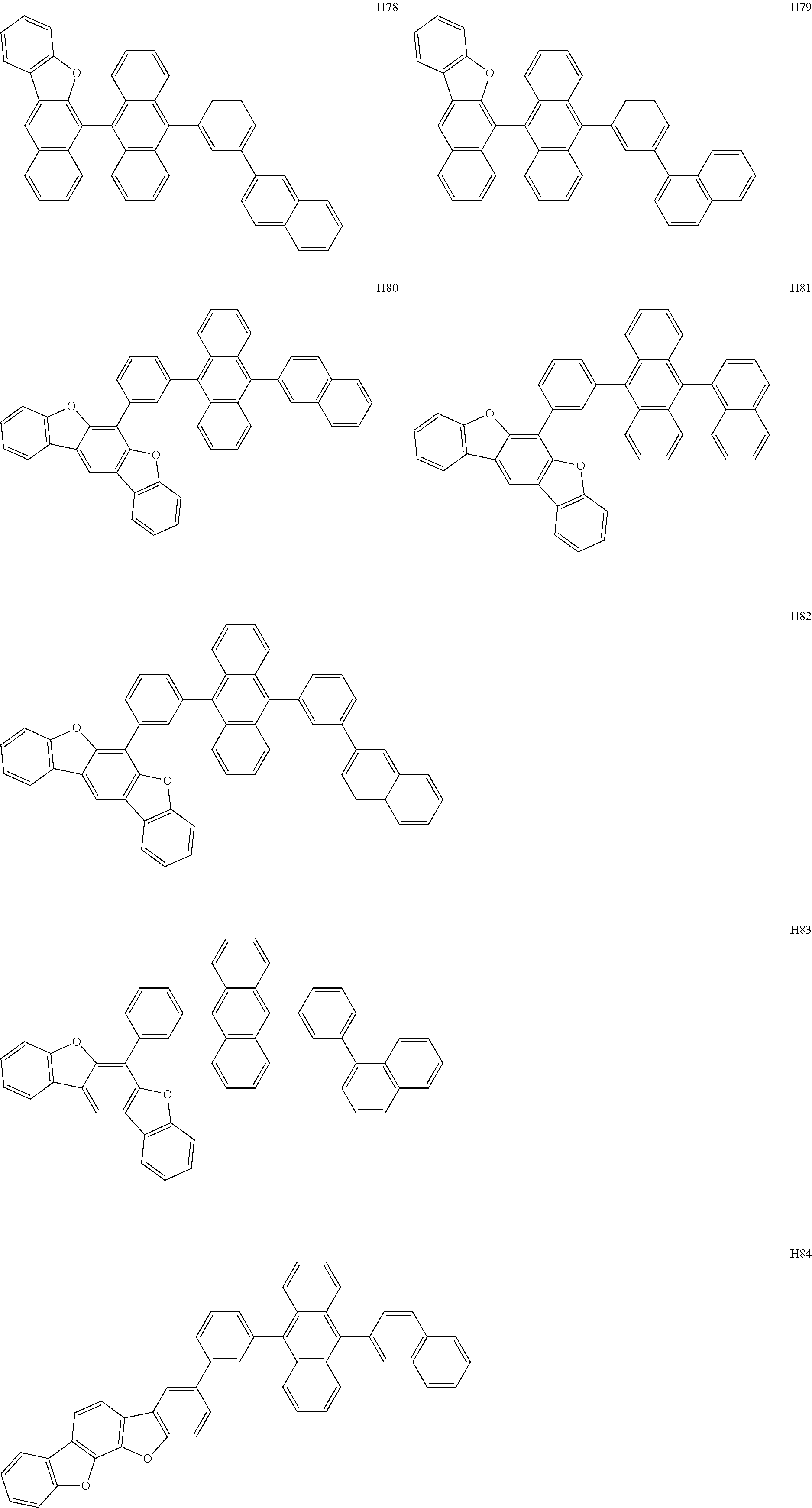

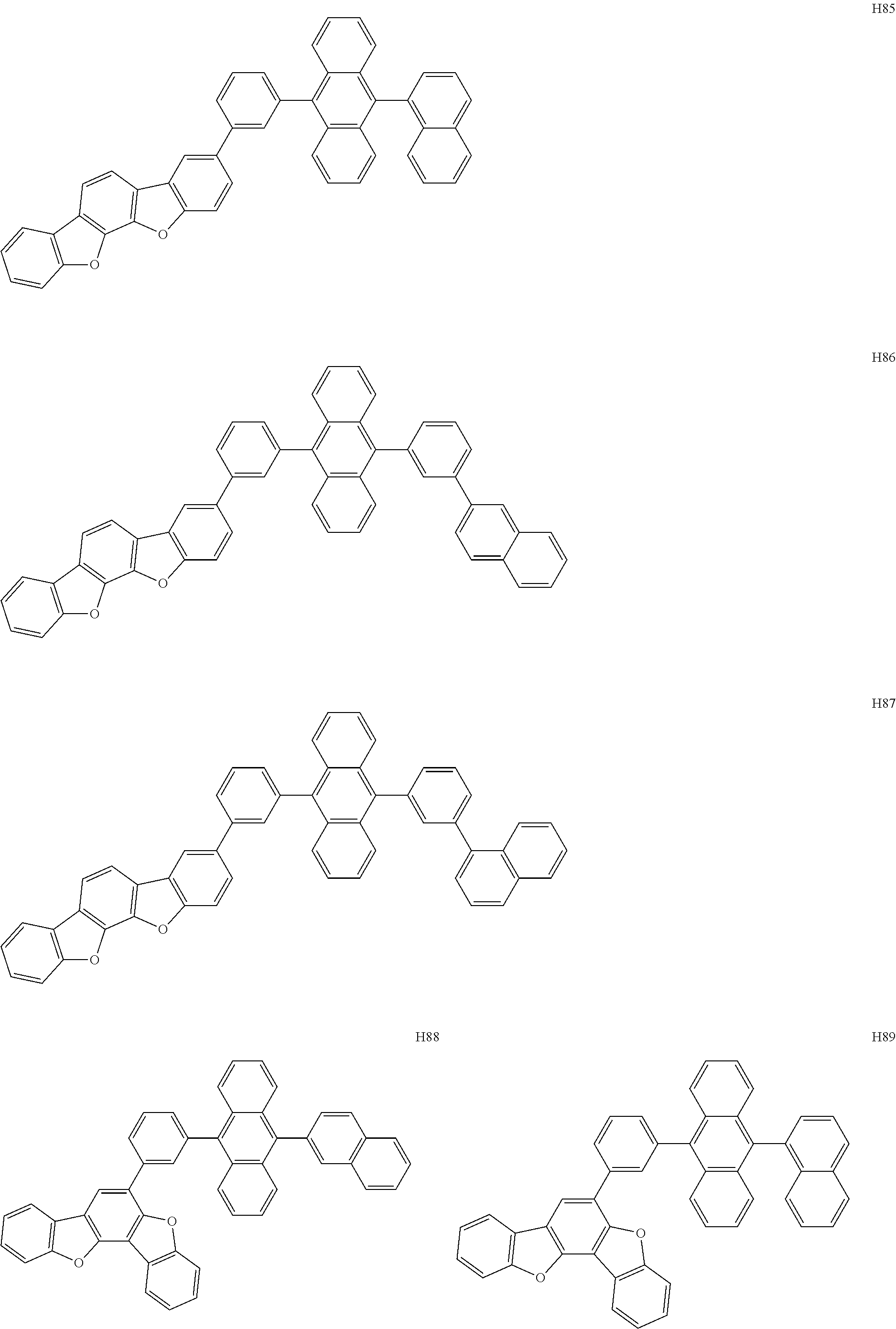 [SMILES: c1cc(-c2ccc3oc4c(ccc5c6ccccc6oc54)c3c2)cc(-c2c3ccccc3c(-c3cccc4ccccc34)c3ccccc23)c1 ; c1cc(-c2ccc3ccccc3c2)cc(-c2c3ccccc3c(-c3cccc(-c4ccc5oc6c(ccc7c8ccccc8oc76)c5c4)c3)c3ccccc23)c1 ; c1cc(-c2ccc3oc4c(ccc5c6ccccc6oc54)c3c2)cc(-c2c3ccccc3c(-c3cccc(-c4cccc5ccccc45)c3)c3ccccc23)c1 ; c1cc(-c2c3ccccc3c(-c3ccc4ccccc4c3)c3ccccc23)cc(-c2cc3c4ccccc4oc3c3c2oc2ccccc23)c1 ; c1cc(-c2c3ccccc3c(-c3cccc4ccccc34)c3ccccc23)cc(-c2cc3c4ccccc4oc3c3c2oc2ccccc23)c1]

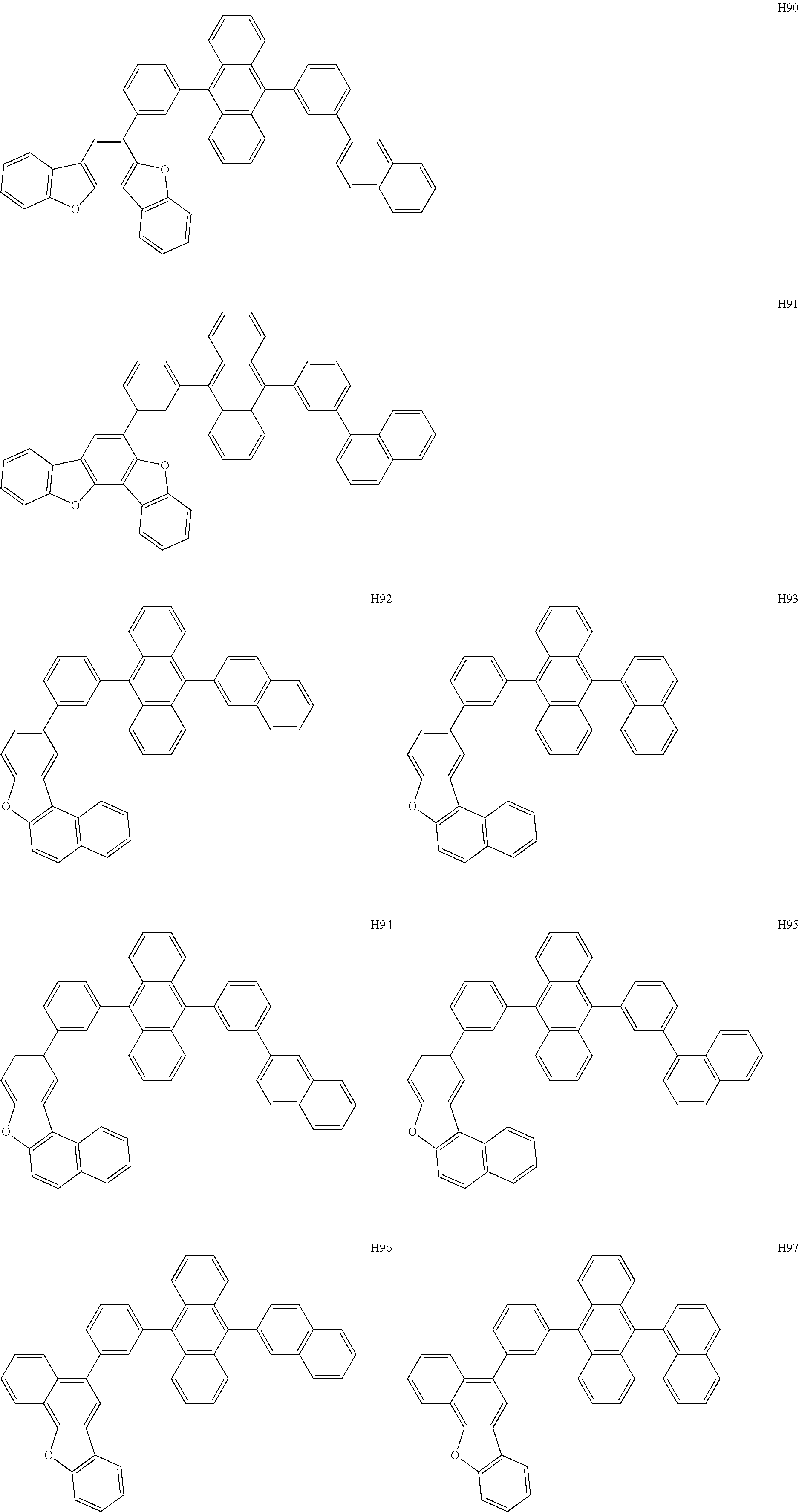

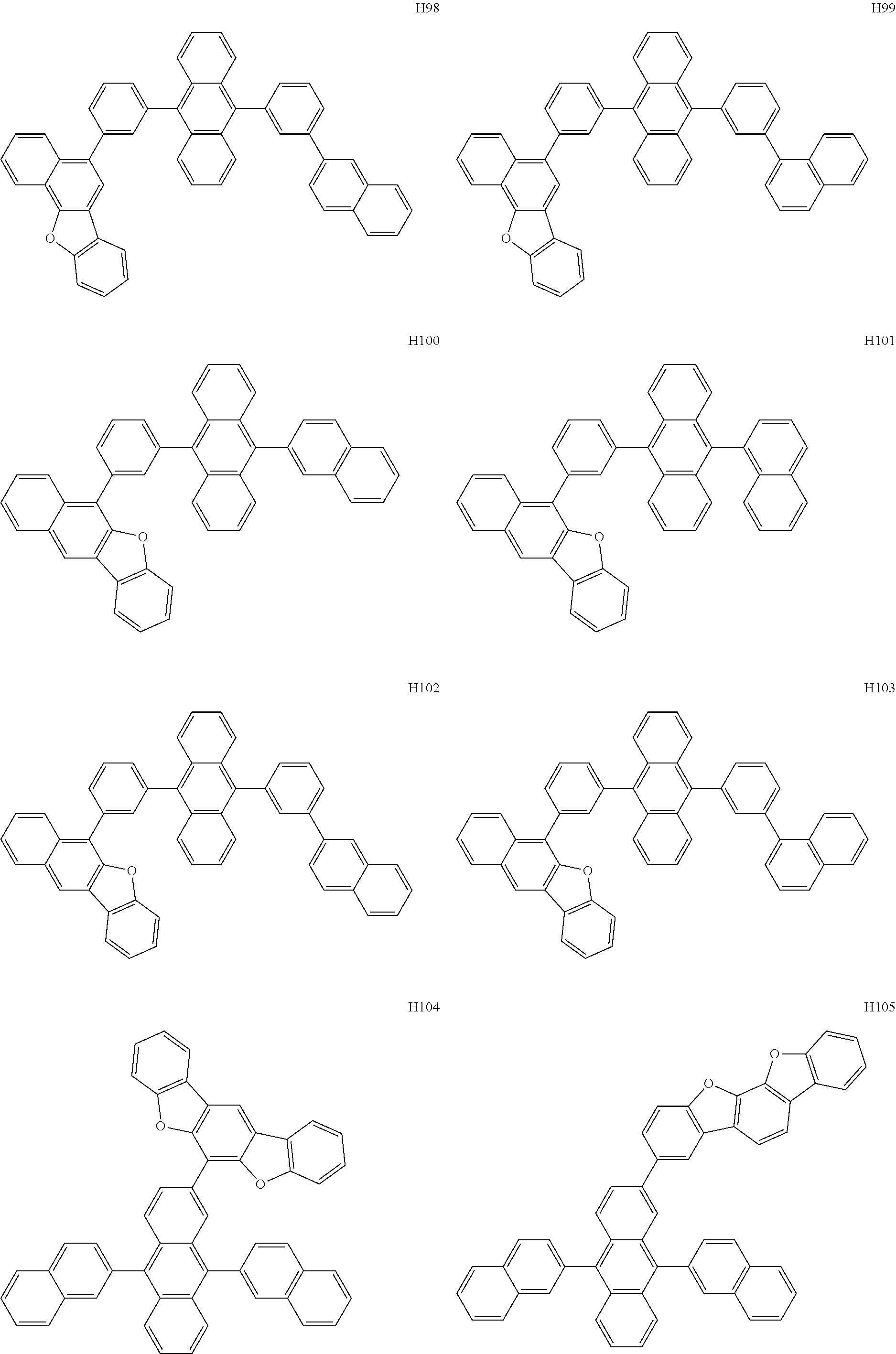

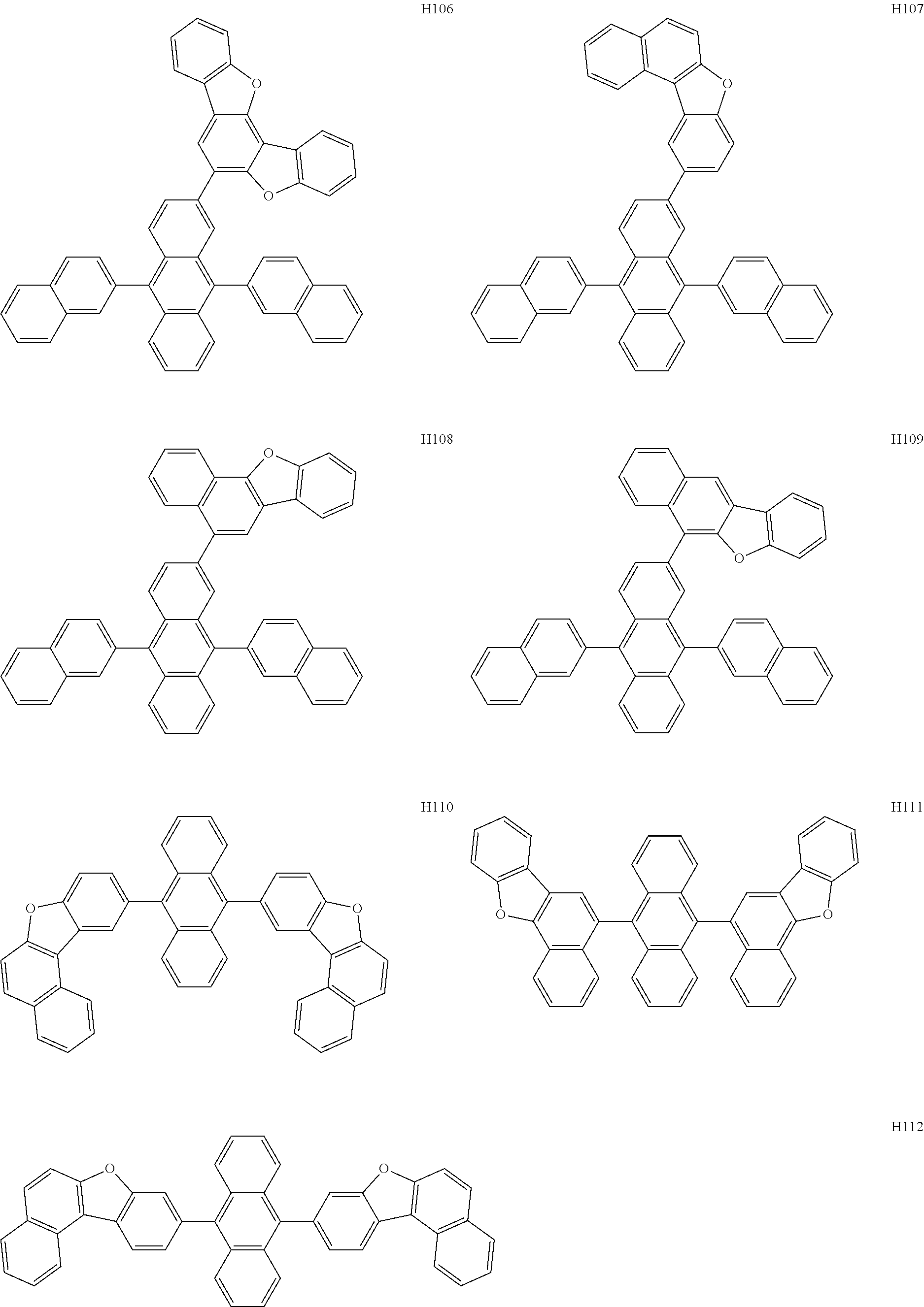

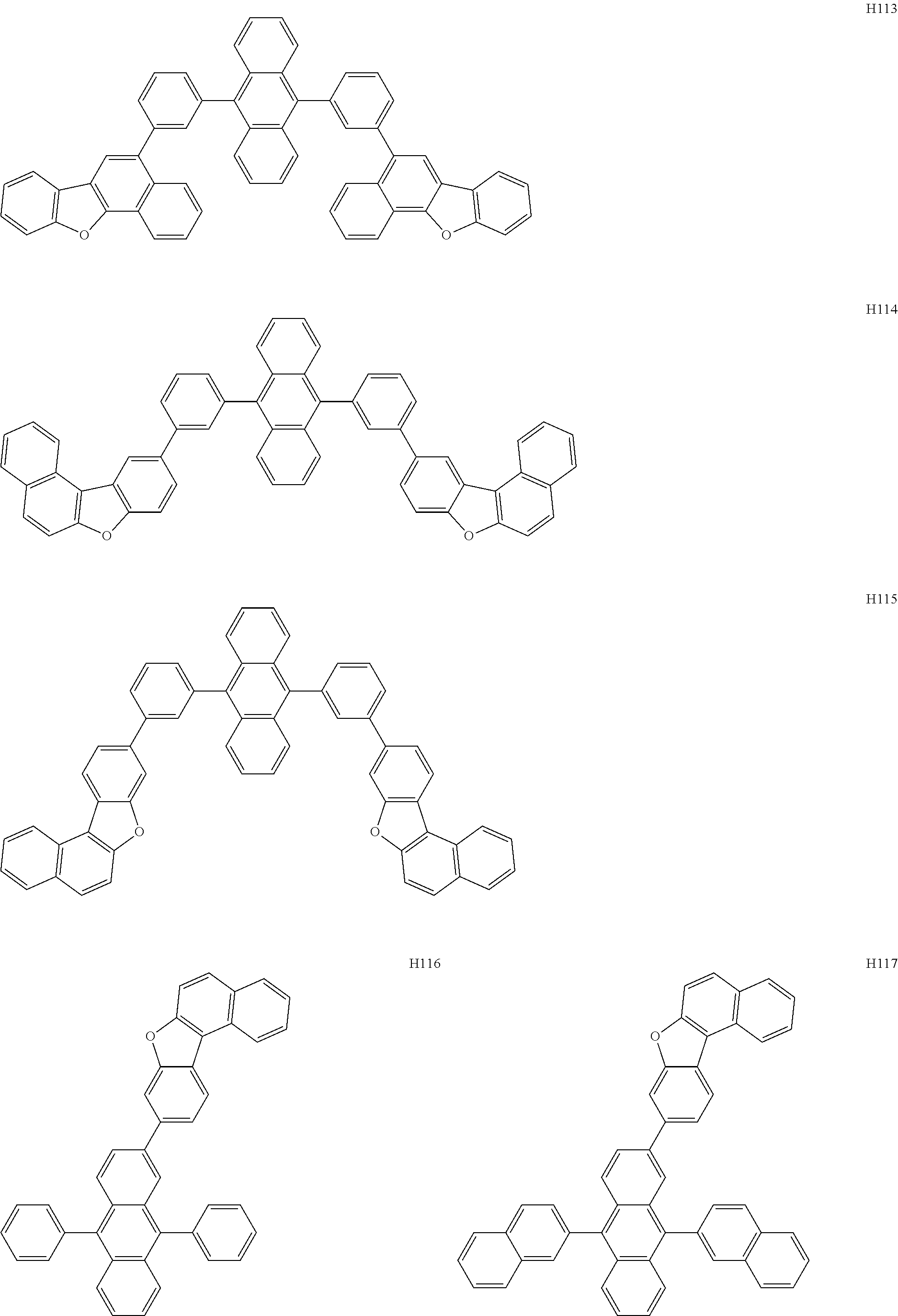 [SMILES: c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1]

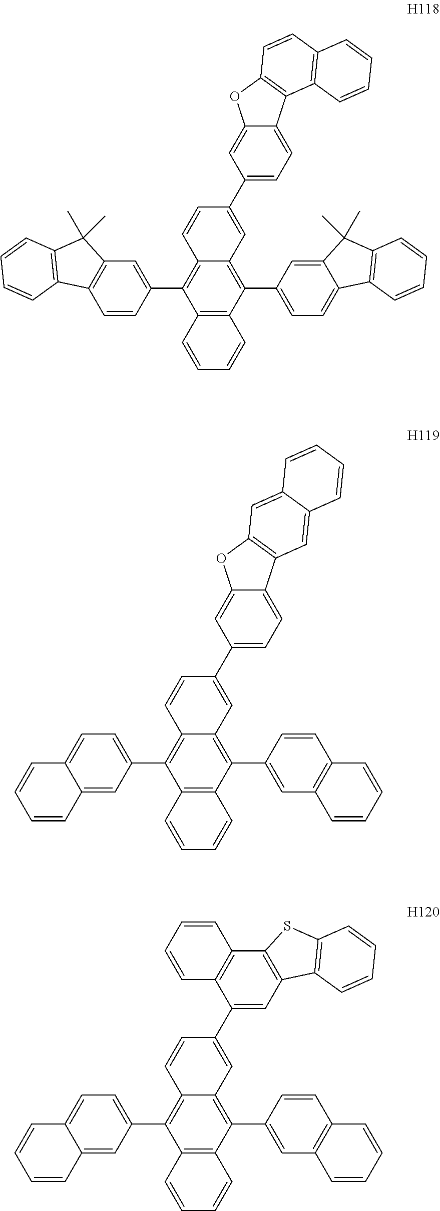 [SMILES: CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

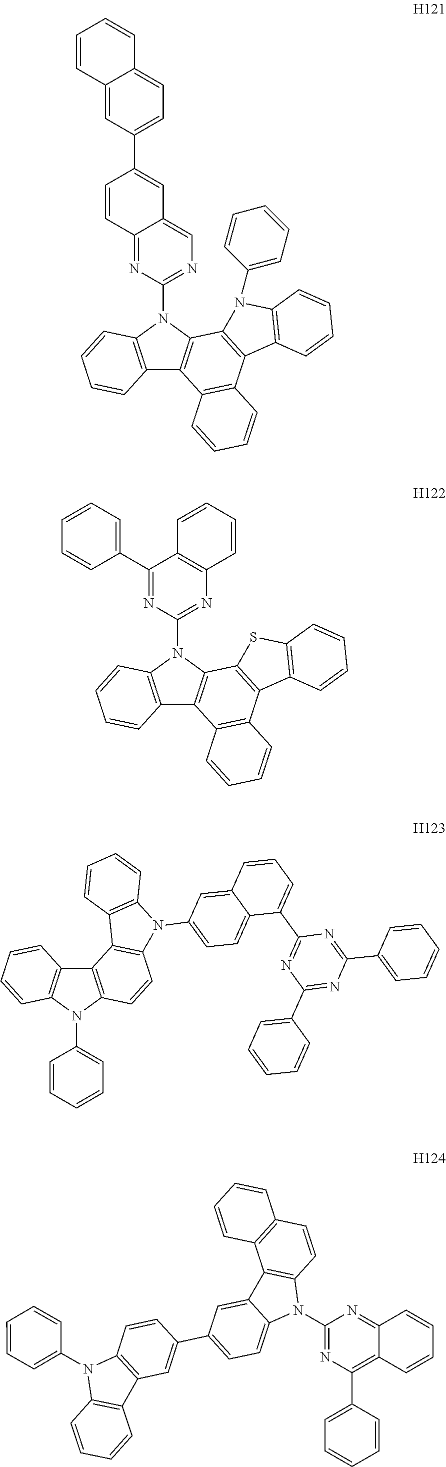 [SMILES: c1ccc(-n2c3ccccc3c3c4ccccc4c4c5ccccc5n(-c5ncc6cc(-c7ccc8ccccc8c7)ccc6n5)c4c32)cc1 ; c1ccc(-c2nc(-n3c4ccccc4c4c5ccccc5c5c6ccccc6sc5c43)nc3ccccc23)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

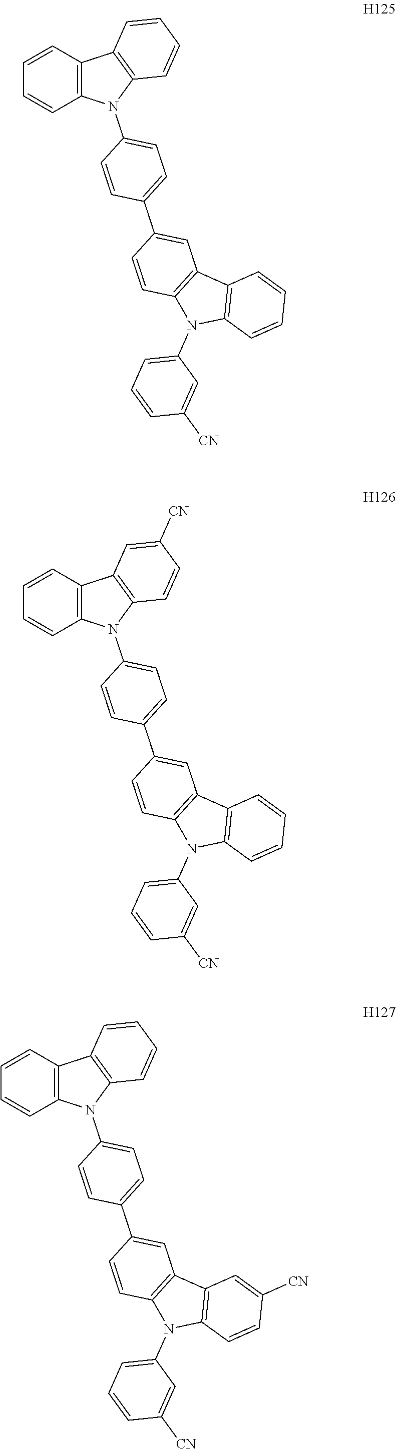 [SMILES: N#Cc1cccc(-n2c3ccccc3c3cc(-c4ccc(-n5c6ccccc6c6ccccc65)cc4)ccc32)c1 ; N#Cc1cccc(-n2c3ccccc3c3cc(-c4ccc(-n5c6ccccc6c6cc(C#N)ccc65)cc4)ccc32)c1 ; N#Cc1cccc(-n2c3ccc(C#N)cc3c3cc(-c4ccc(-n5c6ccccc6c6ccccc65)cc4)ccc32)c1]

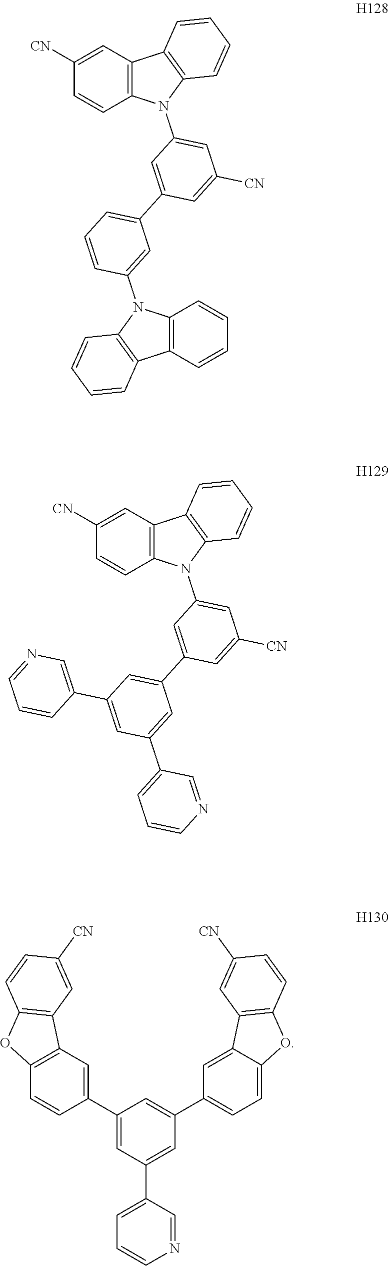

### Dopant in Emission Layer

The first dopant may be an organometallic compound including: iridium or platinum; and at least one organic ligand, and the organic ligand may be a bidentate organic ligand, a tridentate organic ligand, or a tetradentate organic ligand.

In an embodiment, the first dopant may be an organometallic compound including platinum and a tetradentate ligand.

In one or more embodiments, the first dopant may include an organometallic compound represented by Formula 40, an organometallic compound represented by Formula 50, or any combination thereof:

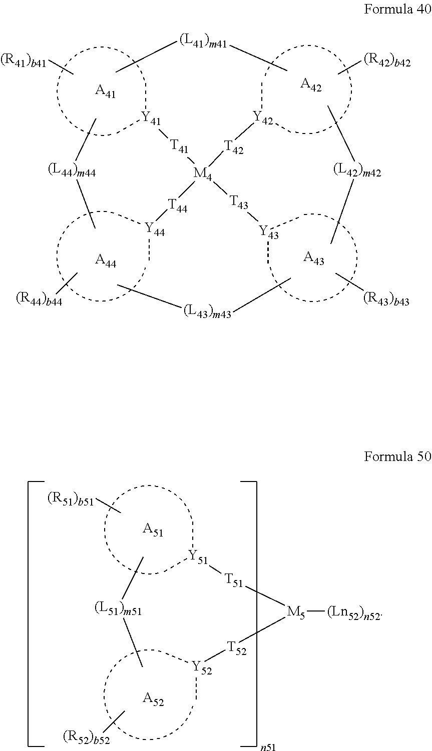

In Formulae 40 and 50,
M₄ and M₅ may each independently be platinum (Pt), palladium (Pd), copper (Cu), silver (Ag), gold (Au), rhodium (Rh), iridium (Ir), ruthenium (Ru), osmium (Os), titanium (Ti), zirconium (Zr), hafnium (Hf), europium (Eu), terbium (Tb) or thulium (Tm),
n51 may be 1, 2, or 3,
Ln52 may be an organic ligand,
n52 may be 0, 1, or 2,
Y₄₁ to Y₄₄ and Y₅₁ and Y₅₂ may each independently be N or C,
ring A₄₁ to ring A₄₄, ring A₅₁, and ring A₅₂ may each independently be a C₃-C₆₀ carbocyclic group or a C₁-C₆₀ heterocyclic group,
T₄₁ to T₄₄, T₅₁, and T₅₂ may each independently be a chemical bond (for example, a covalent bond or a coordination bond), *—O—**, or *—S—**,
L₄₁ to L₄₄ and L₅₁ may each independently be a single bond, *—O—**, *—S—**, *—C(R₄₅)(R₄₆)—**, *—C(R₄₅)═**, *═C(R₄₅)—**, *—C(R₄₅)═C(R₄₅)—**, *—C(═O)—**, *—C(═S)—**, *—C═C—**, *—B(R₄₅)—**, *—N(R₄₅)—**, *—P(R₄₅)—**, *—Si(R₄₅)(R₄₆)—**, *—P(R₄₅)(R₄₆)—**, or *—Ge(R₄₅)(R₄₆)—*,
m41 to m44 may each independently be 0, 1, or 2, wherein, when m41 is 0, L₄₁ does not exist (e.g., is omitted or not included), when m42 is 0, L₄₂ does not exist, when m43 is 0, L₄₃ does not exist, when m44 is 0, L₄₄ does not exist, and two or more of m41 to m44 are not 0,
m51 may be 1 or 2,
R₄₁ to R₄₆, R₅₁, and R₅₂ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkenyl group unsubstituted or substituted with at least one R₁₀ₐ, a C₁-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₄₁)(Q₄₂)(Q₄₃), —N(Q₄₁)(Q₄₂), —B(Q₄₁)(Q₄₂), —C(═O)(Q₄₁), —S(═O)₂(Q₄₁), or —P(═O)(Q₄₁)(Q₄₂),
R₄₅ and R₄₁; R₄₅ and R₄₂; R₄₅ and R₄₃; or R₄₅ and R₄₄ may optionally be linked to each other to form a C₃-C₆₀ carbocyclic group unsubstituted or substituted with at least one R₁₀ₐ, or a C₁-C₆₀ heterocyclic group unsubstituted or substituted with at least one R₁₀ₐ,
b41 to b44, b51, and b52 may each independently be an integer from 1 to 8,
* and *′ each indicate a binding site to a neighboring atom,
R₁₀ₐ may be the same as described in the present specification, and
Q₄₁ to Q₄₃ may each independently be the same as described in connection with Q₁₁.

In Formulae 40 and 50, M₄ and M₅ may each independently be Pt, Pd, Cu, Ag, Au, Ir, or Os.

For example, in Formulae 40 and 50, M₄ and M₅ may each independently be Pt or Ir.

In an embodiment, M₄ may be Pt, and M₅ may be Ir.

In an embodiment, in Formula 40,
Y₄₁, Y₄₂, and Y₄₃ may each be C, and Y₄₄ may be N;
Y₄₁, Y₄₂, and Y₄₄ may each be C, and Y₄₃ may be N;
Y₄₁, Y₄₃, and Y₄₄ may each be C, and Y₄₂ may be N;
Y₄₂, Y₄₃, and Y₄₄ may each be C, and Y₄₁ may be N;
Y₄₁ and Y₄₄ may each be C, and Y₄₂ and Y₄₃ may each be N;
Y₄₁ and Y₄₄ may each be N, and Y₄₂ and Y₄₃ may each be C;
Y₄₁ and Y₄₂ may each be C, and Y₄₃ and Y₄₄ may each be N;
Y₄₁ and Y₄₂ may each be N, and Y₄₃ and Y₄₄ may each be C;
Y₄₁ and Y₄₃ may each be C, and Y₄₂ and Y₄₄ may each be N; or
Y₄₁ and Y₄₃ may each be N, and Y₄₂ and Y₄₄ may each be C.
In one or more embodiments, in Formula 50,
Y₅₁ and Y₅₂ may each be C,
Y₅₁ may be N, and Y₅₂ may be C,
Y₅₁ may be C, and Y₅₂ may be N, or
Y₅₁ and Y₅₂ may each be N.

In Formulae 40 and 50, ring A₄₁ to ring A₄₄, ring A₅₁, and ring A₅₂ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an indenopyridine group, an indolopyridine group, a benzofuropyridine group, a benzothienopyridine group, a benzosilolopyridine group, an indenopyrimidine group, an indolopyrimidine group, a benzofuropyrimidine group, a benzothienopyrimidine group, a benzosilolopyrimidine group, a dihydropyridine group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a 2,3-dihydroimidazole group, a triazole group, a 2,3-dihydrotriazole group, an oxazole group, an isoxazole group, a thiazole group, an isothiazole group, an oxadiazole group, a thiadiazole group, a benzopyrazole group, a benzimidazole group, a 2,3-dihydrobenzimidazole group, an imidazopyridine group, a 2,3-dihydroimidazopyridine group, an imidazopyrimidine group, a 2,3-dihydroimidazopyrimidine group, an imidazopyrazine group, a 2,3-dihydroimidazopyrazine group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, in Formula 40,
each of T₄₁ to T₄₄ may be a chemical bond;
T₄₁ may be *—O—*′ or *—S—*, and T₄₂ to T₄₄ may be chemical bonds;
T₄₂ may be *—O—*′ or *—S—*′, and T₄₁, T₄₃, and T₄₄ may be chemical bonds;
T₄₃ may be *—O—*′ or *—S—*′, and T₄₁, T₄₂, and T₄₄ may be chemical bonds; or
T₄₄ may be *—O—*′ or *—S—*′, and T₄₁, T₄₂, and T₄₃ may be chemical bonds.

In one or more embodiments, in Formula 40, each of T₄₁ to T₄₄ may be a chemical bond.

In one or more embodiments, in Formula 50, each of T₅₁ and T₅₂ may be a chemical bond.

In one or more embodiments, a bond between Y₄₁ and T₄₁ or a bond between Y₄₁ and M₄ may be a covalent bond or a coordinate bond.

In one or more embodiments, a bond between Y₄₂ and T₄₂ or a bond between Y₄₂ and M₄ may be a covalent bond or a coordinate bond.

In one or more embodiments, a bond between Y₄₃ and T₄₃ or a bond between Y₄₃ and M₄ may be a covalent bond or a coordinate bond.

In one or more embodiments, a bond between Y₄₄ and T₄₄ or a bond between Y₄₄ and M₄ may be a covalent bond or a coordinate bond.

In one or more embodiments, a bond between Y₅₁ and T₅₁ or a bond between Y₅₁ and M₅ may be a covalent bond or a coordinate bond.

In one or more embodiments, a bond between Y₅₂ and T₅₂ or a bond between Y₅₂ and M₅ may be a covalent bond or a coordinate bond.

In one or more embodiments, L₄₁ to L₄₄ and L₅₁ may each independently be a single bond, *—O—*, *—S—*, *—C(R₄₅)(R₄₆)—*, *—C(R₄₅)═*, *═C(R₄₅)—*′, *—C(R₄₅)═C(R₄₅)—*, *—C(═O)—**, or *—N(R₄₅)—**.

In one or more embodiments, m41 may be 0, m42 to m44 may be 1, and m51 may be 1.

In one or more embodiments, in Formulae 40 and 50, R₄₁ to R₄₆, R₅₁, and R₅₂ may each independently be:
hydrogen, deuterium, —F, —Cl, —Br, —I, a cyano group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, a cyano group, a phenyl group, a biphenyl group, or any combination thereof;
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphtho silolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indeno carbazolyl group, or an indolocarbazolyl group, each unsubstituted or substituted with deuterium, —F, —Cl, —Br, —I, a cyano group, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphtho silolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indeno carbazolyl group, an indolocarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), —P(═O)(Q₃₁)(Q₃₂), or any combination thereof; or
—Si(Q₄₁)(Q₄₂)(Q₄₃), —N(Q₄₁)(Q₄₂), —B(Q₄₁)(Q₄₂), —C(═O)(Q₄₁), —S(═O)₂(Q₄₁), or —P(═O)(Q₄₁)(Q₄₂).

In one or more embodiments, in Formulae 40 and 50, R₄₁ to R₄₆, R₅₁, and R₅₂ may each independently be:
hydrogen, deuterium, —F, —Cl, —Br, —I, a cyano group, a C₁-C₂₀ alkyl group, or a C₁-C₂₀ alkoxy group;
a C₁-C₂₀ alkyl group or a C₁-C₂₀ alkoxy group, each substituted with deuterium, —F, —Cl, —Br, —I, a cyano group, a phenyl group, a biphenyl group, or any combination thereof; or
a phenyl group, a biphenyl group, a terphenyl group, a naphthyl group, a fluorenyl group, a spiro-bifluorenyl group, a carbazolyl group, a dibenzofuranyl group, a dibenzothiophenyl group, or a dibenzosilole group, each unsubstituted or substituted with deuterium, —F, —Cl, —Br, —I, a cyano group, a C₁-C₂₀ alkyl group, a C₁-C₂₀ alkoxy group, a phenyl group, a biphenyl group, or any combination thereof.

In an embodiment, the first dopant may be an organometallic compound represented by Formula 40, wherein in Formula 40, Y₄₁ may be C, T₄₁ may be a coordinate bond, m41 may be 0, and m42 to m44 may each be 1.

In an embodiment, the first dopant may be an organometallic compound represented by Formula 40, wherein, in Formula 40, Y₄₁ may be C, T₄₁ may be a coordinate bond, m41 may be 0, m42 to m44 may each be 1, L₄₂ and L₄₄ may each be a single bond, and L₄₃ may be *—O—*, *—S—*, *—C(R₄₅)(R₄₆)—**, or *—N(R₄₅)—*.

In an embodiment, the first dopant may be an organometallic compound represented by Formula 50, wherein in Formula 50, Y₅₁ may be C, and T₅₁ may be a coordinate bond.

In an embodiment, the first dopant may be an organometallic compound represented by Formula 41:

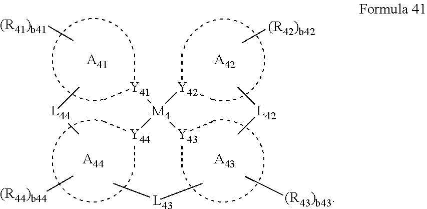

In Formula 41, M₄, Y₄₁ to Y₄₄, ring A₄₁ to ring A₄₄, L₄₂ to L₄₄, R₄₁ to R₄₄, and b41 to b44 may each independently be the same as described in the present specification.

In an embodiment, in Formula 41, a group represented by

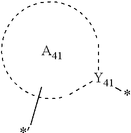

may be a group represented by one of Formulae A41-1 to A41-6:

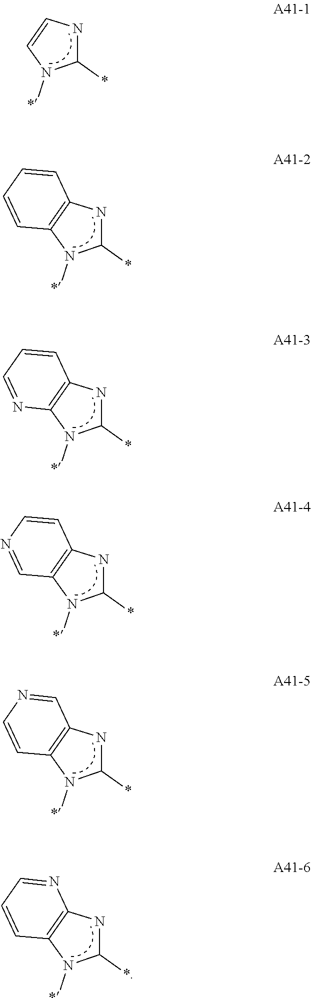

In Formulae A41-1 to A41-6,
* is a binding site to M₄ in Formula 41, and
*′ is a binding site to L₄₄ in Formula 41.

In an embodiment, in Formula 41, a group represented by

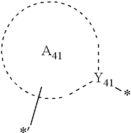

may be a group represented by Formula A41-2.

In one or more embodiments, in Formula 41, a group represented by

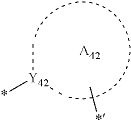

may be a group represented by one of Formulae A42-1 to A42-11:

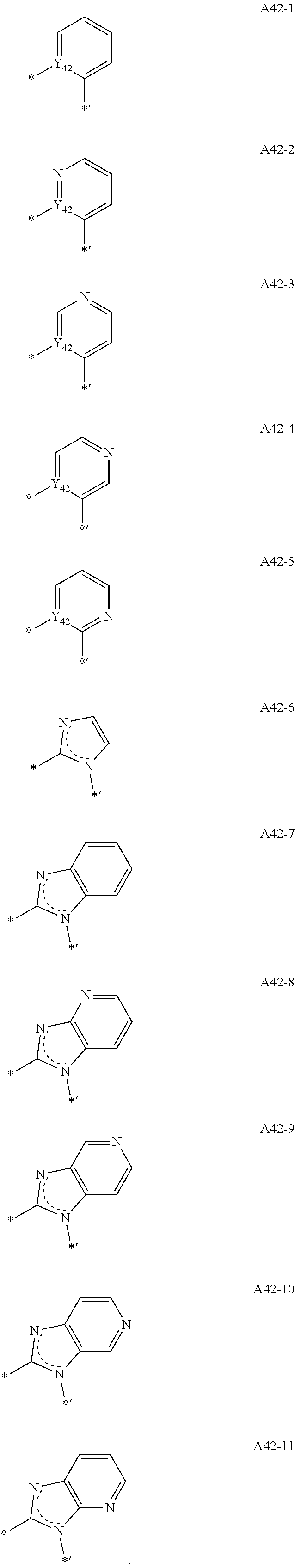

In Formulae A42-1 to A42-11,
Y₄₂ may be the same as described in the present specification,
* is a binding site to M₄ in Formula 41, and
*′ is a binding site to L₄₂ in Formula 41.

In one or more embodiments, in Formula 41, a group represented by

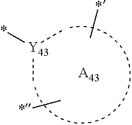

may be a group represented by one of Formulae A43-1 to A43-5:

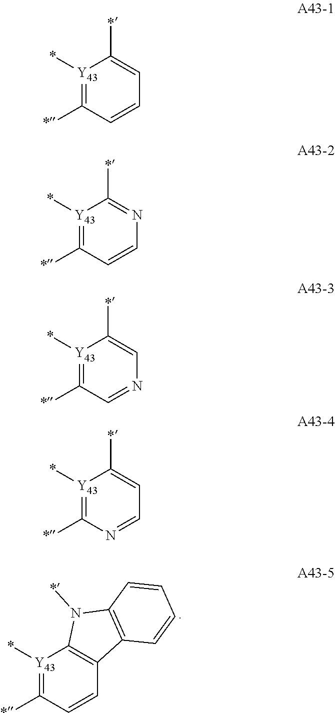

In Formulae A43-1 to A43-5,
Y₄₃ may be the same as described in the present specification,
* is a binding site to M₄ in Formula 41,
*′ is a binding site to L₄₂ in Formula 41, and
*″ is a binding site to L₄₃ in Formula 41.

In one or more embodiments, in Formula 41, a group represented by

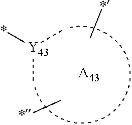

may be a group represented by Formula A43-5.

In one or more embodiments, in Formula 41, a group represented by

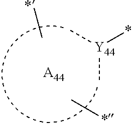

may be a group represented by one of Formulae A44-1 to A44-4:

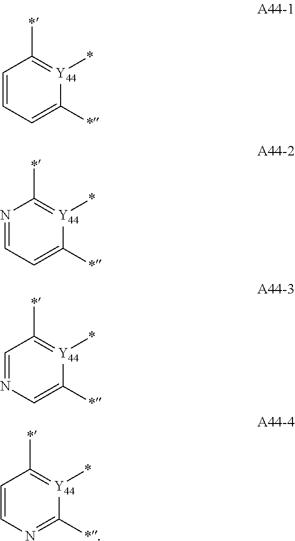

In Formulae A44-1 to A44-4,
Y₄₄ may be the same as described in the present specification,
* is a binding site to M₄ in Formula 41,
*′ is a binding site to L₄₄ in Formula 41, and
*″ is a binding site to L₄₃ in Formula 41.

The first dopant may include, for example, one of Compounds PD1 to PD25, one of Compounds 40-1 to 40-14, one of Compounds 50-1 to 50-84, one of Compounds D1-1 to D1-3, or any combination thereof:

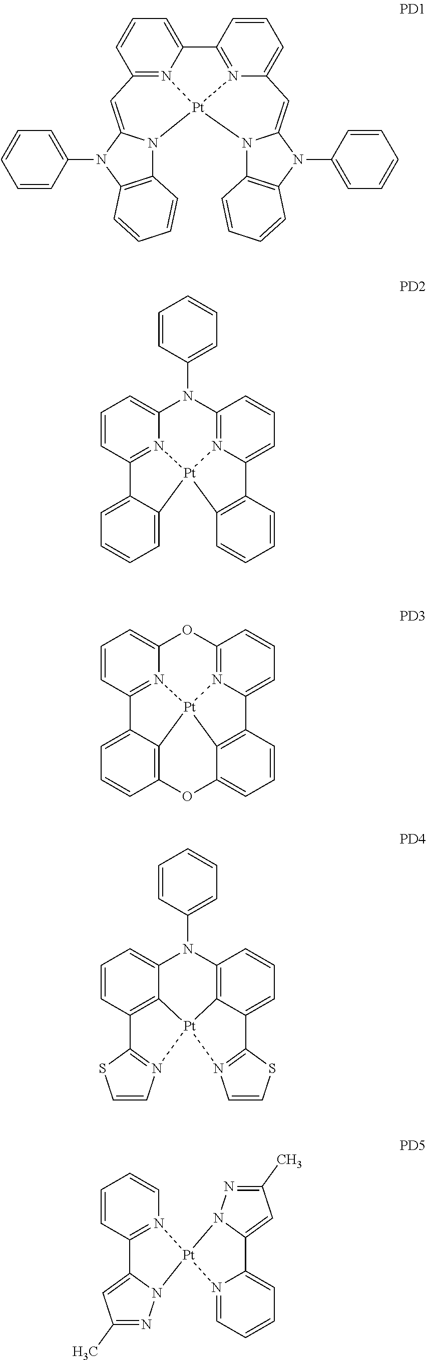

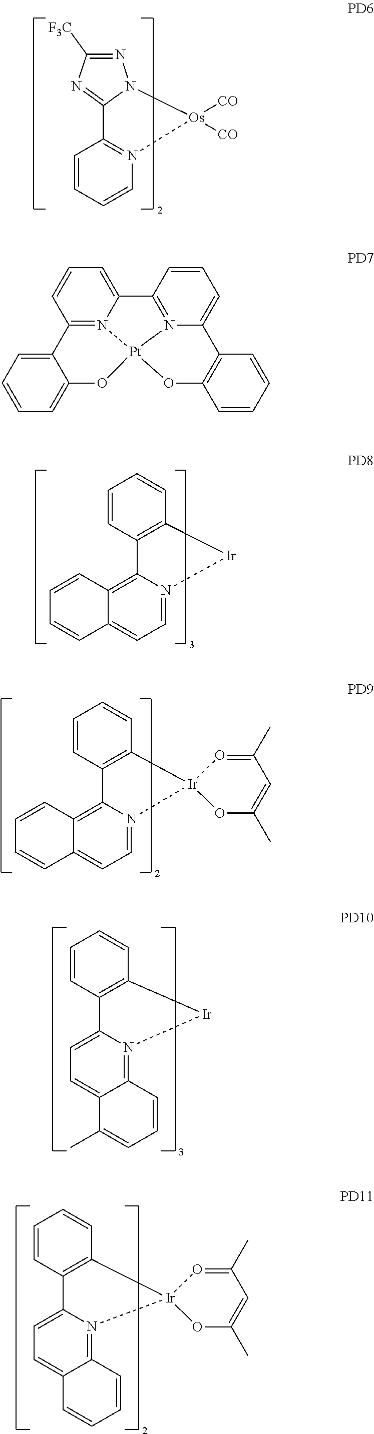

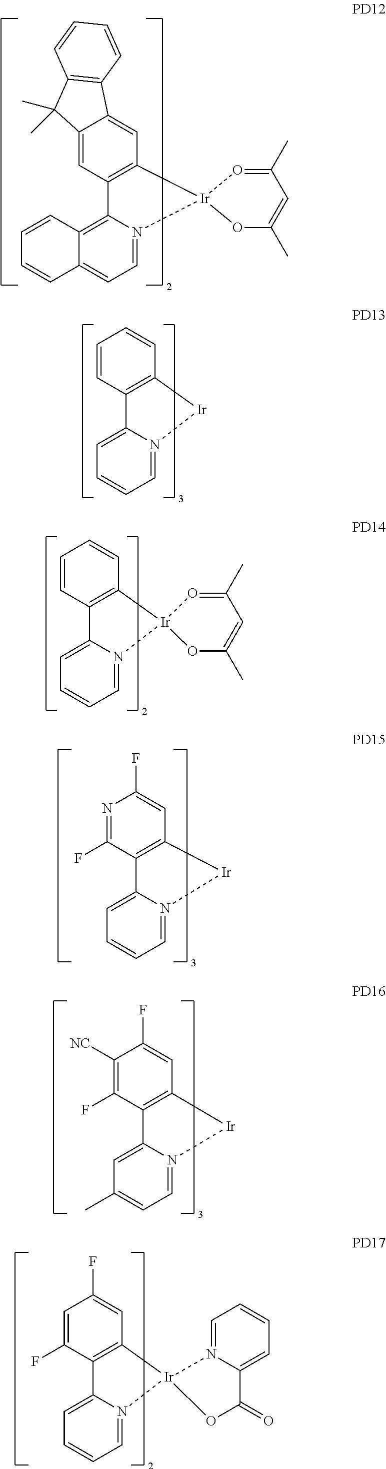

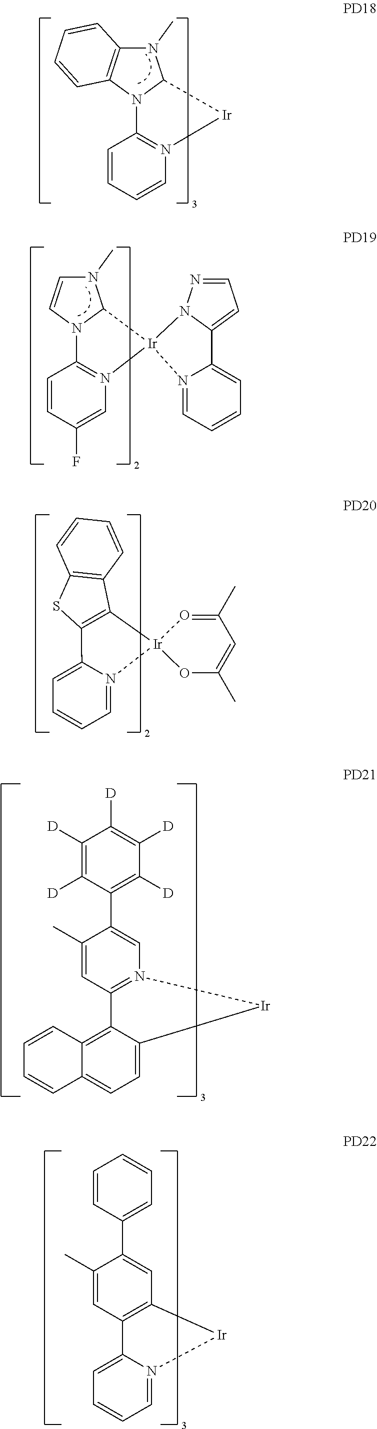

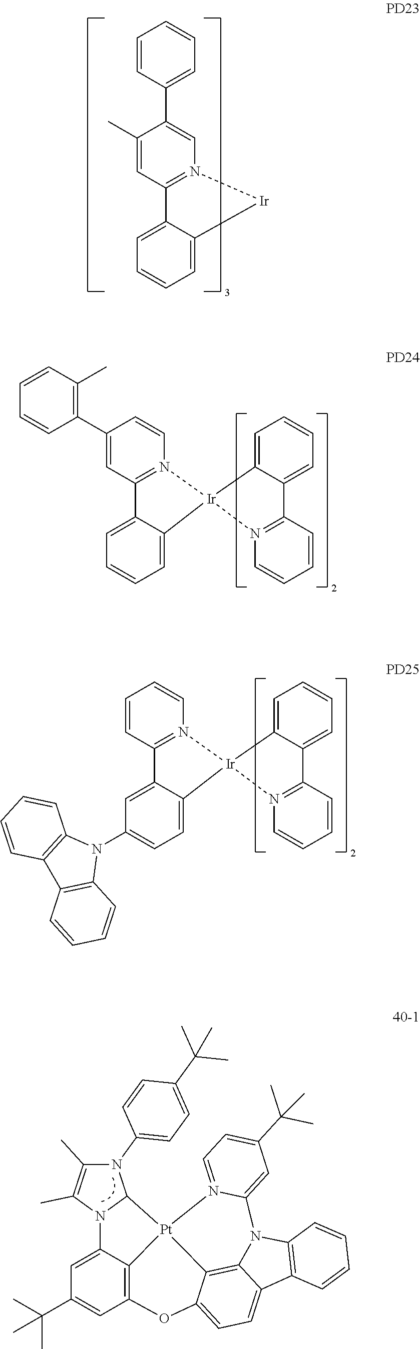

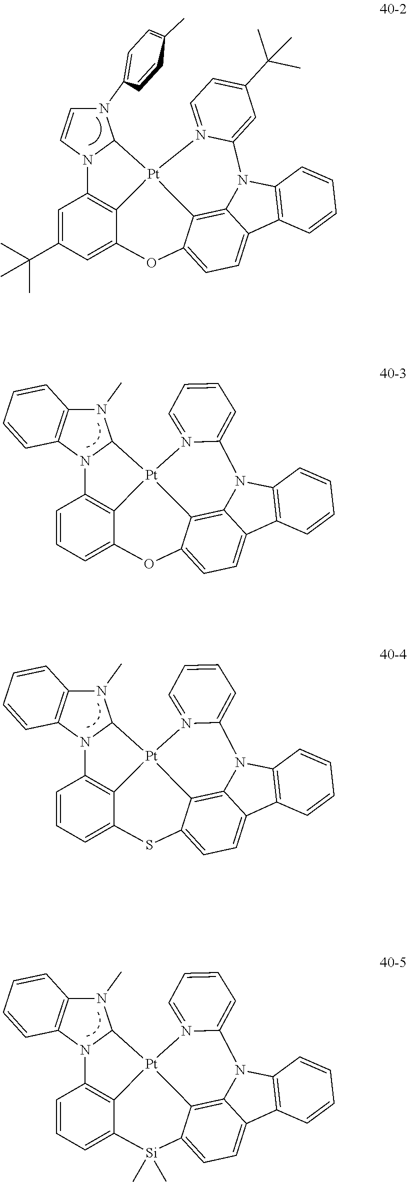

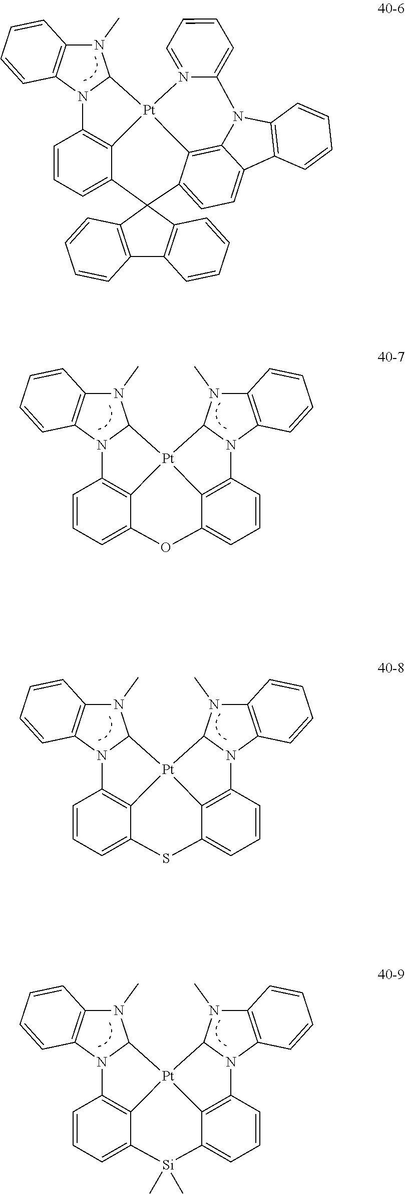

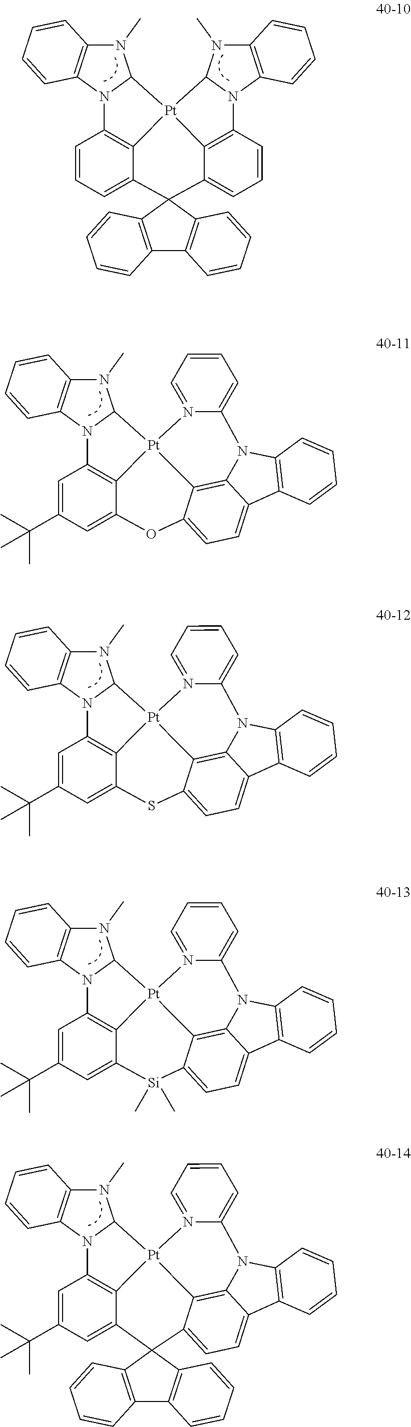

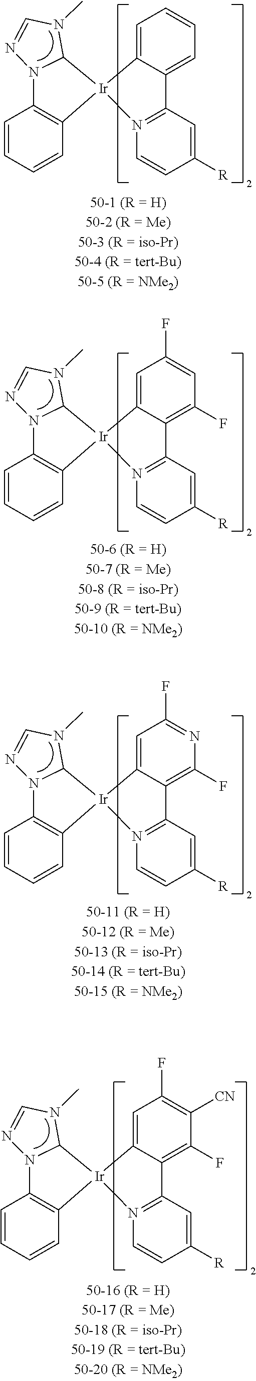

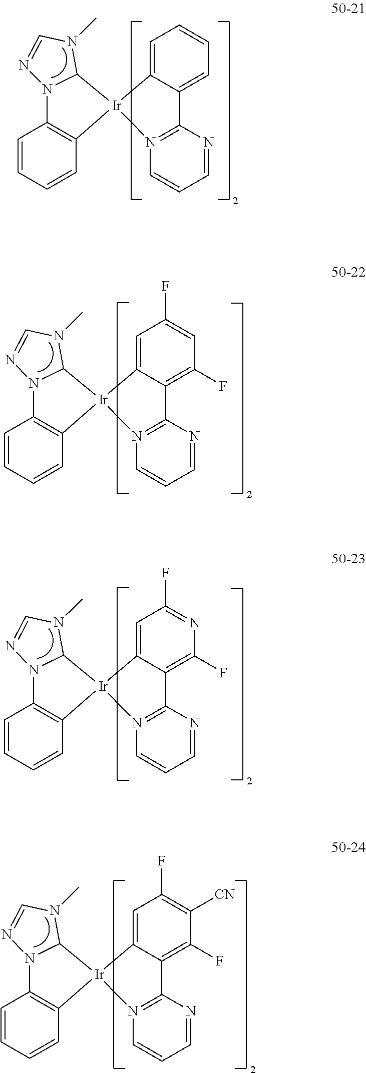

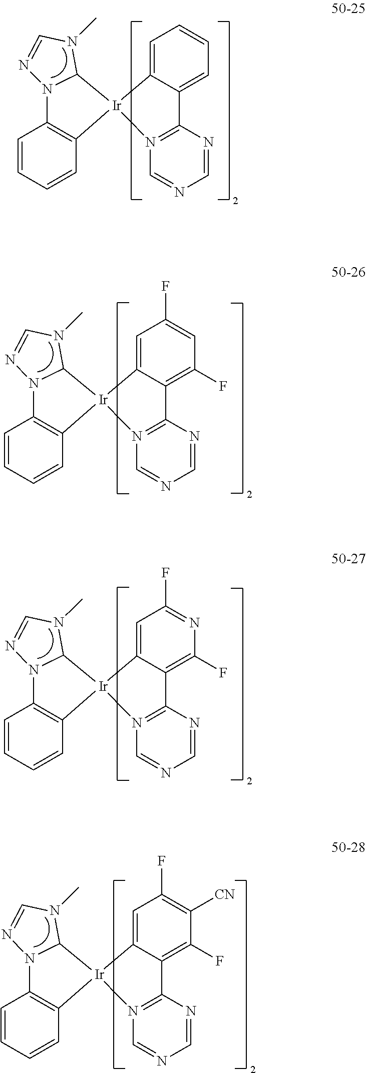

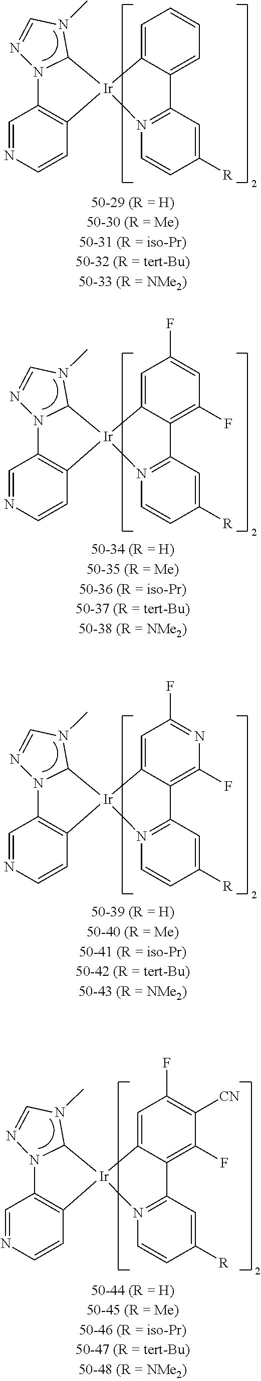

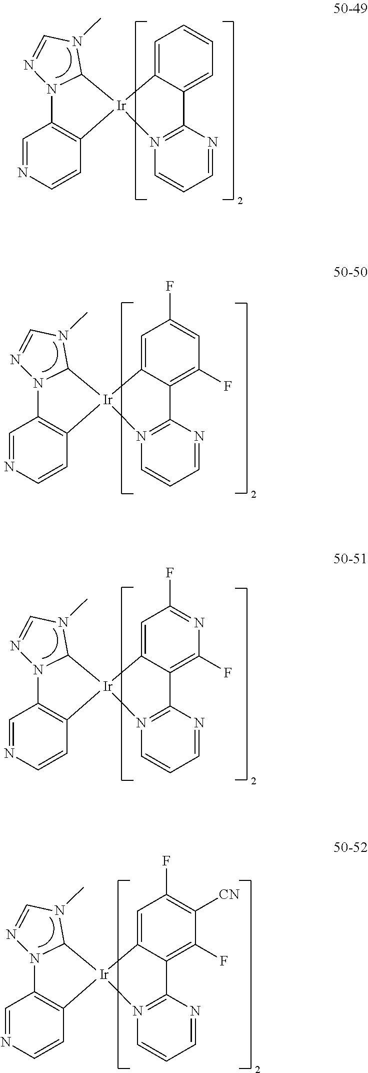

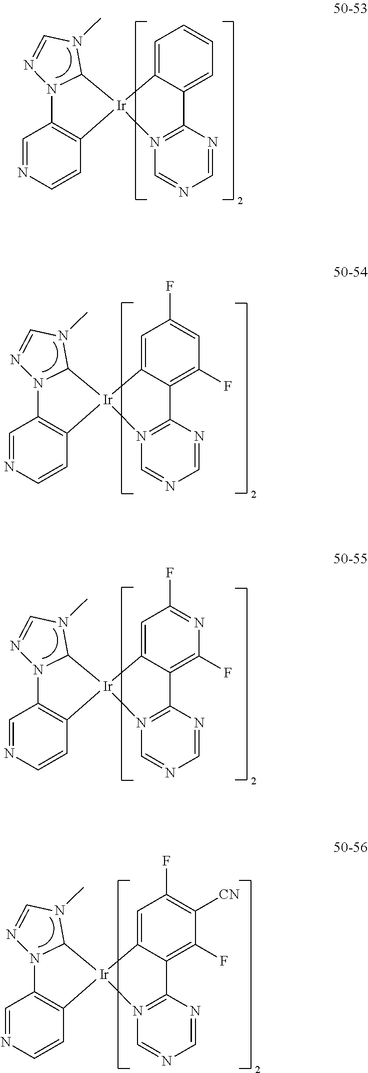

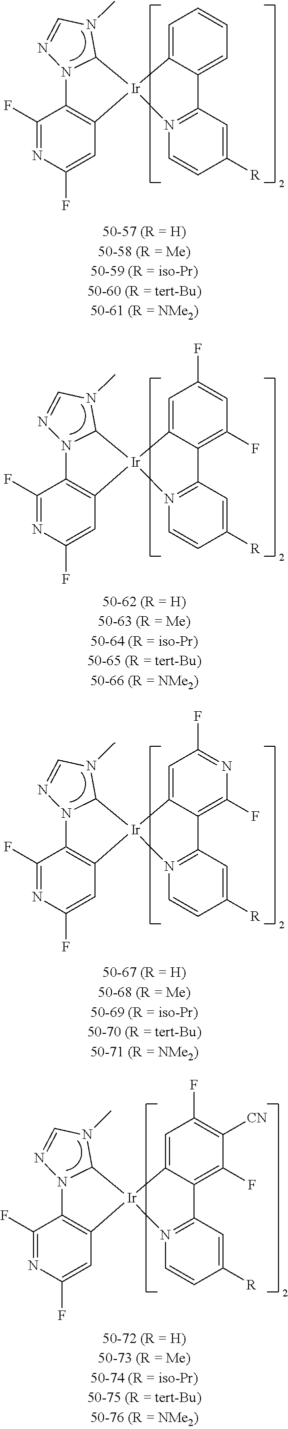

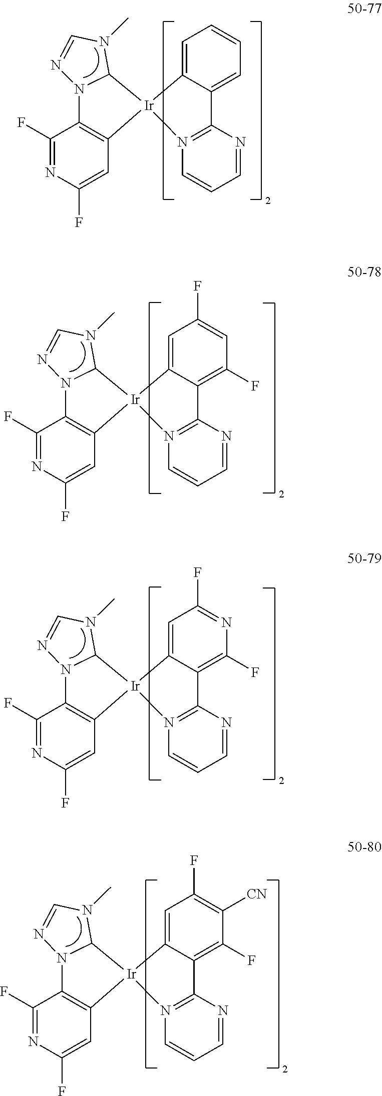

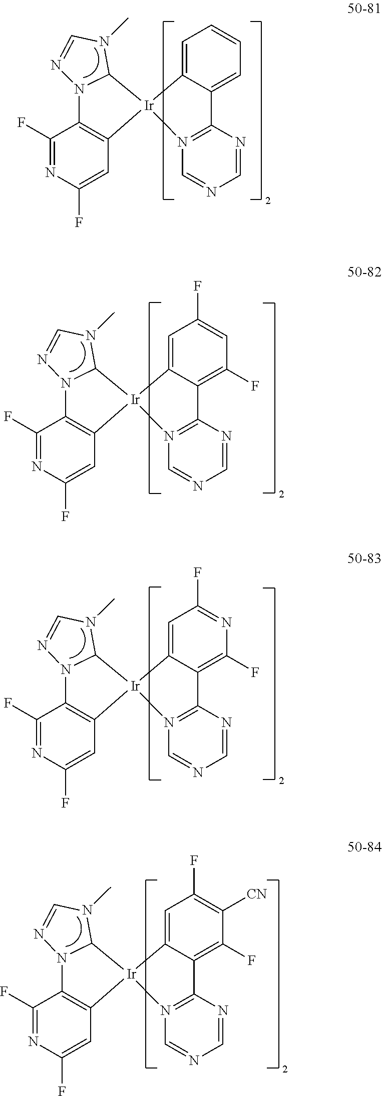

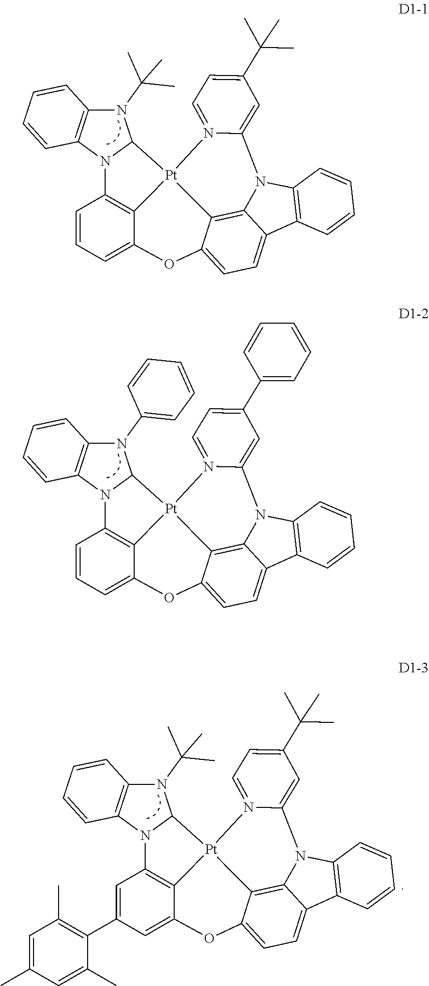

In Compounds PD1 to PD25, Compounds 40-1 to 40-14, Compounds 50-1 to 50-84, and Compounds D1-1 to D1-3, Me represents a methyl group, iso-Pr represents an isopropyl group, and tert-Bu represents a t-butyl group.

In an embodiment, the second dopant may not include a transition metal (e.g., may not be a transition metal complex).

In an embodiment, the second dopant may be a fluorescent dopant that may be to emit fluorescence. The fluorescence may be prompt fluorescence or delayed fluorescence. Therefore, the second dopant may include a prompt fluorescence dopant, a delayed fluorescence dopant, or any combination thereof.

In one or more embodiments, the second dopant may be a delayed fluorescence dopant satisfying Equation 3-2:

$${Δ E}_{ST} = S 1 ( D 2 ) - T 1 ( D 2 ) \leq 0.3 eV . \qquad Equation 3-2$$

In Equation 3-2,
S1(D2) is a lowest excitation singlet energy level of the second dopant, and
T1(D2) is a lowest excitation triplet energy level of the second dopant.

When the second dopant satisfies Equation 3-2, AEST (which is the difference between the lowest excitation triplet energy and the lowest excitation singlet energy) is significantly or suitably low, and thus, even at room temperature, thermally activated reverse intersystem crossing (RISC) from a triplet excited state to a singlet excited state may occur.

Accordingly, excitons in a triplet state of the second dopant may transition to a singlet excited state and may be used for fluorescence emission, and the fluorescence emission efficiency and/or the lifespan of the light-emitting device may be improved.

In an embodiment, the second dopant may include: i) a material that includes at least one electron donor (for example, a IT electron-rich C₃-C₆₀ cyclic group, such as a carbazole group) and at least one electron acceptor (for example, a sulfoxide group, a cyano group, and/or a TT electron-deficient nitrogen-containing C₁-C₆₀ cyclic group), ii) a material including a C₈-C₆₀ polycyclic group in which two or more cyclic groups share a boron (B) atom and are condensed with each other.

In an embodiment, the second dopant may include a heterocyclic compound represented by Formula 11:

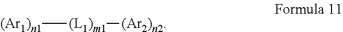

In Formula 11,
L₁ may be a C₃-C₆₀ carbocyclic group or a C₁-C₆₀ heterocyclic group, each unsubstituted or substituted with at least one R₁₀ₐ,
n1 and n2 may each independently be 0, 1, 2, or 3,
the sum of n1 and n2 may be greater than or equal to 1,
m1 may be an integer from 0 to 5, and
Ar₁ and Ar₂ may each independently be a group represented by Formula 11A-1, a group represented by Formula 11A-2, or a group represented by Formula 11B,

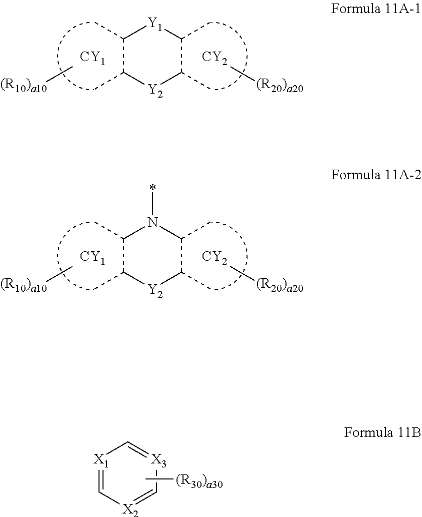

In Formulae 11A-1, 11A-2, and 11B,
Y₁ and Y₂ may each independently be a single bond, *—O—**, *—S—**, *—C(Z₁)(Z₂)—*, *—N(Z₁)—*, *—Si(Z₁)(Z₂)—*, *—C(═O)—*, *—S(═O)₂—*, *—B(Z₁)—*, *—P(Z₁)—*, or —P(═O)(Z₁)(Z₂)-**, where (e.g., provided) at least one of Y₁ and Y₂ in Formula 11A-1 may not be a single bond,
ring CY1 and ring CY2 may each independently be a C₃-C₆₀ carbocyclic group or a C₁-C₆₀ heterocyclic group,
X₁ to X₃ may each independently be C or N, wherein when each of X₁ to X₃ is C, at least one of R₃₀(s) may be a cyano group,
Z₁, Z₂, R₁₀, R₂₀, and R₃₀ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkenyl group unsubstituted or substituted with at least one R₁₀ₐ, a C₁-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a10 and a20 may each independently be an integer from 1 to 10,
a30 may be an integer from 1 to 6,
two or more of Z₁, Z₂, R₁₀, R₂₀, and R₃₀ may optionally be linked to each other to form a C₃-C₆₀ carbocyclic group unsubstituted or substituted with at least one R₁₀ₐ, or a C₁-C₆₀ heterocyclic group unsubstituted or substituted with at least one R₁₀ₐ,
two or more R₃₀ may optionally be linked to each other to form a C₃-C₆₀ carbocyclic group unsubstituted or substituted with at least one R₁₀ₐ, or a C₁-C₆₀ heterocyclic group unsubstituted or substituted with at least one R₁₀ₐ,
at least one of R₁₀ or R₂₀ in Formula 11A-1 may be a binding site to L₁ or Ar₁ in Formula 11,
* in Formula 11A-2 may be a binding site to L₁ or Ar₁ in Formula 11,
at least one of the R₃₀(s) in Formula 11B may be a binding site to L₁ or Ar₁, and
R₁₀ₐ and Q₁ to Q₃ may each independently be the same as described in the present specification.

The heterocyclic compound may efficiently block or reduce intermolecular orbital overlap by separating an electron donor moiety and an electron acceptor moiety, such that the singlet and triplet states of a molecule do not substantially overlap, and thus the heterocyclic compound may have a significantly low ΔEₛₜ. Accordingly, even at room temperature, reverse intersystem crossing from a triplet excited state to a singlet excited state through thermal activity is possible, such that the heterocyclic compound may exhibit thermally activated delayed fluorescence emitter (TADF), and thus triplet state excitons may be used for light emission, resulting in improved emission efficiency of the light-emitting device.

In one or more embodiments, the second dopant may include a condensed cyclic ring in which at least one first ring and at least one second ring are condensed with each other, wherein the at least one first ring may be a 6-membered ring including boron (B) as a ring-forming atom (for example, a 6-membered ring including boron (B) and nitrogen (N) as ring-forming atoms) and the second ring may be a pyrrole group, a furan group, a thiophene group, a benzene group, a pyridine group, or a pyrimidine group.

In one or more embodiments, the second dopant may include a heterocyclic compound represented by one of Formulae 11(4) to 11(7):

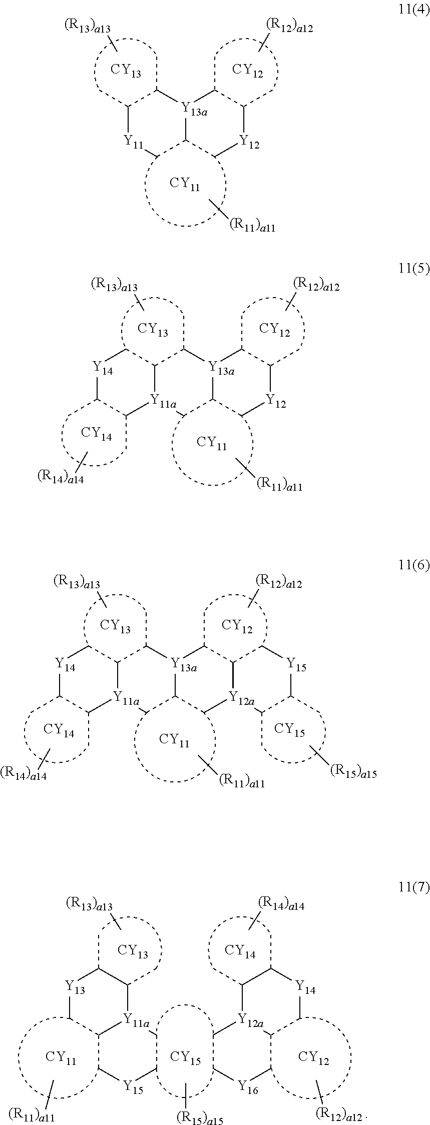

In Formulae 11(4) to 11(7),
ring CY₁₁ to ring CY₁₅ may each independently be a C₃-C₆₀ carbocyclic group or a C₁-C₆₀ heterocyclic group,
Y₁₁ to Y₁₆ may each independently be a single bond, *—O—*, *—S—**, *—C(R₁₆)(R₁₇)—**, *—N(R₁₆)—**, *—Si(R₁₆)(R₁₇)—*, *—C(═O)—*, *—S(═O)₂-**, *—B(R₁₆)—**, *—P(R₁₇)—*, or *—P(═O)(R₁₆)—*, and * and *′ may each indicate a binding site to a neighboring atom,
Y₁₁ₐ, Y₁₂ₐ, and Y₁₃ₐ may each independently be N, B, or P,
R₁₁ to R₁₇ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkenyl group unsubstituted or substituted with at least one R₁₀ₐ, a C₁-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
two or more of R₁₁ to R₁₇ may optionally be linked to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
a11 to a15 may each independently be an integer from 1 to 6, and
R₁₀ₐ and Q₁ to Q₃ may each independently be the same as described in the present specification.

In one or more embodiments, in Formulae 11(4) to 11(7), CY₁₁ to CY₁₅ may each independently be a benzene group, a naphthalene group, a carbazole group, a dibenzofuran group, a dibenzothiophene group, or a dibenzosilole group.

In one or more embodiments, in Formulae 11(4) to 11(7), R₁₁ to R₁₇ may each independently be:
hydrogen, deuterium, —F, —Cl, —Br, —I, a methyl group, an ethyl group, an n-propyl group, an isopropyl group, an n-butyl group, a sec-butyl group, an isobutyl group, a tert-butyl group, an ethenyl group, a propenyl group, a butenyl group, a methoxy group, an ethoxy group, an n-propoxy group, an isopropoxy group, an n-butoxy group, a sec-butoxy group, an isobutoxy group, or a tert-butoxy group;
a methyl group, an ethyl group, an n-propyl group, an isopropyl group, an n-butyl group, a sec-butyl group, an isobutyl group, a tert-butyl group, a methoxy group, an ethoxy group, an n-propoxy group, an isopropoxy group, an n-butoxy group, a sec-butoxy group, an isobutoxy group, or a tert-butoxy group, each substituted with deuterium, —F, —Cl, —Br, —I, a cyano group, a phenyl group, a biphenyl group, or any combination thereof;
a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphtho silolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indeno carbazolyl group, and an indolocarbazolyl group, each unsubstituted or substituted with deuterium, —F, —Cl, —Br, —I, a cyano group, a methyl group, an ethyl group, an n-propyl group, an isopropyl group, an n-butyl group, a sec-butyl group, an isobutyl group, a tert-butyl group, a methoxy group, an ethoxy group, an n-propoxy group, an isopropoxy group, an n-butoxy group, a sec-butoxy group, an isobutoxy group, a tert-butoxy group, a cyclopentyl group, a cyclohexyl group, a cycloheptyl group, a cyclopentenyl group, a cyclohexenyl group, a phenyl group, a biphenyl group, a terphenyl group, a pentalenyl group, an indenyl group, a naphthyl group, an azulenyl group, an indacenyl group, an acenaphthyl group, a fluorenyl group, a spiro-bifluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a perylenyl group, a pentacenyl group, a pyrrolyl group, a thiophenyl group, a furanyl group, a silolyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an indolyl group, an isoindolyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a benzoquinazolinyl group, a cinnolinyl group, a phenanthridinyl group, an acridinyl group, a phenanthrolinyl group, a phenazinyl group, a benzimidazolyl group, a benzofuranyl group, a benzothiophenyl group, a benzosilolyl group, a benzothiazolyl group, a benzoisothiazolyl group, a benzoxazolyl group, a benzoisoxazolyl group, a triazolyl group, a tetrazolyl group, a thiadiazolyl group, an oxadiazolyl group, a triazinyl group, a carbazolyl group, a dibenzofuranyl group, a dibenzothiophenyl group, a dibenzosilolyl group, a benzocarbazolyl group, a naphthobenzofuranyl group, a naphthobenzothiophenyl group, a naphthobenzosilolyl group, a dibenzocarbazolyl group, a dinaphthofuranyl group, a dinaphthothiophenyl group, a dinaphtho silolyl group, an imidazopyridinyl group, an imidazopyrimidinyl group, an oxazolopyridinyl group, a thiazolopyridinyl group, a benzonaphthyridinyl group, an azafluorenyl group, an azaspiro-bifluorenyl group, an azacarbazolyl group, an azadibenzofuranyl group, an azadibenzothiophenyl group, an azadibenzosilolyl group, an indenopyrrolyl group, an indolopyrrolyl group, an indeno carbazolyl group, an indolocarbazolyl group, —Si(Q₃₁)(Q₃₂)(Q₃₃), —N(Q₃₁)(Q₃₂), —B(Q₃₁)(Q₃₂), —C(═O)(Q₃₁), —S(═O)(Q₃₁), —S(═O)₂(Q₃₁), —P(═O)(Q₃₁)(Q₃₂), —P(═S)(Q₃₁)(Q₃₂), or any combination thereof; or
—N(Q₁₁)(Q₁₂).

In one or more embodiments, the second dopant may include one of Compounds 12-1 to 12-10, Compound D2-1, or any combination thereof:

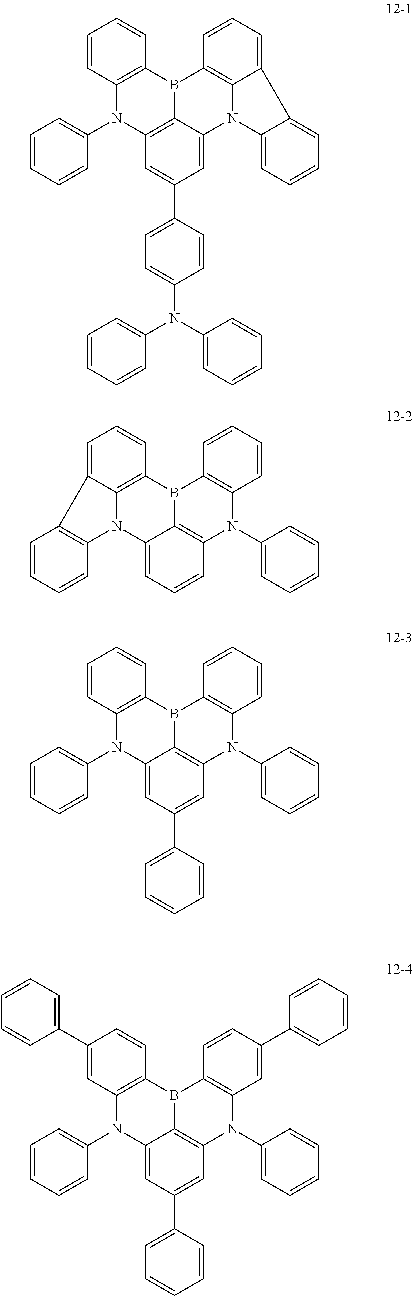

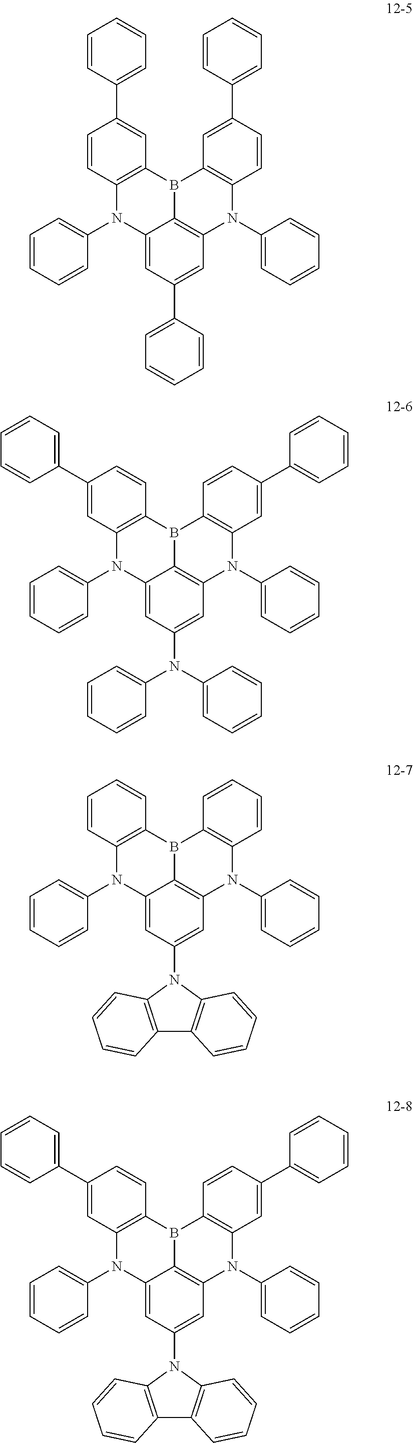 [SMILES: c1ccc(-c2ccc3c(c2)B2c4cc(-c5ccccc5)ccc4N(c4ccccc4)c4cc(-c5ccccc5)cc(c42)N3c2ccccc2)cc1 ; c1ccc(-c2ccc3c(c2)N(c2ccccc2)c2cc(N(c4ccccc4)c4ccccc4)cc4c2B3c2ccc(-c3ccccc3)cc2N4c2ccccc2)cc1 ; c1ccc(N2c3ccccc3B3c4ccccc4N(c4ccccc4)c4cc(-n5c6ccccc6c6ccccc65)cc2c43)cc1 ; c1ccc(-c2ccc3c(c2)N(c2ccccc2)c2cc(-n4c5ccccc5c5ccccc54)cc4c2B3c2ccc(-c3ccccc3)cc2N4c2ccccc2)cc1]

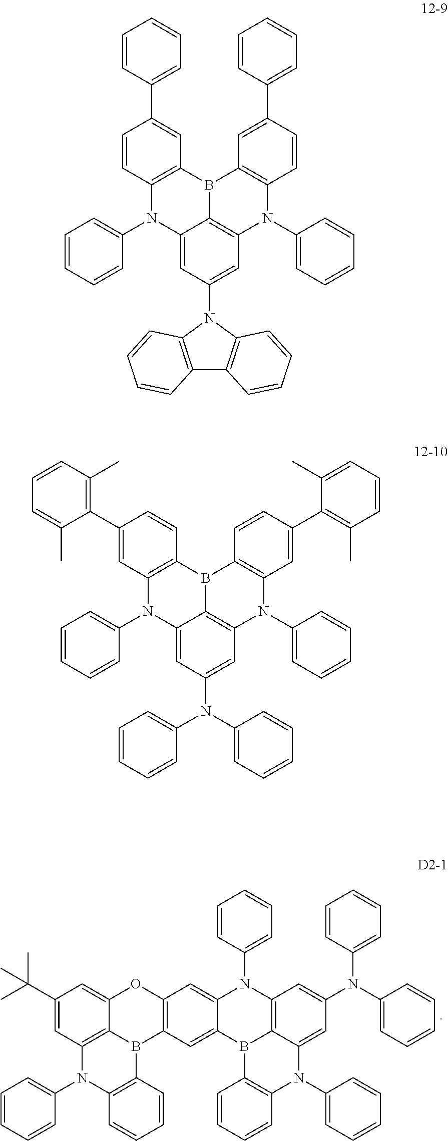 [SMILES: c1ccc(-c2ccc3c(c2)B2c4cc(-c5ccccc5)ccc4N(c4ccccc4)c4cc(-n5c6ccccc6c6ccccc65)cc(c42)N3c2ccccc2)cc1 ; Cc1cccc(C)c1-c1ccc2c(c1)N(c1ccccc1)c1cc(N(c3ccccc3)c3ccccc3)cc3c1B2c1ccc(-c2c(C)cccc2C)cc1N3c1ccccc1 ; CC(C)(C)c1cc2c3c(c1)N(c1ccccc1)c1ccccc1B3c1cc3c(cc1O2)N(c1ccccc1)c1cc(N(c2ccccc2)c2ccccc2)cc2c1B3c1ccccc1N2c1ccccc1]

In one or more embodiments, the second dopant may be a prompt fluorescence dopant.

In an embodiment, the fluorescent dopant may include an amine group-containing compound, a styryl group-containing compound, or any combination thereof.

In an embodiment, the fluorescent dopant may include a compound represented by Formula 501:

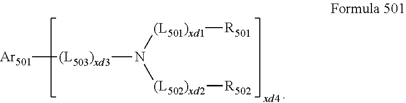

In Formula 501,
Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
xd1 to xd3 may each independently be 0, 1, 2, or 3, and
xd4 may be 1, 2, 3, 4, 5, or 6.

In an embodiment, Ar₅₀₁ in Formula 501 may be a condensed cyclic group in which three or more monocyclic groups are condensed (for example, an anthracene group, a chrysene group, or a pyrene group).

In an embodiment, xd4 in Formula 501 may be 2.

In an embodiment, Ar₅₀₁ in Formula 501 may be a naphthalene group, a heptalene group, a fluorene group, a spiro-bifluorene group, a benzofluorene group, a dibenzofluorene group, a phenalene group, a phenanthrene group, an anthracene group, a fluoranthene group, a triphenylene group, a pyrene group, a chrysene group, a naphthacene group, a picene group, a perylene group, a pentaphene group, an indenoanthracene group, an indeno phenanthrene group, or a group represented by

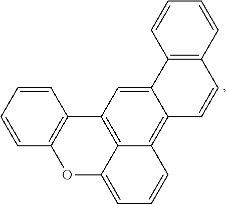 [SMILES: c1ccc2c(c1)Oc1cccc3c1c-2cc1c2ccccc2ccc31]

each unsubstituted or substituted with at least one R₁₀ₐ.

In one or more embodiments, in Formula 501, L₅₀₁ to L₅₀₃, R₅₀₁, and R₅₀₂ may each independently be a benzene group, a naphthalene group, a fluorene group, a spiro-bifluorene group, a benzofluorene group, a dibenzofluorene group, a phenanthrene group, an anthracene group, a fluoranthene group, a triphenylene group, a pyrene group, a chrysene group, a perylene group, a pentaphene group, a hexacene group, a pentacene group, a thiophene group, a furan group, a carbazole group, an indole group, an isoindole group, a benzofuran group, a benzothiophene group, a dibenzofuran group, a dibenzothiophene group, a benzocarbazole group, a dibenzocarbazole group, a dibenzosilole group, or a pyridine group, each unsubstituted or substituted with at least one R₁₀ₐ.

In an embodiment, the fluorescent dopant may include one of Compounds FD1 to FD37, DPVBi, DPAVBi, or any combination thereof:

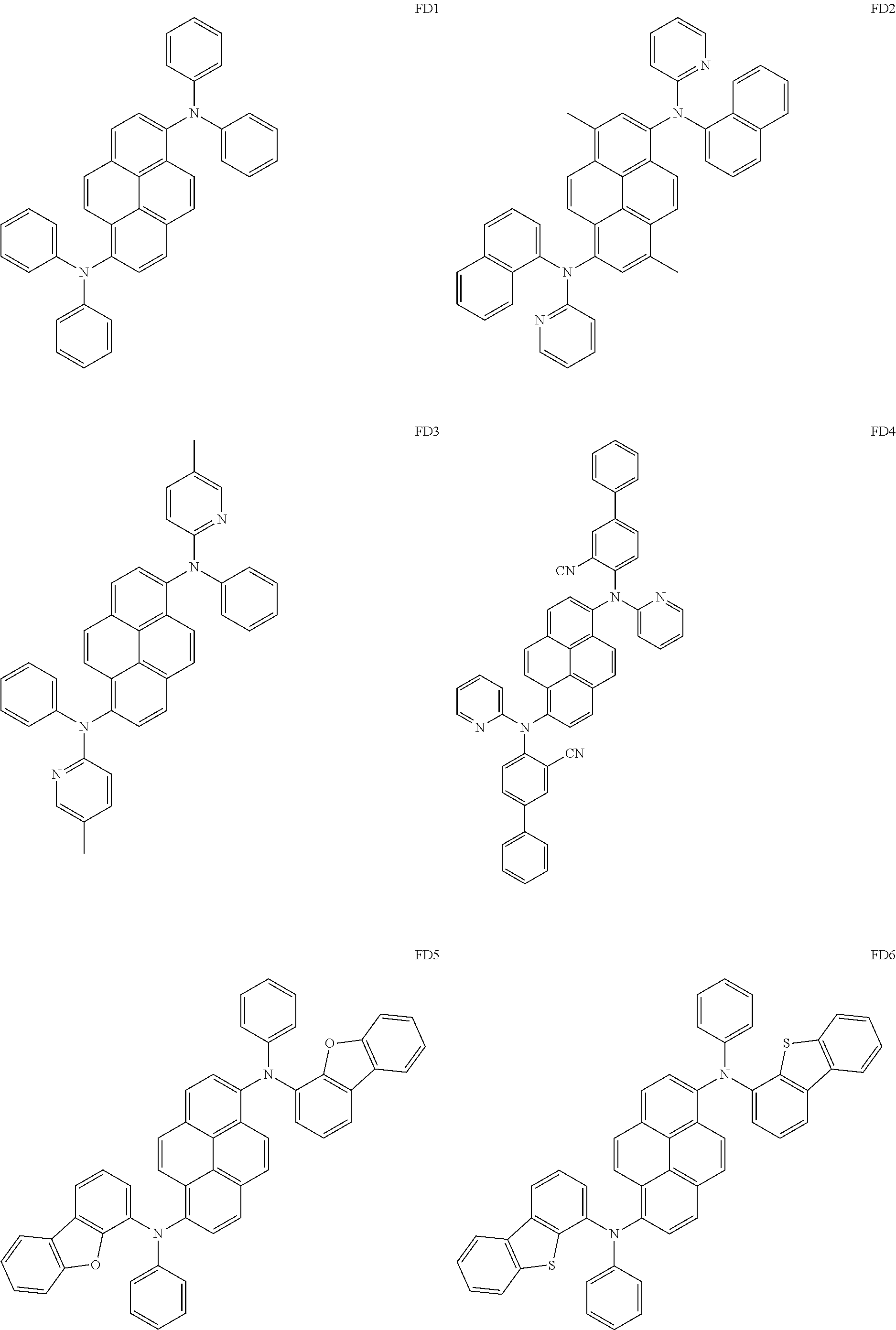

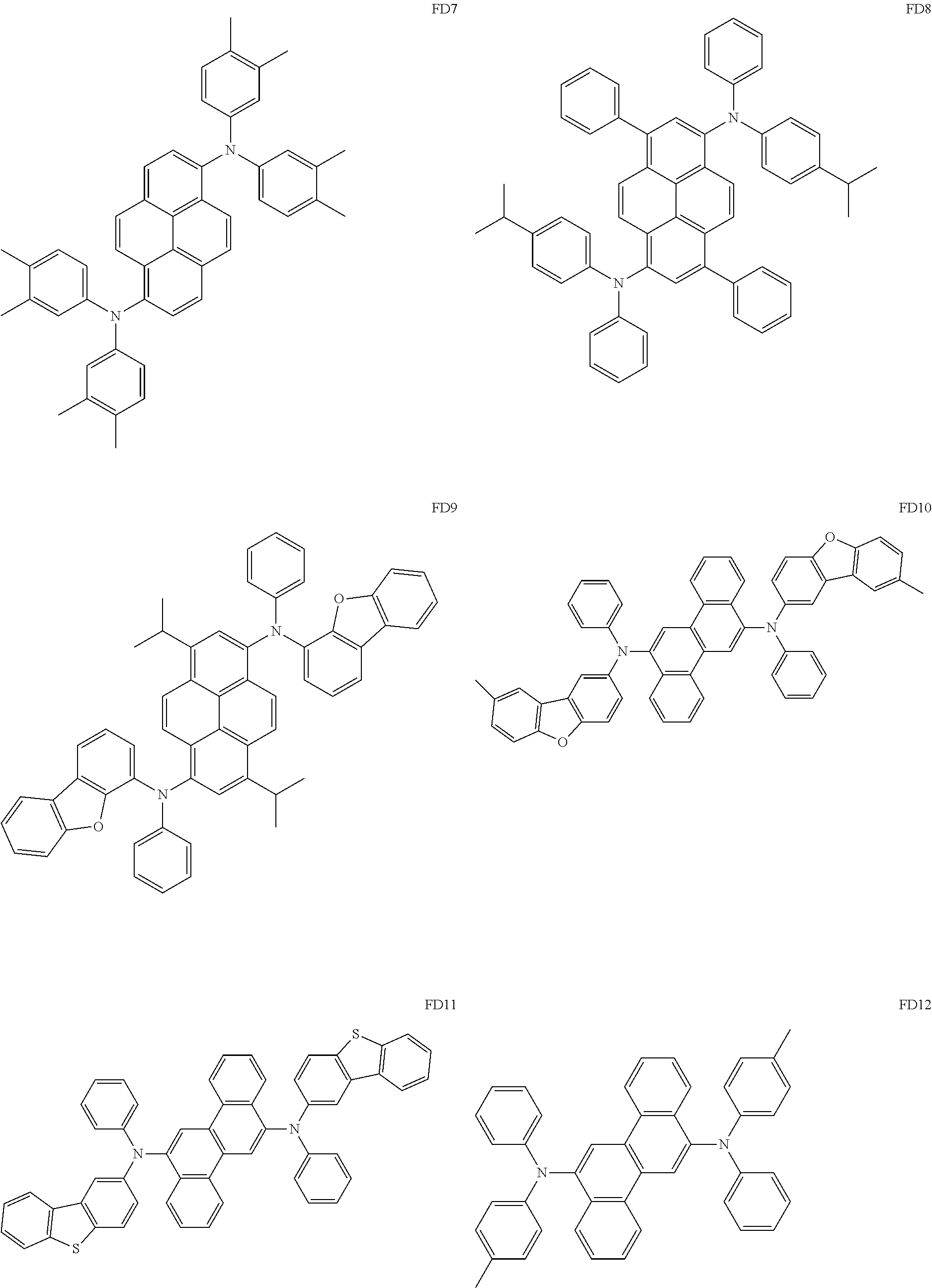

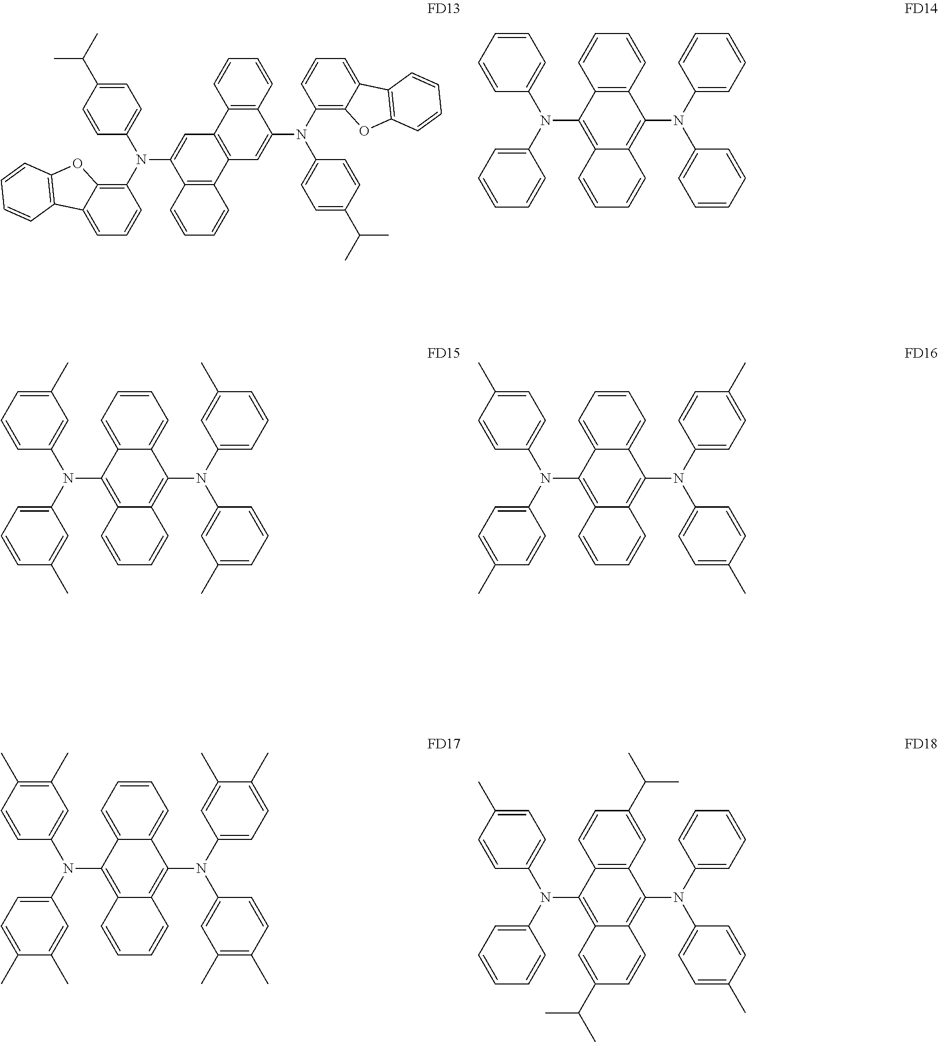

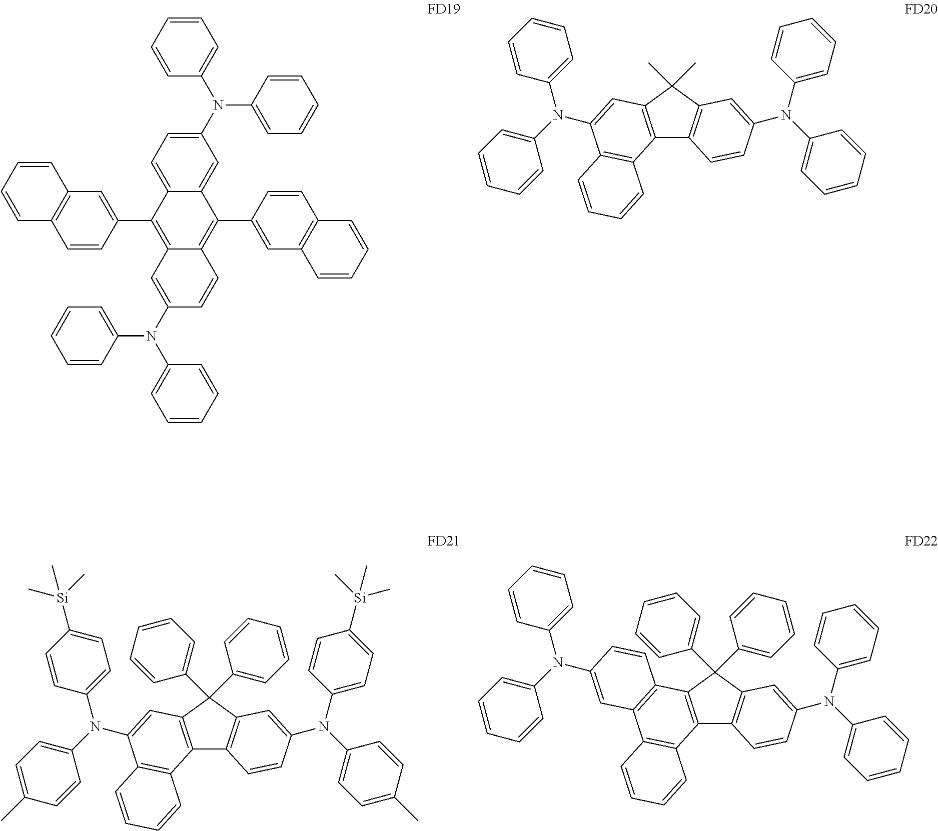

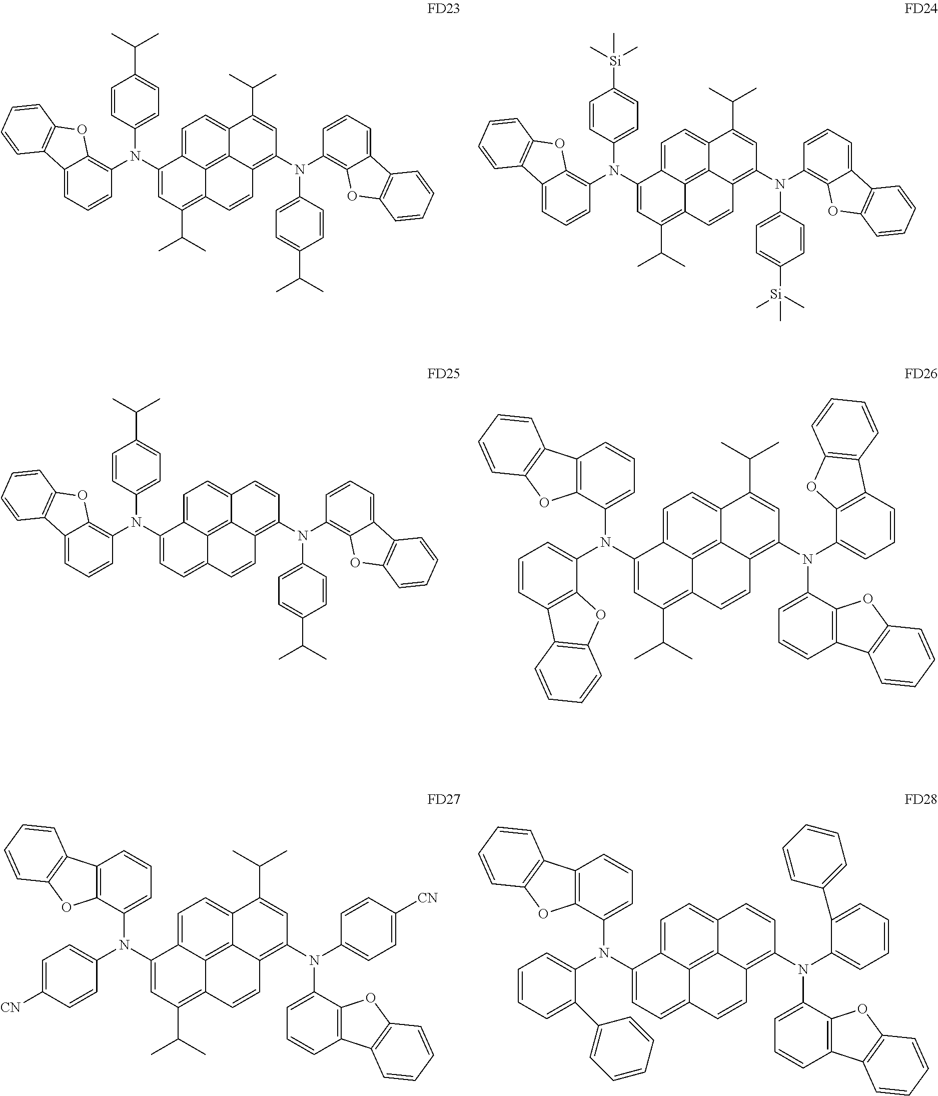

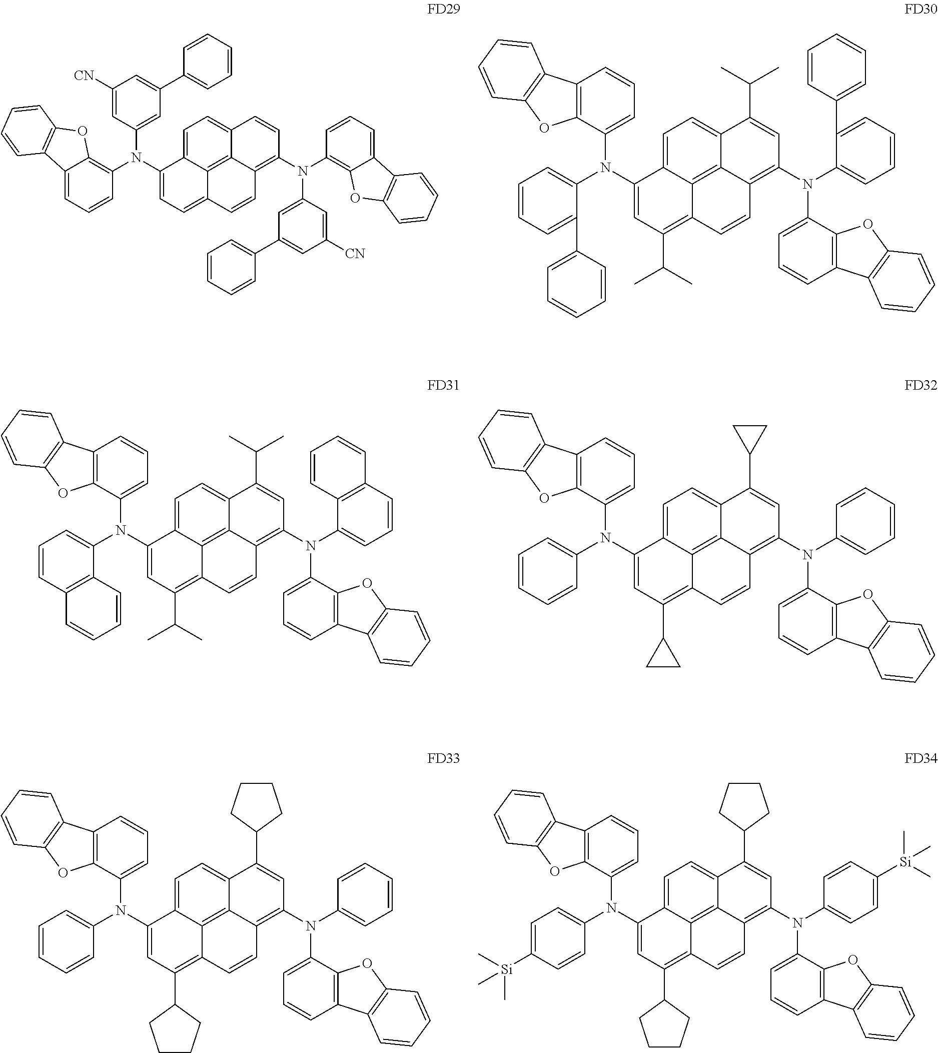

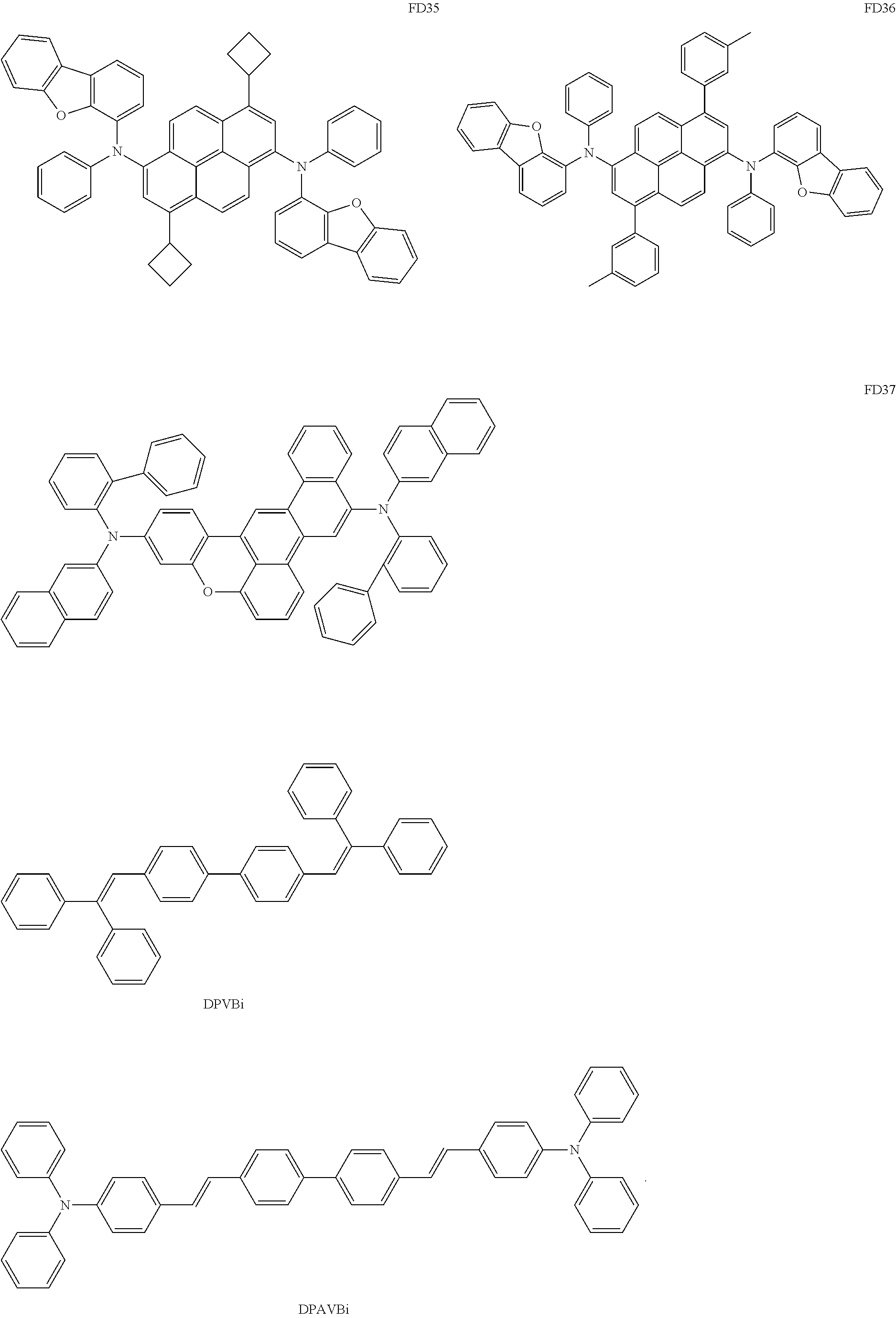

### Electron Transport Region in Interlayer 130

The electron transport region may have: i) a single-layered structure including (e.g., consisting of) a single layer including (e.g., consisting of) a single material, ii) a single-layered structure including (e.g., consisting of) a single layer including (e.g., consisting of) a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

In an embodiment, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the constituting layers of each structure are sequentially stacked from an emission layer.

The electron transport region (for example, the buffer layer, the hole blocking layer, the electron control layer, and/or the electron transport layer in the electron transport region) may include a metal-free compound including at least one IT-electron-deficient nitrogen-containing C₁-C₆₀ cyclic group.

In an embodiment, the electron transport region may include a compound represented by Formula 601:

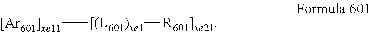

In Formula 601,
Ar₆₀₁ and L₆₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,
xe11 may be 1, 2, or 3,
xe1 may be 0, 1, 2, 3, 4, or 5,
R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),
Q₆₀₁ to Q₆₀₃ may each independently be the same as described in connection with Q₁,
xe21 may be 1, 2, 3, 4, or 5, and
at least one of Ar₆₀₁, L₆₀₁, or R₆₀₁ may each independently be a π electron-deficient nitrogen-containing C₁-C₆₀ cyclic group unsubstituted or substituted with at least one R₁₀ₐ.

In an embodiment, when xe11 in Formula 601 is 2 or more, the two or more Ar₆₀₁(s) may be linked to each other via a single bond.

In an embodiment, Ar₆₀₁ in Formula 601 may be a substituted or unsubstituted anthracene group.

In an embodiment, the electron transport region may include a compound represented by Formula 601-1:

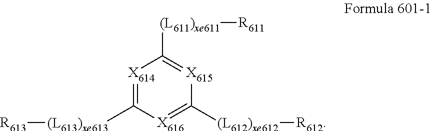

In Formula 601-1,
X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,
L₆₁₁ to L₆₁₃ may each independently be the same as described in connection with L₆₀₁,
xe611 to xe613 may each independently be the same as described in connection with xe1,
R₆₁₁ to R₆₁₃ may each independently be the same as described in connection with R₆₀₁, and
R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, xe1 and xe611 to xe613 in Formulae 601 and 601-1 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

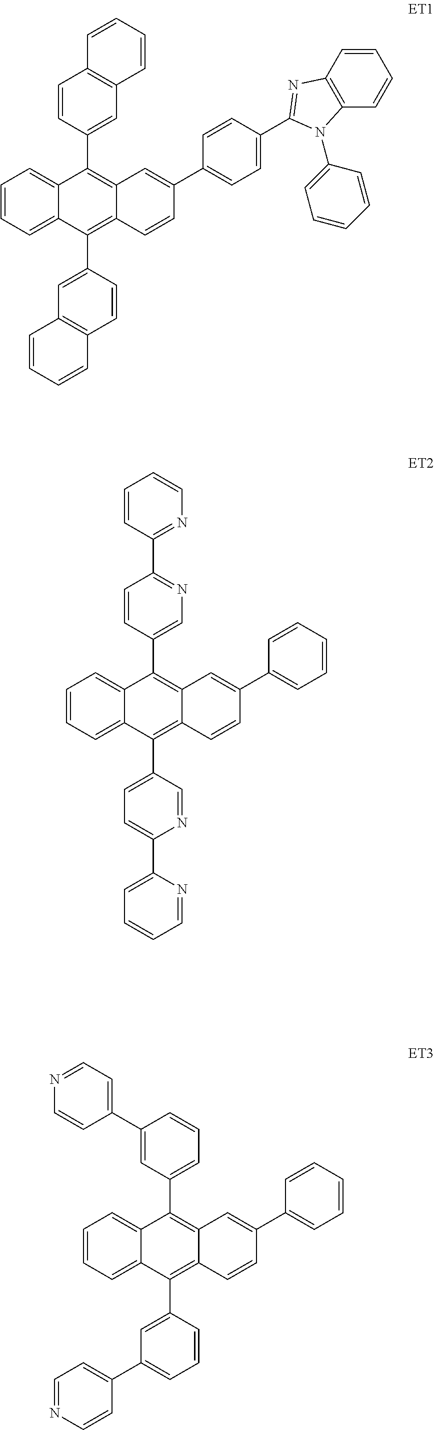 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

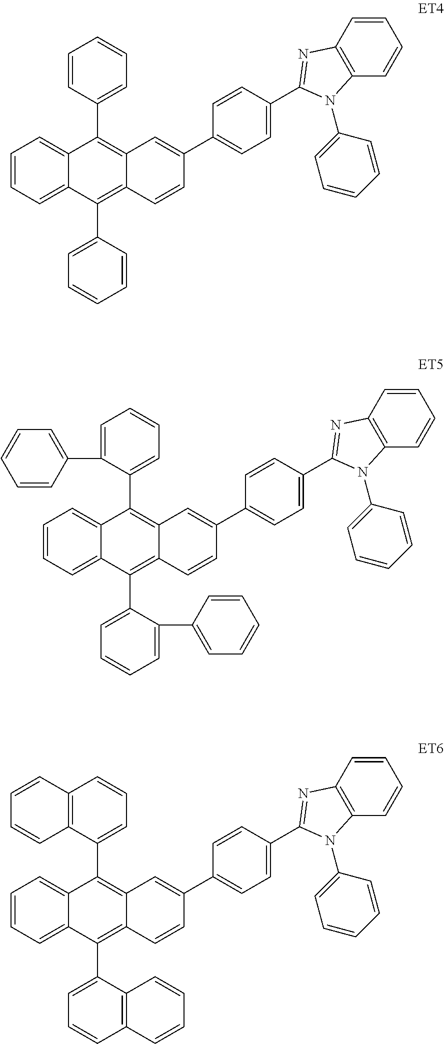 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

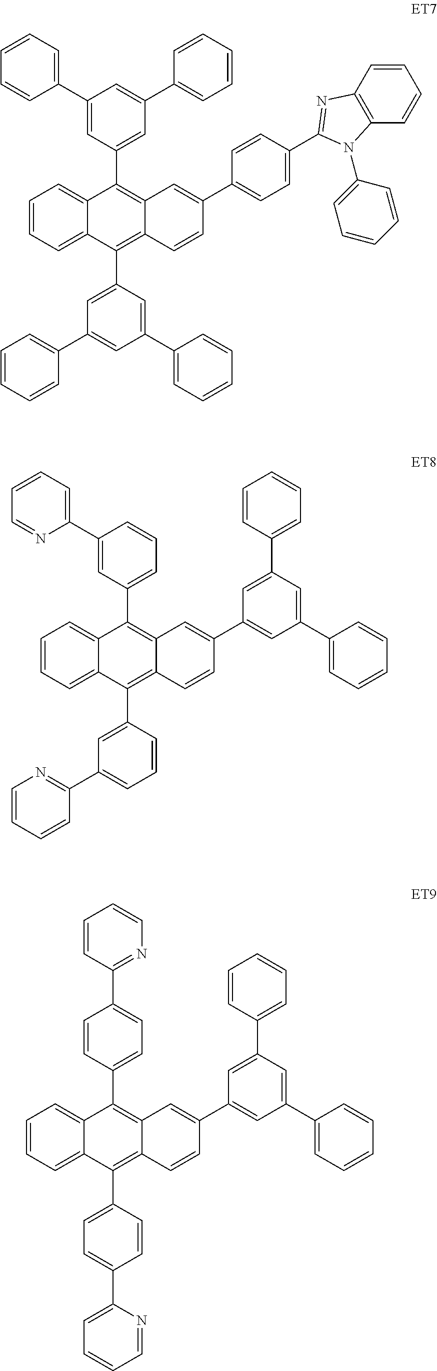 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

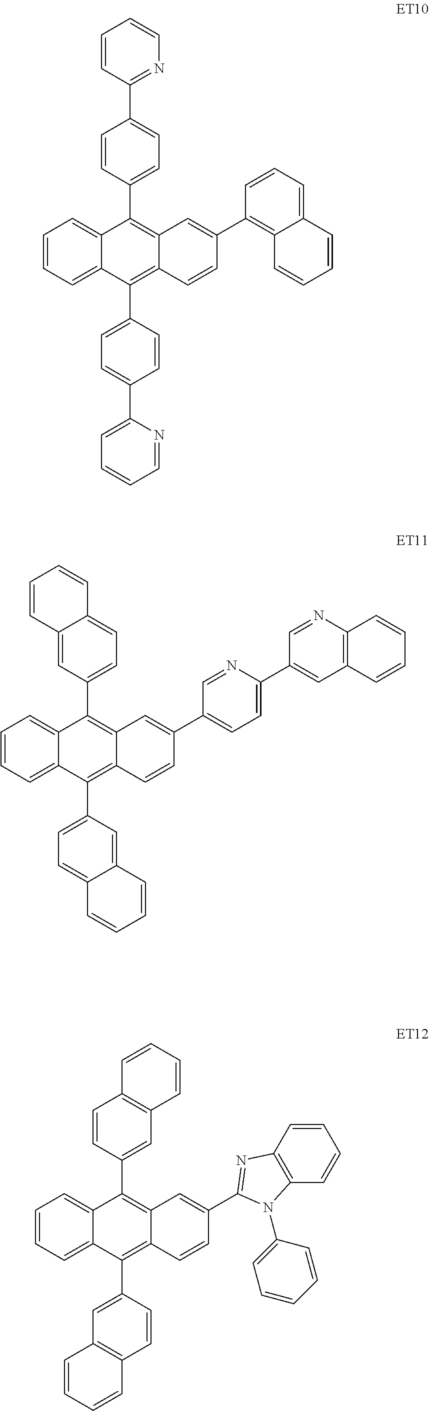 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

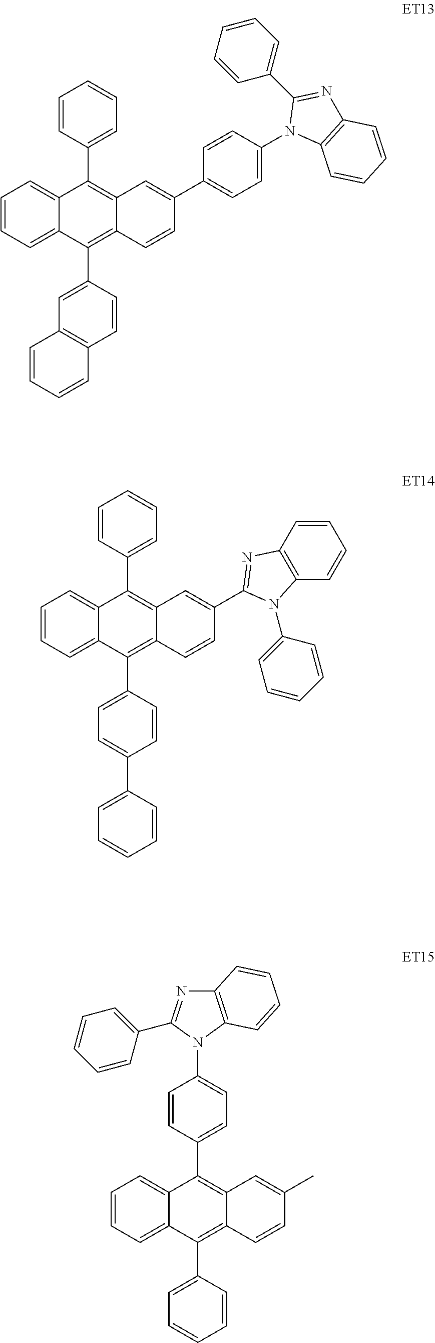 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

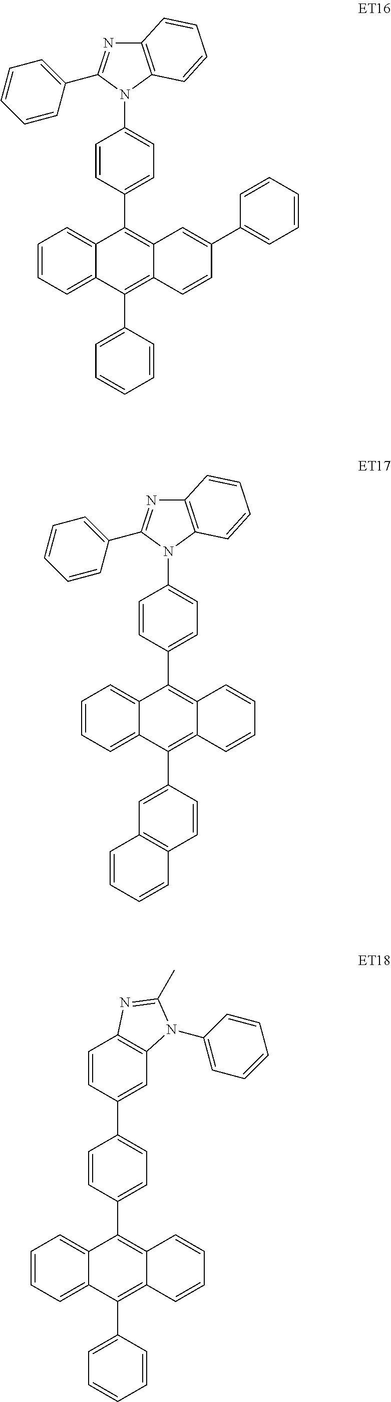 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

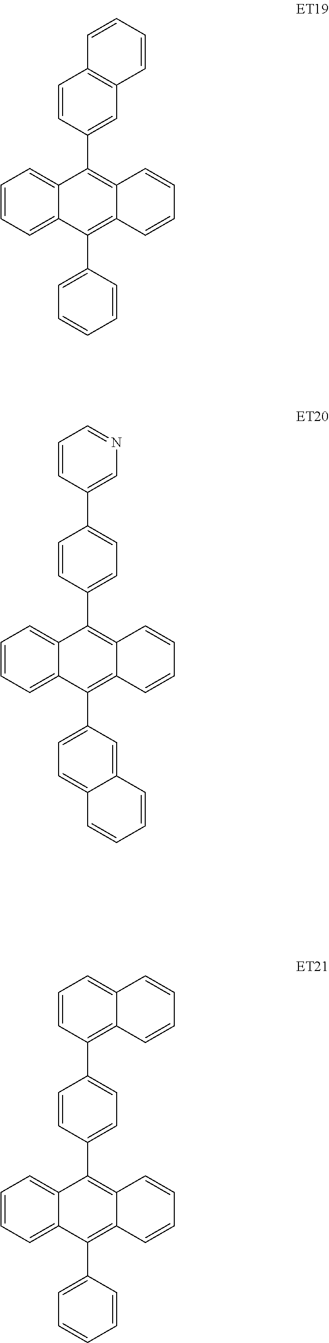

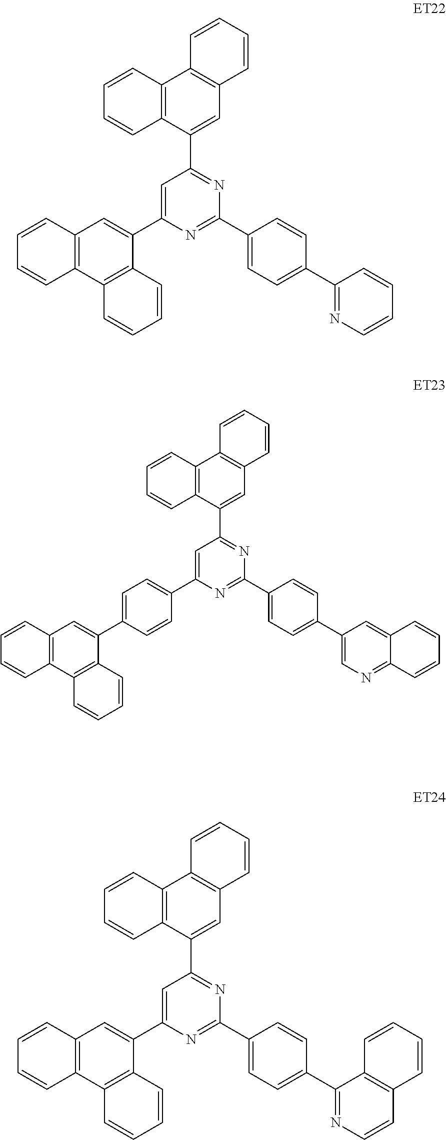 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

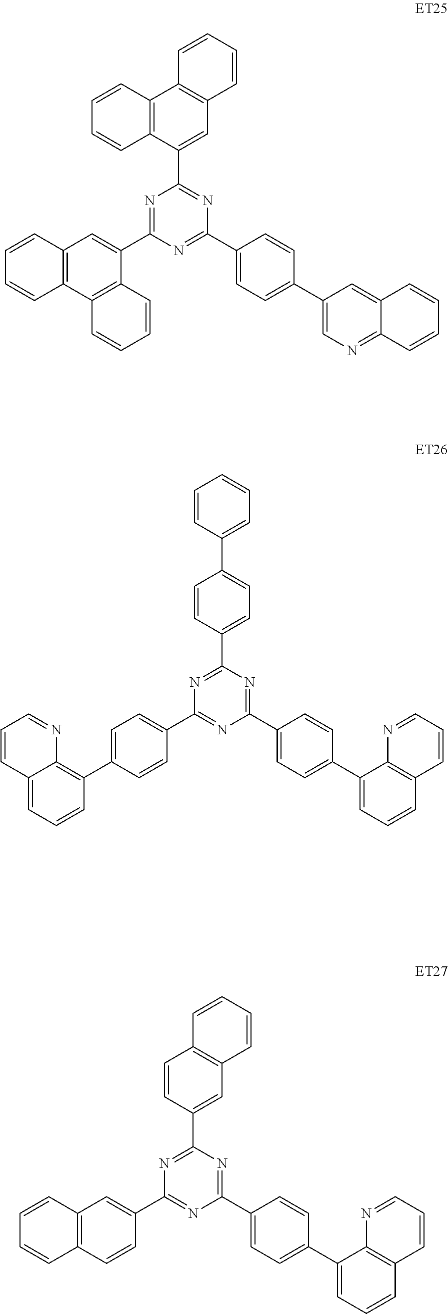 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

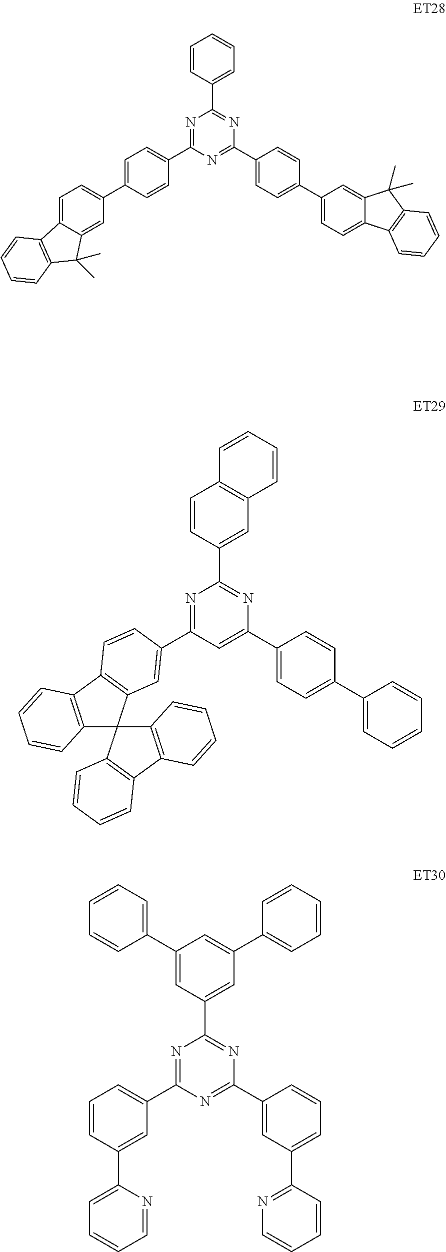 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

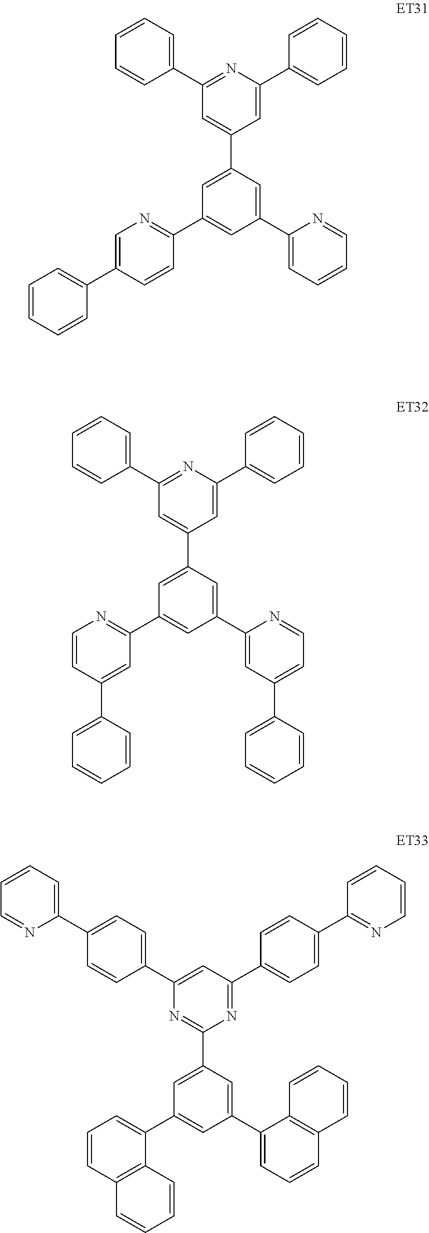 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

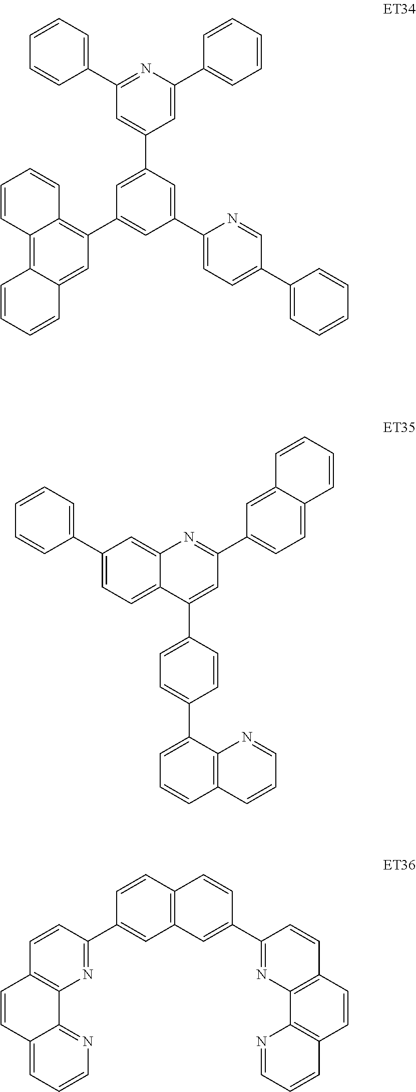 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

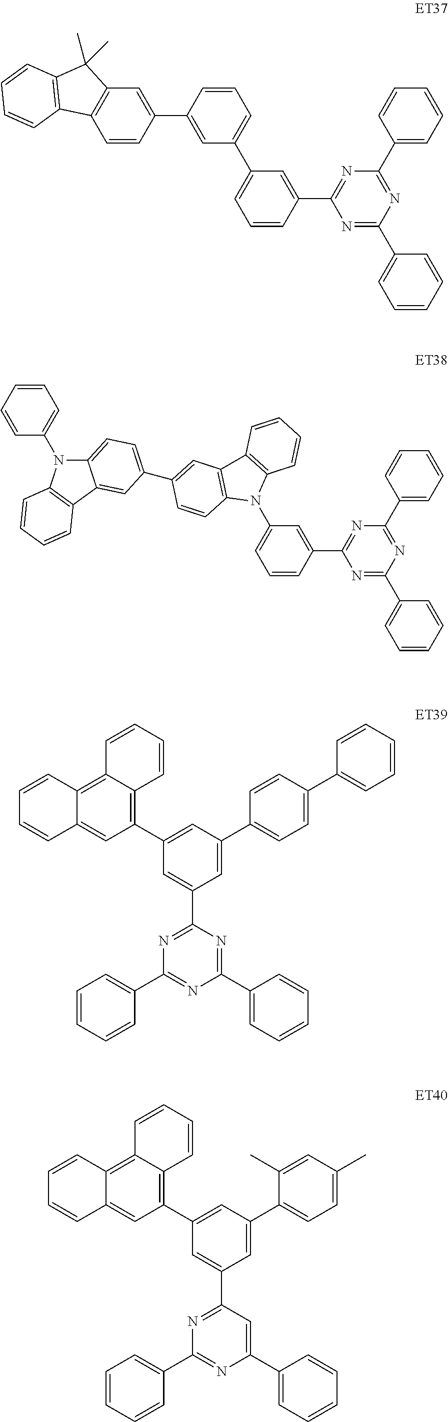 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3cc(-c4ccccc4)nc(-c4ccccc4)n3)cc(-c3cc4ccccc4c4ccccc34)c2)c(C)c1]

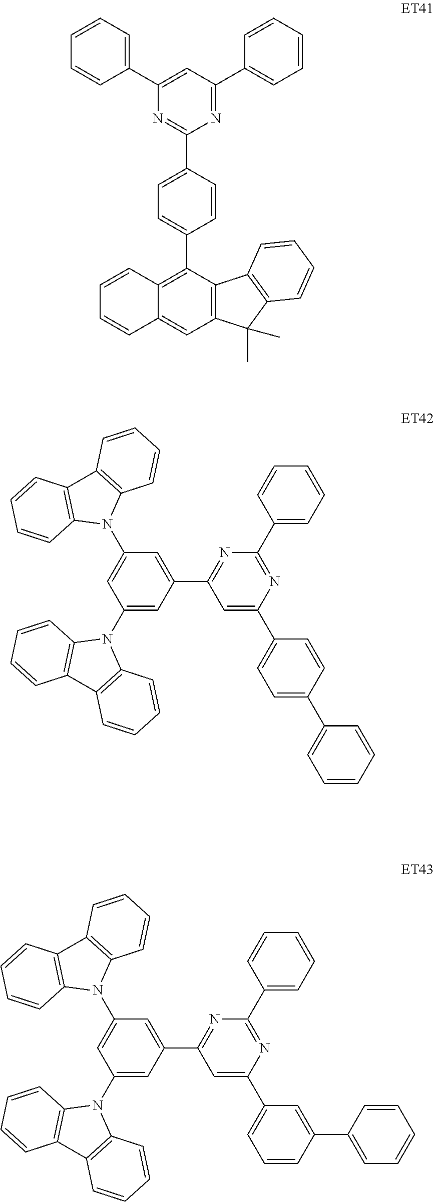 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

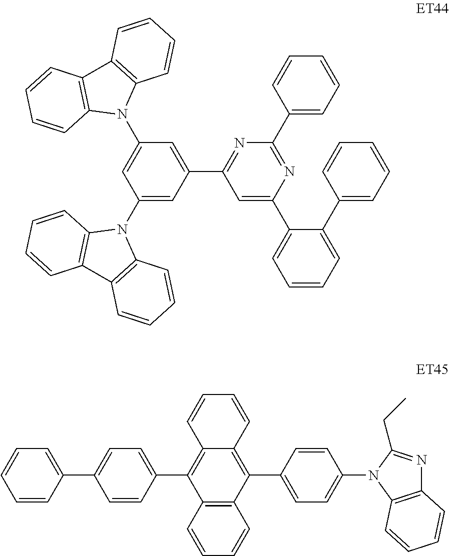 [SMILES: c1ccc(-c2nc(-c3cc(-n4c5ccccc5c5ccccc54)cc(-n4c5ccccc5c5ccccc54)c3)cc(-c3ccccc3-c3ccccc3)n2)cc1 ; CCc1nc2ccccc2n1-c1ccc(-c2c3ccccc3c(-c3ccc(-c4ccccc4)cc3)c3ccccc23)cc1]

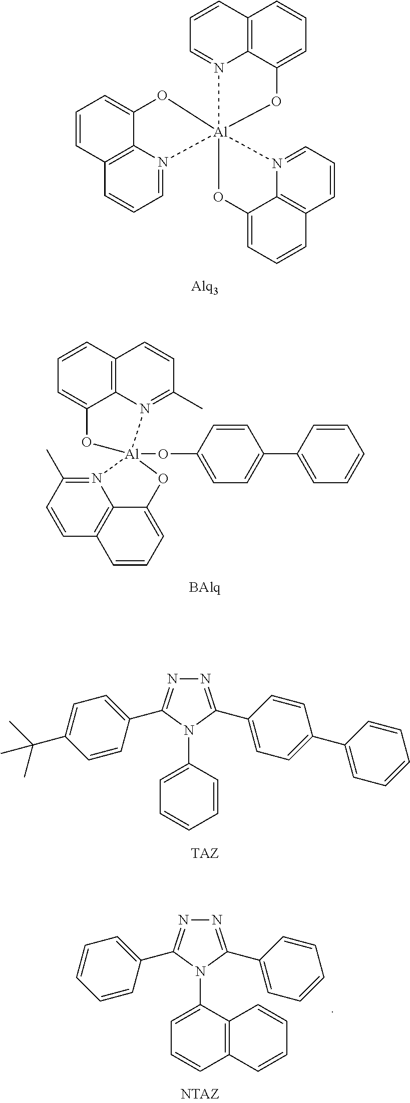

A thickness of the electron transport region may be about 100 Å to about 5,000 Å, for example, about 160 Å to about 4,000 Å. When the electron transport region includes a buffer layer, a hole blocking layer, an electron control layer, an electron transport layer, or any combination thereof, the thicknesses of the buffer layer, the hole blocking layer, and/or the electron control layer may each independently be about 20 Å to about 1,000 Å, for example, about 30 Å to about 300 Å, and the thickness of the electron transport layer may be about 100 Å to about 1,000 Å, for example, about 150 Å to about 500 Å. When the thicknesses of the buffer layer, the hole blocking layer, the electron control layer, and/or the electron transport layer are within these ranges, satisfactory hole transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth-metal complex, or any combination thereof. A metal ion of the alkali metal complex may be a Li ion, a Na ion, a K ion, a Rb ion, or a Cs ion, and a metal ion of the alkaline earth-metal complex may be a Be ion, a Mg ion, a Ca ion, a Sr ion, or a Ba ion. A ligand coordinated with the metal ion of the alkali metal complex or the alkaline earth-metal complex may be a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or ET-D2:

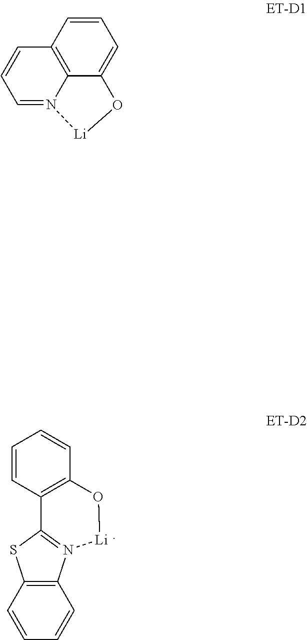

The electron transport region may include an electron injection layer to facilitate injection of electrons from the second electrode 150. The electron injection layer may directly contact the second electrode 150.

The electron injection layer may have: i) a single-layered structure including (e.g., consisting of) a single layer including (e.g., consisting of) a single material, ii) a single-layered structure including (e.g., consisting of) a single layer including a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof.

The alkali metal may include Li, Na, K, Rb, Cs, or any combination thereof. The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may be or include oxides, tellurides, and/or halides (for example, fluorides, chlorides, bromides, and/or iodides) of the alkali metal, the alkaline earth metal, and the rare earth metal, respectively.

The alkali metal-containing compound may be an alkali metal oxide (such as Li₂O, Cs₂O, or K₂O), and/or an alkali metal halide (such as LiF, NaF, CsF, KF, LiI, NaI, CsI, or KI). The alkaline earth metal-containing compound may include an alkaline earth metal oxide (such as BaO, SrO, CaO, BaₓSr₁₋ₓO (x is a real number that satisfies the condition of 0<x<1), and/or BaₓCa₁₋ₓO (x is a real number that satisfies the condition of 0<x<1)). The rare earth metal-containing compound may include YbF₃, ScF₃, SC₂O₃, Y₂O₃, Ce₂O₃, GdF₃, TbF₃, YbI₃, ScI₃, TbI₃, or any combination thereof. In an embodiment, the rare earth metal-containing compound may be or include a lanthanide metal telluride. Non-limiting examples of the lanthanide metal telluride include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and/or Lu₂Te₃.

The alkali metal complex, the alkaline earth-metal complex, and the rare earth metal complex may each include i) an ion of the alkali metal, the alkaline earth metal, and the rare earth metal, respectively, and ii) a ligand linked to the metal ion, for example, hydroxyquinoline, hydroxy isoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof, or may further include an organic material (for example, a compound represented by Formula 601).

In an embodiment, the electron injection layer may include (e.g., consist of): i) an alkali metal-containing compound (for example, an alkali metal halide), or ii) a) an alkali metal-containing compound (for example, an alkali metal halide); and b) an alkali metal, an alkaline earth metal, a rare earth metal, or any combination thereof. In an embodiment, the electron injection layer may be a KI:Yb co-deposited layer or a RbI:Yb co-deposited layer.

When the electron injection layer further includes an organic material, the alkali metal, the alkaline earth metal, the rare earth metal, the alkali metal-containing compound, the alkaline earth metal-containing compound, the rare earth metal-containing compound, the alkali metal complex, the alkaline earth-metal complex, the rare earth metal complex, or combination thereof may be substantially homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in driving voltage.

### Second Electrode 150

The second electrode 150 may be located on the interlayer 130 having the above-described structure. The second electrode 150 may be a cathode (which is an electron injection electrode), and a metal, an alloy, an electrically conductive compound, or any combination thereof, each having a low work function, may be used as the material for forming the second electrode 150.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multi-layered structure including two or more layers.

### Capping Layer

A first capping layer may be located outside the first electrode 110, and/or a second capping layer may be located outside the second electrode 150. In detail, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in an emission layer of the interlayer 130 of the light-emitting device 10 may be extracted or transmitted toward the outside through the first electrode 110 (which is a semi-transmissive electrode or a transmissive electrode) and the first capping layer, and light generated in an emission layer of the interlayer 130 of the light-emitting device 10 may be extracted or transmitted toward the outside through the second electrode 150 (which is a semi-transmissive electrode or a transmissive electrode) and the second capping layer.

The first capping layer and/or the second capping layer may increase the external luminescence efficiency of the device according to the principle of constructive interference. Accordingly, the light extraction efficiency of the light-emitting device 10 may be increased, and the luminescence efficiency of the light-emitting device 10 may be improved.

Each of the first capping layer and the second capping layer may include a material having a refractive index of 1.6 or more (at 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer or the second capping layer may each independently include a carbocyclic compound, a heterocyclic compound, an amine group-containing compound, a porphyrin derivative, a phthalocyanine derivative, a naphthalocyanine derivative, an alkali metal complex, an alkaline earth-metal complex, or any combination thereof. The carbocyclic compound, the heterocyclic compound, and the amine group-containing compound may each be optionally substituted with a substituent containing O, N, S, Se, Si, F, Cl, Br, I, or any combination thereof.

In an embodiment, at least one of the first capping layer or the second capping layer may each independently include an amine group-containing compound.

In an embodiment, at least one of the first capping layer or second capping layer may each independently include a compound represented by Formula 201, a compound represented by Formula 202, or any combination thereof.

In an embodiment, at least one of the first capping layer or the second capping layer may each independently include one of Compounds HT28 to HT33, one of Compounds CP1 to CP6, β-NPB, or any combination thereof:

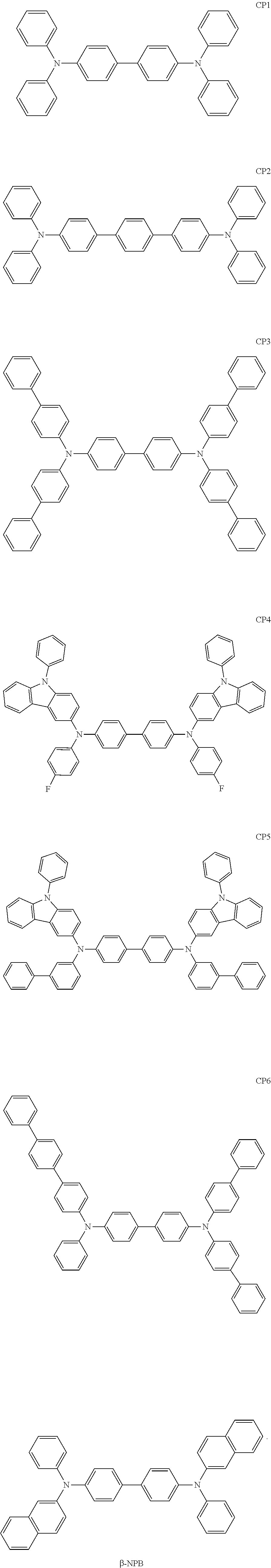

### Electronic Apparatus

The light-emitting device may be included in one or more suitable electronic apparatuses. In an embodiment, an electronic apparatus including the light-emitting device may be a light-emitting apparatus, an authentication apparatus, and/or the like.

The electronic apparatus (for example, light-emitting apparatus) may further include, in addition to the light-emitting device, i) a color filter, ii) a color conversion layer, or iii) a color filter and a color conversion layer. The color filter and/or the color conversion layer may be located in at least one traveling direction of light to be emitted from the light-emitting device. In an embodiment, light to be emitted from the light-emitting device may be blue light or white light. The light-emitting device may be the same as described above. In an embodiment, the color conversion layer may include a quantum dot.

The electronic apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the plurality of subpixel areas.

A pixel-defining film may be located between the plurality of subpixel areas to define each of the subpixel areas.

The color filter may further include a plurality of color filter areas and light-blocking patterns located between the plurality of color filter areas, and the color conversion layer may further include a plurality of color conversion areas and light-blocking patterns located between the plurality of color conversion areas.

The plurality of color filter areas (and/or the plurality of color conversion areas) may each independently include a first area to emit first-color light, a second area to emit second-color light, and/or a third area to emit third-color light, and the first-color light, the second-color light, and/or the third-color light may have different maximum emission wavelengths from one another. In an embodiment, the first-color light may be red light, the second-color light may be green light, and the third-color light may be blue light. In an embodiment, the plurality of color filter areas (and/or the plurality of color conversion areas) may include quantum dots. For example, the first area may include a red quantum dot, the second area may include a green quantum dot, and the third area may not include a quantum dot. Each of the first area, the second area, and/or the third area may further include a scattering body.

In an embodiment, the light-emitting device may be to emit first light, the first area may be to absorb the first light to emit first first-color light, the second area may be to absorb the first light to emit second first-color light, and the third area may be to absorb the first light to emit third first-color light. In this regard, the first first-color light, the second first-color light, and the third first-color light may have different maximum emission wavelengths from one another. For example, the first light may be blue light, the first first-color light may be red light, the second first-color light may be green light, and the third first-color light may be blue light.

The electronic apparatus may further include a thin-film transistor in addition to the light-emitting device as described above. The thin-film transistor may include a source electrode, a drain electrode, and an activation layer, wherein any one of the source electrode or the drain electrode may be electrically connected to any one of the first electrode or the second electrode of the light-emitting device.

The thin-film transistor may further include a gate electrode, a gate insulation layer, and/or the like.

The activation layer may include crystalline silicon, amorphous silicon, organic semiconductor, oxide semiconductor, and/or the like.

The electronic apparatus may further include a sealing portion for sealing the light-emitting device. The sealing portion may be located between the color filter and the light-emitting device, or between the color conversion layer and the light-emitting device. The sealing portion may allow light from the light-emitting device to be extracted or transmitted to the outside, while concurrently (e.g., simultaneously) preventing or reducing ambient air and/or moisture from penetrating into the light-emitting device. The sealing portion may be a sealing substrate including a transparent glass substrate and/or a plastic substrate. The sealing portion may be a thin film encapsulation layer including one or more organic layers and/or one or more inorganic layers. When the sealing portion is a thin film encapsulation layer, the electronic apparatus may be flexible.

On the sealing portion, in addition to the color filter and/or color conversion layer, one or more suitable functional layers may be further located according to the use of the electronic apparatus. Non-limiting examples of the functional layers include a touch screen layer, a polarizing layer, and/or the like. The touch screen layer may be a pressure-sensitive touch screen layer, a capacitive touch screen layer, or an infrared touch screen layer. The authentication apparatus may be, for example, a biometric authentication apparatus for authenticating an individual by using biometric information of a biometric body (for example, a fingertip, a pupil, or the like).

The authentication apparatus may further include, in addition to the light-emitting device, a biometric information collector.

The electronic apparatus may be applied to various suitable displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various suitable measuring instruments, meters (for example, meters for a vehicle, an aircraft, and a vessel), projectors, and/or the like.

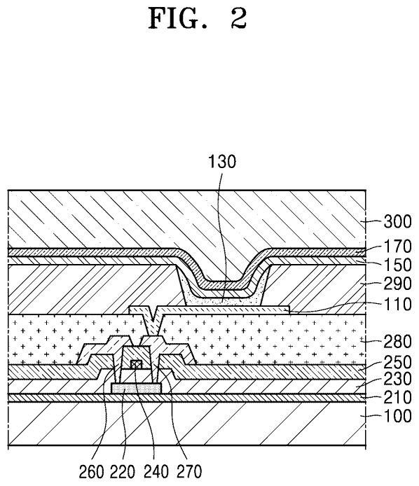

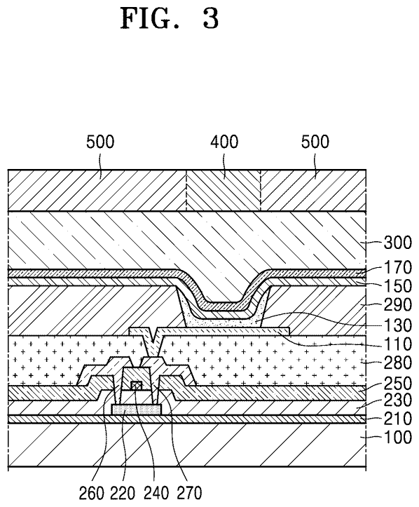

### Description of FIGS. 2 and 3

FIG. 2 is a cross-sectional view showing a light-emitting apparatus according to an embodiment of the present disclosure.

The light-emitting apparatus of FIG. 2 includes a substrate 100, a thin-film transistor (TFT), a light-emitting device, and an encapsulation portion 300 that seals light-emitting device.

The substrate 100 may be a flexible substrate, a glass substrate, or a metal substrate. A buffer layer 210 may be located on the substrate 100. The buffer layer 210 may prevent or reduce penetration of impurities through the substrate 100, and may provide a flat surface on (e.g., may planarize) the substrate 100.

The TFT may be located on the buffer layer 210. The TFT may include an activation layer 220, a gate electrode 240, a source electrode 260, and a drain electrode 270.

The activation layer 220 may include an inorganic semiconductor (such as silicon and/or polysilicon), an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240.

The interlayer insulating film 250 is located between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be located to be in contact with the exposed portions of the source region and the drain region of the activation layer 220.

The TFT may be electrically connected to a light-emitting device to drive the light-emitting device, and may be protectively covered by a passivation layer 280. The passivation layer 280 may include an inorganic insulating film, an organic insulating film, or a combination thereof. A light-emitting device is provided on the passivation layer 280. The light-emitting device includes the first electrode 110, the interlayer 130, and the second electrode 150.

The first electrode 110 may be located on the passivation layer 280. The passivation layer 280 does not completely cover the drain electrode 270 and may exposes a portion of the drain electrode 270, and the first electrode 110 may be connected to the exposed portion of the drain electrode 270.

A pixel defining layer 290 including an insulating material may be located on the first electrode 110. The pixel defining layer 290 may expose a set or predetermined region of the first electrode 110, and the interlayer 130 may be formed in the exposed region of the first electrode 110. The pixel defining layer 290 may be a polyimide or polyacryl-based organic film. In some embodiments, at least some layers of the interlayer 130 may extend beyond the upper portion of the pixel defining layer 290 and may thus be located in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on a light-emitting device and protects the light-emitting device from moisture or oxygen. The encapsulation portion 300 may include: an inorganic film including silicon nitride (SiNₓ), silicon oxide (SiOₓ), indium tin oxide, indium zinc oxide, or a combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate or polyacrylic acid), an epoxy-based resin (for example, aliphatic glycidyl ether (AGE)), or any combination thereof; or a combination of an inorganic film and an organic film.

FIG. 3 is a cross-sectional view of a light-emitting apparatus according to another embodiment.

The light-emitting apparatus of FIG. 3 is the same as the light-emitting apparatus of FIG. 2, except that a light-blocking pattern 500 and a functional region 400 are additionally located on the encapsulation portion 300. The functional region 400 may be i) a color filter area, ii) a color conversion area, or iii) a combination of the color filter area and the color conversion area. In an embodiment, the light-emitting device included in the light-emitting apparatus of FIG. 3 may be a tandem light-emitting device.

### Preparation Method

The layers constituting the hole transport region, the emission layer, and the layers constituting the electron transport region may be formed in a set or predetermined region using one or more suitable methods selected from vacuum deposition, spin coating, casting, Langmuir-Blodgett (LB) deposition, ink-jet printing, laser-printing, and laser-induced thermal imaging.

When the layers constituting the hole transport region, the emission layer, and the layers constituting the electron transport region are formed by vacuum deposition, the deposition may be performed at a deposition temperature of about 100° C. to about 500° C., a vacuum degree of about 10-8 torr to about 10-3 torr, and a deposition speed of about 0.01 Å/sec to about 100 Å/sec by taking into account a material to be included and the structure of a layer to be formed.

### Definition of Terms

The term “C₃-C₆₀ carbocyclic group” as used herein refers to a cyclic group that includes (e.g., consists of) carbon only as a ring-forming atom and has three to sixty carbon atoms, and the term “C₁-C₆₀ heterocyclic group” as used herein refers to a cyclic group that has one to sixty carbon atoms and further includes, in addition to carbon, a heteroatom as a ring-forming atom. The C₃-C₆₀ carbocyclic group and the C₁-C₆₀ heterocyclic group may each be a monocyclic group that includes (e.g., consists of) one ring, or a polycyclic group in which two or more rings are condensed with each other. In an embodiment, the number of ring-forming atoms of the C₁-C₆₀ heterocyclic group may be from 3 to 61.

The term “cyclic group” as used herein includes the C₃-C₆₀ carbocyclic group and the C₁-C₆₀ heterocyclic group.

The term “TT electron-rich C₃-C₆₀ cyclic group” as used herein refers to a cyclic group that has three to sixty carbon atoms and does not include *—N═*′ as a ring-forming moiety, and the term “IT electron-deficient nitrogen-containing C₁-C₆₀ cyclic group” as used herein refers to a heterocyclic group that has one to sixty carbon atoms and includes *—N═* as a ring-forming moiety.

In an embodiment,
the C₃-C₆₀ carbocyclic group may be i) a group T1 (described below) or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),
the C₁-C₆₀ heterocyclic group may be i) a group T2 (described below), ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothieno dibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),
the π electron-rich C₃-C₆₀ cyclic group may be i) a group T1, ii) a condensed cyclic group in which two or more groups T1 are condensed with each other, iii) a group T3 (described below), iv) a condensed cyclic group in which two or more groups T3 are condensed with each other, or v) a condensed cyclic group in which at least one group T3 and at least one group T1 are condensed with each other (for example, a C₃-C₆₀ carbocyclic group, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, or a benzothienodibenzothiophene group),
the π-electron-deficient nitrogen-containing C₁-C₆₀ cyclic group may be i) a group T4 (described below), ii) a condensed cyclic group in which two or more groups T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with each other (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, or an azadibenzofuran group),
where the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane group (or, a bicyclo[2.2.1]heptane group), a norbornene group, a bicyclo[1.1.1]pentane group, a bicyclo[2.1.1]hexane group, a bicyclo[2.2.2]octane group, or a benzene group,
the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group,
the group T3 may be a furan group, a thiophene group, a 1H-pyrrole group, a silole group, or a borole group, and
the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The cyclic group, the C₃-C₆₀ carbocyclic group, the C₁-C₆₀ heterocyclic group, the TT electron-rich C₃-C₆₀ cyclic group, and the TT-electron-deficient nitrogen-containing C₁-C₆₀ cyclic group may each independently be a group that is condensed with a cyclic group, a monovalent group, and/or a polyvalent group (for example, a divalent group, a trivalent group, a tetravalent group, (and/or the like), according to the structure of the formula described with the corresponding terms. In an embodiment, the term “benzene group” may be a benzo group, a phenyl group, a phenylene group, and/or the like, which may be easily understand by one of ordinary skill in the art according to the structure of a formula including the “benzene group.”

In an embodiment, examples of the monovalent C₃-C₆₀ carbocyclic group and examples of the monovalent C₁-C₆₀ heterocyclic group are (e.g., may be or include) a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and/or a monovalent non-aromatic condensed heteropolycyclic group, and examples of the divalent C₃-C₆₀ carbocyclic group and examples of the divalent C₁-C₆₀ heterocyclic group are (e.g., may be or include) a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group” as used herein refers to a linear or branched aliphatic hydrocarbon saturated monovalent group having 1 to 60 carbon atoms, and examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having substantially the same structure as the C₁-C₆₀ alkyl group.

The term “C₂-C₆₀ alkenyl group” as used herein refers to a monovalent hydrocarbon group having at least one carbon-carbon double bond in the middle or at the terminus of a C₂-C₆₀ alkyl group, and examples thereof include an ethenyl group, a propenyl group, and a butenyl group. The term “C₂-C₆₀ alkenylene group” as used herein refers to a divalent group having substantially the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of a C₂-C₆₀ alkyl group, and examples thereof include an ethynyl group and a propynyl group. The term “C₂-C₆₀ alkynylene group” as used herein refers to a divalent group having substantially the same structure as the C₂-C₆₀ alkynyl group.

The term “C₁-C₆₀ alkoxy group” as used herein refers to a monovalent group represented by -OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cycloctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having substantially the same structure as the C₃-C₁₀ cycloalkyl group.

The term “C₁-C₁₀ heterocycloalkyl group” as used herein refers to a monovalent cyclic group that further includes, in addition to a carbon atom, at least one heteroatom as a ring-forming atom and has 1 to 10 carbon atoms, and examples thereof are a 1,2,3,4-oxatriazolidinyl group, a tetrahydrofuranyl group, and a tetrahydrothiophenyl group. The term “C₁-C₁₀ heterocycloalkylene group” as used herein refers to a divalent group having substantially the same structure as the C₁-C₁₀ heterocycloalkyl group.

The term “C₃-C₁₀ cycloalkenyl group” as used herein refers to a monovalent cyclic group that has 3 to 10 carbon atoms, at least one double bond in the ring thereof, and no aromaticity, and non-limiting examples thereof include a cyclopentenyl group, a cyclohexenyl group, and/or a cycloheptenyl group. The term “C₃-C₁₀ cycloalkenylene group” as used herein refers to a divalent group having substantially the same structure as the C₃-C₁₀ cycloalkenyl group.

The term “C₁-C₁₀ heterocycloalkenyl group” as used herein refers to a monovalent cyclic group that has, in addition to a carbon atom, at least one heteroatom as a ring-forming atom, 1 to 10 carbon atoms, and at least one carbon-carbon double bond in the cyclic structure thereof. Non-limiting examples of the C₁-C₁₀ heterocycloalkenyl group include a 4,5-dihydro-1,2,3,4-oxatriazolyl group, a 2,3-dihydrofuranyl group, and/or a 2,3-dihydrothiophenyl group. The term “C₁-C₁₀ heterocycloalkenylene group” as used herein refers to a divalent group having substantially the same structure as the C₁-C₁₀ heterocycloalkenyl group.

The term “C₆-C₆₀ aryl group” as used herein refers to a monovalent group having a carbocyclic aromatic system having 6 to 60 carbon atoms, and the term “C₆-C₆₀ arylene group” as used herein refers to a divalent group having a carbocyclic aromatic system having 6 to 60 carbon atoms. Non-limiting examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and/or an ovalenyl group. When the C₆-C₆₀ aryl group and the C₆-C₆₀ arylene group each include two or more rings, the two or more rings may be condensed to each other.

The term “C₁-C₆₀ heteroaryl group” as used herein refers to a monovalent group having a heterocyclic aromatic system that has, in addition to 1 to 60 carbon atoms, at least one heteroatom as a ring-forming atom. The term “C₁-C₆₀ heteroarylene group” as used herein refers to a divalent group having a heterocyclic aromatic system that has, in addition to 1 to 60 carbon atoms, at least one heteroatom as a ring-forming atom. Non-limiting examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the two or more rings may be condensed with each other.

The term “monovalent non-aromatic condensed polycyclic group” as used herein refers to a monovalent group (for example, 8 to 60 carbon atoms) having two or more rings condensed with each other, only carbon atoms as ring-forming atoms, and non-aromaticity in its entire molecular structure (e.g., when the molecular structure of the group is considered as a whole). Non-limiting examples of the monovalent non-aromatic condensed polycyclic group include an indenyl group, a fluorenyl group, a spiro-bifluorenyl group, a benzofluorenyl group, an indenophenanthrenyl group, and an indenoanthracenyl group. The term “divalent non-aromatic condensed polycyclic group” as used herein refers to a divalent group having substantially the same structure as the monovalent non-aromatic condensed polycyclic group.

The term “monovalent non-aromatic condensed heteropolycyclic group” as used herein refers to a monovalent group (for example, 1 to 60 carbon atoms) having two or more rings condensed to each other, at least one heteroatom other than carbon atoms, as a ring-forming atom, and non-aromaticity in its entire molecular structure (e.g., when the molecular structure of the group is considered as a whole). Non-limiting examples of the monovalent non-aromatic condensed heteropolycyclic group may include a pyrrolyl group, a thiophenyl group, a furanyl group, an indolyl group, a benzoindolyl group, a naphthoindolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and/or a benzothienodibenzothiophenyl group. The term “divalent non-aromatic condensed heteropolycyclic group” as used herein refers to a divalent group having substantially the same structure as the monovalent non-aromatic condensed heteropolycyclic group.

The term “C₆-C₆₀ aryloxy group” as used herein refers to -OA₁₀₂ (wherein A₁₀₂ is a C₆-C₆₀ aryl group), and the term “C₆-C₆₀ arylthio group” as used herein refers to -SA₁₀₃ (wherein A₁₀₃ is a C₆-C₆₀ aryl group).

The term “R₁₀ₐ” as used herein refers to:
deuterium (-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).
Q₁ to Q₃, Q₁₁ to Q₁₃, Q₂₁ to Q₂₃, and Q₃₁ to Q₃₃ used herein may each independently be: hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom and a hydrogen atom. Non-limiting examples of the heteroatom include O, S, N, P, Si, B, Ge, and/or Se.

The term “Ph” as used herein refers to a phenyl group, the term “Me” as used herein refers to a methyl group, the term “Et” as used herein refers to an ethyl group, the term “ter-Bu” or “But” as used herein refers to a tert-butyl group, and the term “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group”. In other words, the “terphenyl group” is a substituted phenyl group having, as a substituent, a C₆-C₆₀ aryl group substituted with a C₆-C₆₀ aryl group.
* and *′ as used herein, unless defined otherwise, each refer to a binding site to a neighboring atom in a corresponding formula.

### EXAMPLES

### Evaluation Example 1

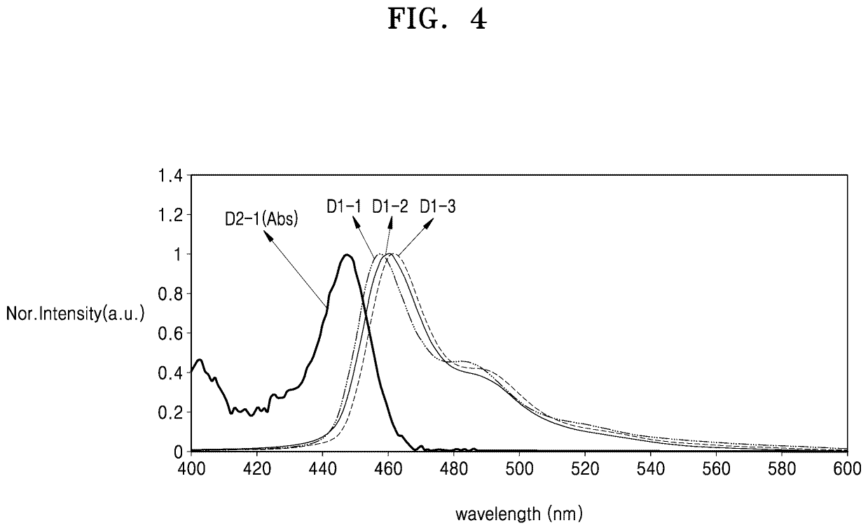

According to the method(s) described in Table 1, an emission spectrum, an emission peak wavelength, an absorption spectrum, an absorption peak wavelength, a molar extinction coefficient, and a Stokes shift were evaluated for each of the compounds described in Table 2, and the results are described in Table 2. The emission spectra of Compounds D1-1, D1-2 and D1-3 (“D1-1”, “D1-2” and “D1-3”) and the absorption spectra of Compound D2-1 (“D2-1 (Abs)”) are shown in FIG. 4.

TABLE 1

| | |
|---|---|
| Emission | A 5 μmol/L toluene solution of the compound to be measured |
| spectrum | was prepared and then placed in a quartz cell, and an emission |
| | spectrum (vertical axis: emission intensity; horizontal axis: |
| | wavelength (nm)) was measured at room temperature (300 K) |
| | using a streak camera (manufactured by Hamamatsu) and a ps |
| | LASER (EKSPLA). |
| Emission peak | The emission wavelength of the peak having the highest |
| wavelength | (maximum) emission intensity in the emission spectrum was |
| (nm) | evaluated as the emission peak wavelength. |
| Absorption | A 5 μmol/L toluene solution of the compound to be measured |
| spectrum | was prepared and then placed in a quartz cell, and an |
| | absorption spectrum (vertical axis: absorption intensity; |
| | horizontal axis: wavelength (nm)) was measured at room |
| | temperature (300 K) using a streak camera (manufactured by |
| | Hamamatsu) and a ps LASER (EKSPLA). |
| Absorption peak | The absorption wavelength of the peak having the highest |
| wavelength | (maximum) absorption intensity in the absorption spectrum was |
| (nm) | evaluated as the absorption peak wavelength. |
| Molar extinction | The intensity of the absorption peak having the longest |
| coefficient | wavelength in the absorption spectrum (among peaks having an |
| (extinction | absorption intensity of 1/10 or more of the absorption peak |
| coefficient (ε), | wavelength) was divided by the concentration of the solution. |
| L/(mol · cm), or M⁻¹ | |
| cm⁻¹) | |
| Stokes shift | The Stokes shift was calculated by subtracting the absorption |
| (nm) | peak wavelength of the absorption spectrum from the emission |
| | peak wavelength of the emission spectrum. |

TABLE 2

| | | | Absorption | Molar | |
|---|---|---|---|---|---|
| | | Emission peak | peak | extinction | Stokes |
| | | wavelength | wavelength | coefficient | shift |
| Compound | | (nm) | (nm) | (M⁻¹ cm⁻¹) | (nm) |
| First | D1-1 | 458 | 410 | — | — |
| dopant | D1-2 | 460 | 415 | — | — |
| | D1-3 | 462 | 417 | — | — |
| | D1-A | 475 | — | — | — |
| Second | D2-1 | 462 | 448 | 9.786 | 14 |
| dopant | D2-A | 461 | 442 | 8.456 | 19 |

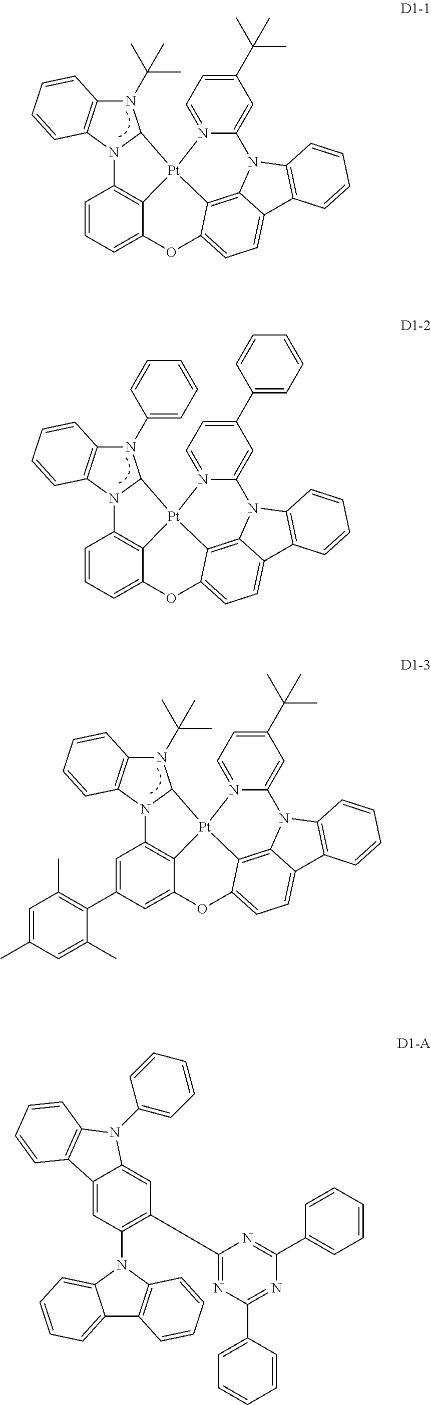

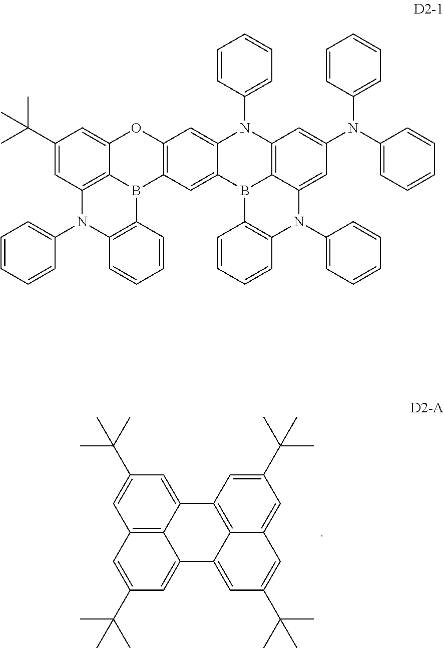

### Evaluation Example 2

The spectral overlap integrals with respect to each of the emission spectra and the absorption spectra of the compounds described in Table 3 were calculated according to Equation 1 (e.g., using an Excel program), and are shown in Table 3.

TABLE 3

| | Compound used | |
|---|---|---|
| Compound used for | for measuring | Spectral overlap integral of emission |
| measuring emission | absorption | spectrum and absorption spectrum |
| spectrum | spectrum | (M⁻¹ cm⁻¹ nm⁴) |
| D1-1 | D2-1 | 1.62 × 10¹⁵ |
| D1-2 | D2-1 | 1.76 × 10¹⁵ |
| D1-3 | D2-1 | 1.60 × 10¹⁵ |
| D1-A | D2-A | 1.32 × 10¹⁵ |

### Evaluation Example 3

A low temperature (4 K) emission spectrum and a room temperature (300 K) emission spectrum of thin films formed by depositing each compound described in Table 4 to a thickness of 300 Å were each measured using a spectrophotometer using the method(s) in Table 1, and then 1) a lowest excited triplet (T₁) energy level was evaluated by comparing the room and low temperature emission spectra and analyzing a peak observed only in the low temperature emission spectrum, and 2) a lowest excited singlet (S₁) energy level was evaluated by converting the emission peak wavelength in the room temperature emission spectrum from nm into eV, and the results are shown in Table 4:

TABLE 4

| | | |
|---|---|---|
| Compound | T₁ (eV) | S₁ (eV) |

| | | | |
|---|---|---|---|
| First dopant | D1-1 | 2.82 | — |
| | D1-2 | 2.72 | — |
| | D1-3 | 2.67 | — |
| | D1-A | 2.60 | — |
| Second | D2-1 | — | 2.67 |
| dopant | D2-A | — | 2.51 |

### Example 1

A 15 Ωcm² (1,200 Å) ITO glass substrate (anode) available from Corning Inc. was cut to a size of 50 mm×50 mm×0.7 mm, sonicated using isopropyl alcohol and pure water for 5 minutes each, and then cleaned by ultraviolet irradiation and ozone exposure for 30 minutes. Then, the resultant glass substrate was loaded onto a vacuum deposition apparatus.

2-TNATA was vacuum-deposited on the glass substrate to form a hole injection layer having a thickness of 600 Å, and then HAT-CN was vacuum-deposited thereon to form a hole transport layer having a thickness of 300 Å.

A host (mCBP), a first dopant, and a second dopant were co-deposited on the hole transport layer at a weight ratio of 90:5:5 to form an emission layer having a thickness of 300 Å. The first dopant and the second dopant are the same as described in Table 5.

Subsequently, ET1 was vacuum-deposited on the emission layer to form an electron transport layer having a thickness of 300 Å. Yb was vacuum-deposited on the electron transport layer to form an electron injection layer having a thickness of 10 Å, and Al was vacuum-deposited thereon to form a cathode having a thickness of 3,000 Å, thereby completing manufacture of an organic light-emitting device.

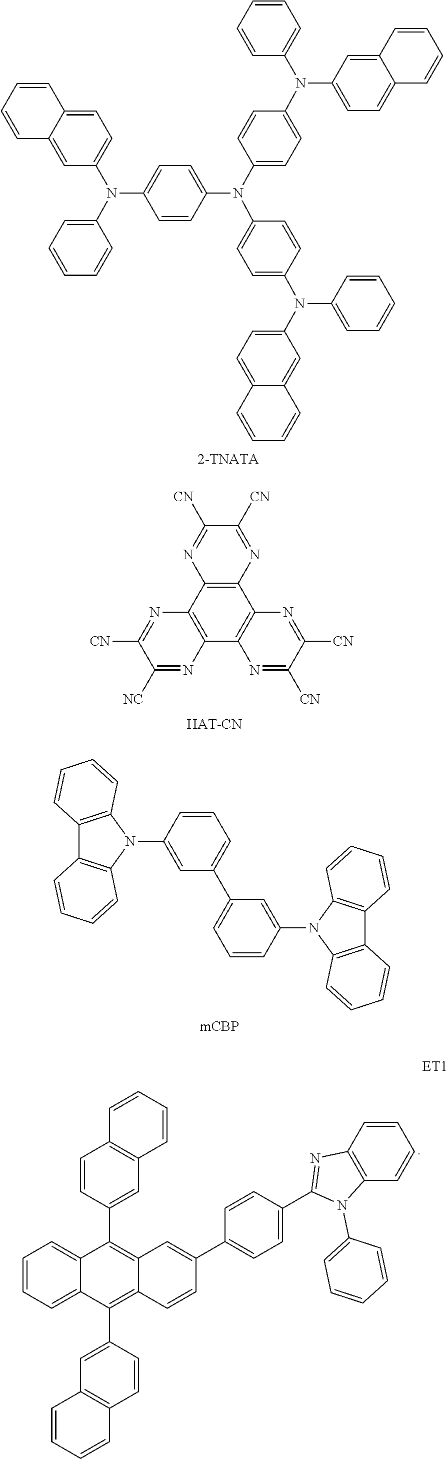

### Examples 2 and 3 and Comparative Example A

Organic light-emitting devices were manufactured in substantially the same manner as in Example 1, except that the compounds described in Table 5 were respectively used in forming the emission layer.

### Evaluation Example 4

The driving voltage at a current density of 10 mA/cm², external quantum efficiency (EQE), lifespan (LT₅₀), and color coordinates of the organic light-emitting devices manufactured in Examples 1 to 3 and Comparative Example A were measured using the following methods, and the results thereof are shown in Table 5:
Color coordinates: Power was supplied from a current-voltmeter (Keithley SMU 236), and the color coordinates were measured using a luminance meter PR650.
Luminance: Power was supplied from a current-voltmeter (Keithley SMU 236), and luminance was measured using a luminance meter PR650.
Efficiency: Power was supplied from a current-voltmeter (Keithley SMU 236), and efficiency was measured using a luminance meter PR650.

Lifespan (LT₅₀) indicates an amount of time that was taken until the luminance was reduced to 50% of initial luminance of 100%.

TABLE 5

| | | | | External | | | |
|---|---|---|---|---|---|---|---|
| | Composition of | | Driv- | quan- | | | |
| | emission layer | | ing | tum ef- | | Color | |
| | First | Second | voltage | ficiency | LT₅₀ | coordinates | |
| | dopant | dopant | (V) | (%) | (hours) | CIEₓ | CIE_{y} |
| Exam- | D1-1 | D2-1 | 4.4 | 19.8 | 460 | 0.128 | 0.130 |
| ple 1 | | | | | | | |
| Exam- | D1-2 | D2-1 | 4.5 | 18.2 | 440 | 0.122 | 0.129 |
| ple 2 | | | | | | | |
| Exam- | D1-3 | D2-1 | 4.5 | 16.3 | 350 | 0.127 | 0.132 |
| ple 3 | | | | | | | |
| Compar- | D1-A | D2-A | 4.5 | 7.3 | 70 | 0.127 | 0.157 |
| ative | | | | | | | |
| Exam- | | | | | | | |
| ple A | | | | | | | |

From Table 5, it is confirmed that the light-emitting devices of Examples 1 to 3 emit blue light and have improved driving voltage, improved external quantum efficiency, and improved lifespan characteristics, compared to the light-emitting device of Comparative Example A.

The light-emitting devices according to embodiments of the present disclosure may have low driving voltage, high external quantum efficiency, and/or long lifespan. Also, an electronic apparatus may be manufactured using the light-emitting devices.

It should be understood that the embodiments described herein should be considered in a descriptive sense only and not for purposes of limitation. Descriptions of features or aspects within each embodiment should typically be considered as being available for other similar features or aspects in other embodiments. While one or more embodiments have been described with reference to the drawings, it will be understood by those of ordinary skill in the art that various suitable changes in form and details may be made therein without departing from the spirit and scope of the present disclosure, as defined by the following claims and equivalents thereof.

What is claimed is:

1. A light-emitting device comprising:
a first electrode;
a second electrode facing the first electrode; and
an interlayer between the first electrode and the second electrode and comprising an emission layer,
wherein the emission layer comprises a host, a first dopant, and a second dopant,
the host, the first dopant, and the second dopant are different from each other,
the first dopant is a phosphorescent dopant, and the first dopant is a transition metal-containing organometallic compound,
a Stokes shift of the second dopant is less than or equal to 15 nm,
a spectral overlap integral of an emission spectrum of the first dopant and an absorption spectrum of the second dopant is greater than or equal to 1.5×10¹⁵ M⁻¹ cm⁻1 nm⁴, and
the spectral overlap integral is evaluated by Equation 1:
$$J ( λ ) = {\int }_{0}^{∞} ε ( λ ) {λ}^{4} {F}_{D} ( λ ) d λ , \qquad Equation 1$$
wherein, in Equation 1,
J(λ) is the spectral overlap integral of the emission spectrum of the first dopant and the absorption spectrum of the second dopant in units of M⁻¹ cm⁻¹ nm⁴,
ε(λ) is a molar extinction coefficient of the second dopant calculated from the absorption spectrum of the second dopant in units of M⁻¹ cm⁻¹,
λ is a wavelength of the emission spectrum and the absorption spectrum in units of nm, and
F_{D}(λ) is a normalized emission spectrum of the first dopant, and
wherein the emission spectrum of the first dopant is an emission spectrum evaluated at room temperature in a 5 μM toluene solution of the first dopant, and
the absorption spectrum of the second dopant is an absorption spectrum evaluated at room temperature in a 5 μM toluene solution of the second dopant, and
wherein the second dopant comprises a heterocyclic compound represented by one of Formulae 11(4) to 11(7): 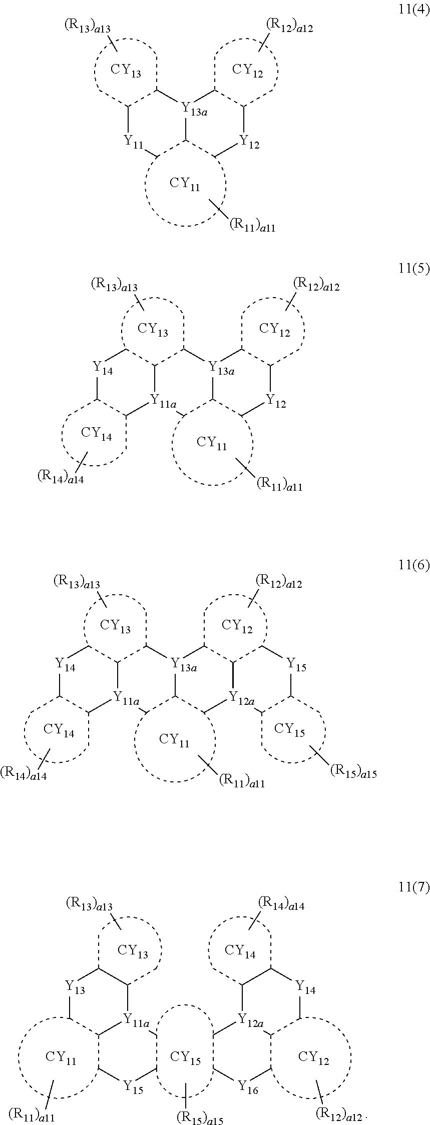
and
wherein in Formulae 11(4) to 11(7),
ring CY11 to ring CY15 are each independently a C₃-C₆₀ carbocyclic group or a C₁-C₆₀ heterocyclic group,
Y₁₁ to Y₁₆ are each independently a single bond, *—O—**, *—S—*, *—C(R₁₆)(R₁₇)—*, *—N(R₁₆)—*, *—Si(R₁₆)(R₁₇)—*, *—C(═O)—*, *—S(═O) 2-**, *—B(R₁₆)—***—P(R₁₇)—*, or *—P(═O)(R₁₆)—*′, and * and *′ each indicate a binding site to a neighboring atom,
Y₁₁ₐ, Y₁₂ₐ, and Y₁₃ₐ are each independently N, B, or P,
R₁₁ to R₁₇ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₁-C₆₀ alkenyl group unsubstituted or substituted with at least one R₁₀ₐ, a C₁-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
two or more of R₁₁ to R₁₇ are optionally linked to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
a11 to a15 are each independently an integer from 1 to 6, and
R₁₀ₐ is:
deuterium (-D), —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, or a C₆-C₆₀ arylthio group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently hydrogen, deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

2. The light-emitting device of claim 1, wherein the first dopant comprises a tridentate organic ligand or a tetradentate organic ligand.

3. The light-emitting device of claim 1, wherein the Stokes shift of the second dopant is greater than or equal to 5 nm and less than or equal to 15 nm.

4. The light-emitting device of claim 1, wherein the spectral overlap integral is greater than or equal to 1.5×10¹⁵ M⁻¹ cm⁻¹ nm⁴ and less than or equal to 2.0×10¹⁵ M⁻¹ cm⁻¹ nm⁴.

5. The light-emitting device of claim 1, wherein an emission peak wavelength in the emission spectrum of the first dopant is greater than or equal to 430 nm and less than or equal to 470 nm.

6. The light-emitting device of claim 1, wherein an emission peak wavelength in the emission spectrum of the first dopant is greater than an absorption peak wavelength in the absorption spectrum of the second dopant.

7. The light-emitting device of claim 1, wherein excitons are to transition from a lowest excitation triplet energy level (T₁) of the first dopant to a lowest excitation singlet energy level (S₁) of the second dopant, and excitons at the lowest excitation singlet energy level (S₁) of the second dopant are to transition to a ground state to thereby emit light.

8. The light-emitting device of claim 1, wherein, the second dopant is to emit greater than or equal to 80% of total emission components to be emitted from the emission layer.

9. The light-emitting device of claim 1, wherein the emission layer is to emit blue light having an emission peak wavelength of greater than or equal to 420 nm and less than or equal to 470 nm.

10. The light-emitting device of claim 1, wherein the emission layer is to emit blue light having a CIEₓ color coordinate of greater than or equal to 0.115 and less than or equal to 0.135, and a CIE_{y} color coordinate of greater than or equal to 0.120 and less than or equal to 0.140.

11. The light-emitting device of claim 1, wherein a sum of an amount of the first dopant and an amount of the second dopant is less than an amount of the host.

12. The light-emitting device of claim 1, wherein a sum of an amount of the first dopant and an amount of the second dopant is greater than or equal to 0.1 parts by weight and less than or equal to 30 parts by weight, based on a total of 100 parts by weight of the emission layer.

13. The light-emitting device of claim 1, wherein the first dopant is an organometallic compound comprising platinum and a tetradentate ligand.

14. The light-emitting device of claim 1, wherein the second dopant does not include a transition metal.

15. The light-emitting device of claim 1, wherein the second dopant is a delayed fluorescence dopant satisfying Equation 3-2:
$${Δ E}_{ST} = S 1 ( D 2 ) - T 1 ( D 2 ) \leq 0.3 eV , and \qquad Equation 3-2$$
wherein, in Equation 3-2,
S1(D2) is a lowest excitation singlet energy level of the second dopant, and
T1(D2) is a lowest excitation triplet energy level of the second dopant.

16. The light-emitting device of claim 1, wherein the second dopant is a prompt fluorescence dopant.

17. An electronic apparatus comprising the light-emitting device of claim 1.

18. The electronic apparatus of claim 17, further comprising a thin-film transistor,
wherein the thin-film transistor comprises a source electrode and a drain electrode, and
the first electrode of the light-emitting device is electrically connected to at least one of the source electrode or the drain electrode of the thin-film transistor.

19. The electronic apparatus of claim 17, further comprising a color filter, a color conversion layer, a touch screen layer, a polarizing layer, or any combination thereof.

20. A light-emitting device comprising:
a first electrode;
a second electrode facing the first electrode; and
an interlayer between the first electrode and the second electrode and comprising an emission layer,
wherein the emission layer comprises a host, a first dopant, and a second dopant,
the host, the first dopant, and the second dopant are different from each other, the first dopant is a phosphorescent dopant, and the first dopant is a transition metal-containing organometallic compound,
a Stokes shift of the second dopant is less than or equal to 15 nm,
a spectral overlap integral of an emission spectrum of the first dopant and an absorption spectrum of the second dopant is greater than or equal to 1.5×10¹⁵ M⁻¹ cm⁻¹ nm⁴, and
the spectral overlap integral is evaluated by Equation 1:
$$J ( λ ) = {\int }_{0}^{∞} ε ( λ ) {λ}^{4} {F}_{D} ( λ ) d λ , \qquad Equation 1$$
wherein, in Equation 1,
J(λ) is the spectral overlap integral of the emission spectrum of the first dopant and the absorption spectrum of the second dopant in units of M⁻¹ cm⁻¹ nm⁴,
ε(λ) is a molar extinction coefficient of the second dopant calculated from the absorption spectrum of the second dopant in units of M⁻¹ cm⁻¹,
λ is a wavelength of the emission spectrum and the absorption spectrum in units of nm, and
F_{D}(λ) is a normalized emission spectrum of the first dopant, and
wherein the emission spectrum of the first dopant is an emission spectrum evaluated at room temperature in a 5 μM toluene solution of the first dopant, and
the absorption spectrum of the second dopant is an absorption spectrum evaluated at room temperature in a 5 μM toluene solution of the second dopant, and
wherein the second dopant comprises a condensed cyclic ring in which at least one first ring and at least one second ring are condensed with each other,
the at least one first ring is a 6-membered ring comprising boron (B) and one nitrogen (N) as ring-forming atoms, and
the at least one second ring is a pyrrole group, a furan group, a thiophene group, a benzene group, a pyridine group, or a pyrimidine group.

21. The light-emitting device of claim 20, wherein the first dopant comprises a tridentate organic ligand or a tetradentate organic ligand.
